(19) United States
(12) Patent Application Publication
(10) Pub. No.: US 2026/0206201 A1
(43) Pub. Date: Jul. 16, 2026

(54) METHOD OF MANUFACTURING SEMICONDUCTOR MEMORY DEVICE

(71) Applicant: SAMSUNG ELECTRONICS CO., LTD., Suwon-si (KR)

(72) Inventors: Sangbin AHN, Suwon-si (KR); Kyounghwan KIM, Suwon-si (KR); Junsoo KIM, Suwon-si (KR); Hyungjoon KIM, Suwon-si (KR); Youngseung CHO, Suwon-si (KR)

(73) Assignee: SAMSUNG ELECTRONICS CO., LTD, Suwon-si (KR)

(21) Appl. No.: 19/443,655

(22) Filed: Jan. 8, 2026

(30) Foreign Application Priority Data
Jan. 10, 2025 (KR) 10-2025-0004220

(51) Int. Cl. H10B 12/00

(52) U.S. Cl. CPC H10B 12/053; H10B 12/315; H10B 12/34

(57) ABSTRACT

A method of manufacturing a semiconductor memory device includes providing a substrate in which a plurality of active areas are defined by a device isolation film, forming a word line trench across the plurality of active areas and the device isolation film, forming a lower word line layer filling a lower portion of the word line trench, forming an upper word line layer filling a portion of the word line trench, performing an etching process having a high etch selectivity of the lower word line layer with respect to the upper word line layer, and forming a buried insulating film covering the lower word line layer and the upper word line layer and filling the word line trench.

### CROSS-REFERENCE TO RELATED APPLICATION

This application claims priority under 35 U.S.C. § 119 to Korean Patent Application No. 10-2025-0004220, filed on January 10, 2025, in the Korean Intellectual Property Office, the disclosure of which is incorporated by reference herein in its entirety.

### BACKGROUND

The present disclosure relates to a method of manufacturing a semiconductor memory device, and more particularly, to a method of manufacturing a semiconductor memory device including a plurality of word lines.

With the rapid development of the electronics industry and the demand of users, electronic devices have become smaller and lighter. Accordingly, semiconductor memory devices used in electronic devices have also been required to have a high degree of integration, and thus, design rules for components of semiconductor memory devices have been reduced. Accordingly, defects have increased in the process of manufacturing semiconductor memory devices, making it difficult to ensure the operational reliability of the semiconductor memory devices.

### SUMMARY

One or more embodiments provide a method of manufacturing a semiconductor memory device having a high degree of integration and operational reliability.

According to an aspect of an embodiment, a method of manufacturing a semiconductor memory device, includes: providing a substrate in which a plurality of active areas are defined by a device isolation film; forming a word line trench extending along a first horizontal direction across the plurality of active areas and the device isolation film; forming a first preliminary conductive layer filling at least a portion of the word line trench; performing a first etching process to remove an upper portion of the first preliminary conductive layer and form a lower word line layer that fills a lower portion of the word line trench; forming a second preliminary conductive layer covering the lower word line layer and filling the word line trench; performing a second etching process to remove an upper portion of the second preliminary conductive layer and form an upper word line layer that fills a portion of the word line trench; performing a third etching process having a high etch selectivity of the lower word line layer with respect to the upper word line layer; and forming a buried insulating film covering the lower word line layer and the upper word line layer and filling the word line trench.

According to another aspect of an embodiment, a method of manufacturing a semiconductor memory device includes: providing a substrate in which a plurality of active areas are defined by a device isolation film; forming a plurality of word line trenches extending parallel to each other along a first horizontal direction across the plurality of active areas and the device isolation film; forming a first preliminary conductive layer filling at least a portion of each of the plurality of word line trenches; performing a first etching process to remove an upper portion of the first preliminary conductive layer and form a plurality of lower word line layers that fill lower portions of the plurality of word line trenches, wherein the first etching process is an anisotropic etching process; forming a second preliminary conductive layer covering the plurality of lower word line layers and filling the plurality of word line trenches; performing a second etching process to remove an upper portion of the second preliminary conductive layer and form a plurality of upper word line layers filling portions of the plurality of word line trenches, wherein the second etching process is an anisotropic etching process; performing a third etching process that is an isotropic etching process and has a high etch selectivity of the plurality of lower word line layers with respect to the plurality of upper word line layers; and forming a plurality of buried insulating films covering the plurality of lower word line layers and the plurality of upper word line layers and filling the plurality of word line trenches.

According to another aspect of an embodiment, a method of manufacturing a semiconductor memory device, includes: providing a substrate in which a plurality of active areas are defined by a device isolation film; forming a plurality of word line trenches extending parallel to each other along a first horizontal direction across the plurality of active areas and the device isolation film; forming a first preliminary conductive layer filling at least a portion of each of the plurality of word line trenches; performing a first etching process to remove an upper portion of the first preliminary conductive layer and form a plurality of lower word line layers filling lower portions of the plurality of word line trenches, wherein the first etching process is an anisotropic etching process, and wherein at least one of the plurality of lower word line layers comprises a defect protruding upward more than other portions of the plurality of lower word line layers; forming a second preliminary conductive layer covering the plurality of lower word line layers and filling the plurality of word line trenches; performing a second etching process to remove an upper portion of the second preliminary conductive layer and form a plurality of upper word line layers filling portions of the plurality of word line trenches, wherein the second etching process is an anisotropic etching process, wherein the defect in the at least one of the plurality of lower word line layers protrudes upward beyond a top surface of the plurality of upper word line layers, and wherein the plurality of lower word line layers and the plurality of upper word line layers constitute a plurality of word lines; performing a third etching process that is an isotropic etching process and has a high etch selectivity of the plurality of lower word line layers with respect to the plurality of upper word line layers, to form an electrode recess by removing at least a portion of the defect in the at least one of the plurality of lower word line layers; forming a plurality of buried insulating films covering the plurality of lower word line layers and the plurality of upper word line layers, and filling the plurality of word line trenches and the electrode recess; forming a plurality of bit lines extending along a second horizontal direction, perpendicular to the first horizontal direction, and a plurality of direct contact conductive patterns connecting the plurality of bit lines to the plurality of active areas, on the plurality of word lines; forming a plurality of buried contacts filling a lower portion of a space between the plurality of bit lines and connected to the plurality of active areas; forming a plurality of landing pads connected to the plurality of buried contacts; and forming a plurality of capacitor structures connected to the plurality of landing pads.

According to another aspect of an embodiment, a semiconductor memory device includes a substrate in which a plurality of active areas are defined by a device isolation film, a word line trench extending along a first horizontal direction across the plurality of active areas and the device isolation film, a word line filling a lower portion of the word line trench, and including a lower word line layer and an upper word line layer on the lower word line layer, a buried insulating film covering the word line and filling the word line trench, and a bit line extending along a second horizontal direction, orthogonal to the first horizontal direction, on the word line, wherein the word line includes an electrode recess, wherein the upper word line layer is separated into two portions by the electrode recess to be spaced apart from each other in the first horizontal direction.

The buried insulating film may include an extension insulating portion filling the electrode recess. The extension insulating portion may contact the lower word line layer.

The lower word line layer may include a material containing metal atoms, and the upper word line layer may include a semiconductor material.

The word line may further include a filling conductive layer filling the electrode recess. The filling conductive layer may include a semiconductor material.

The lower word line layer may include a protrusion protruding toward the electrode recess more than other portions of the lower word line layer.

The electrode recess may include a first electrode recess and a second electrode recess, wherein the protrusion includes a first protrusion protruding toward the first electrode recess and a second protrusion protruding toward the second electrode recess, wherein a horizontal width of an uppermost end of the first electrode recess is greater than a horizontal width of an uppermost end of the second electrode recess, and a protrusion height of the second protrusion is lower than a protrusion height of the first protrusion.

The lower word line layer may include a concave portion having a concave top surface at a portion corresponding to the electrode recess.

The buried insulating film may fill the electrode recess and the concave portion.

### BRIEF DESCRIPTION OF DRAWINGS

The above and other aspects will be more apparent from the following description of embodiments taken in conjunction with the accompanying drawings, in which:

FIG. 1 is a block diagram for describing a semiconductor memory device, according to embodiments;

FIG. 2 is a schematic planar layout for describing main components of a semiconductor memory device, according to embodiments;

FIGS. 3A, 3B, 3C, 3D, 4A, 4B, 4C, 4D, 5A, 5B, 5C, 5D, 6A, 6B, 6C, 6D, 7A, 7B, 7C, 7D, 8A, 8B, 8C, 8D, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C and 15D are cross-sectional views for describing a method of manufacturing a semiconductor device, according to embodiments;

FIGS. 16A, 16B, 16C and 16D are cross-sectional views for describing a semiconductor memory device, according to embodiments;

FIGS. 17A, 17B and 17C are partially enlarged views illustrating a semiconductor memory device, according to embodiments;

FIGS. 18A, 18B, 18C and 18D are partially enlarged views illustrating a semiconductor memory device, according to embodiments;

FIGS. 19A, 19B, 19C, 19D, 20A, 20B, 20C, 20D, 21A, 21B, 21C and 21D are cross-sectional views for describing a method of manufacturing a semiconductor memory device, according to embodiments;

FIGS. 22A, 22B, 22C and 22D are cross-sectional views illustrating a semiconductor memory device, according to embodiments;

FIGS. 23A, 23B and 23C are partially enlarged views illustrating a semiconductor memory device, according to embodiments; and

FIGS. 24A, 24B, 24C and 24D are partially enlarged views illustrating a semiconductor memory device, according to embodiments.

### DETAILED DESCRIPTION

Hereinafter, example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

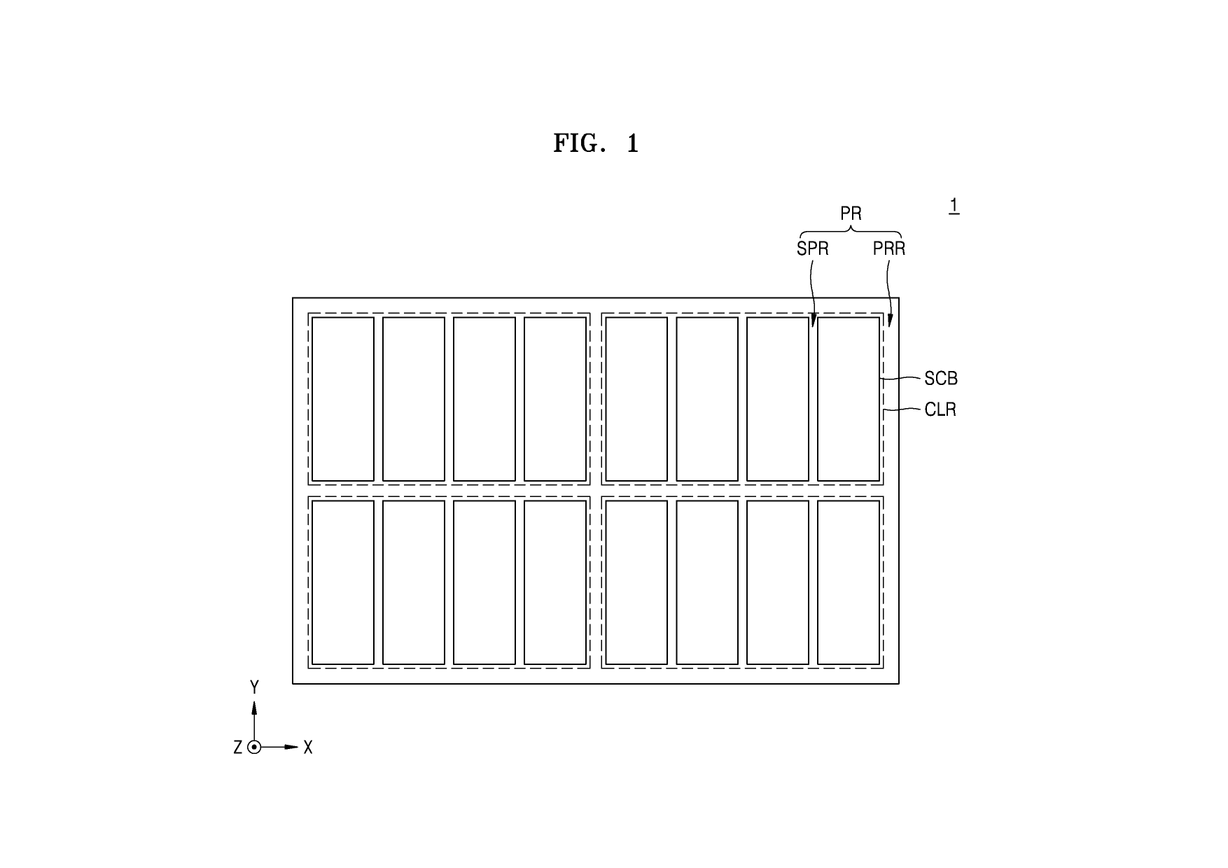

FIG. 1 is a block diagram for describing a semiconductor memory device, according to embodiments.

Referring to FIG. 1, a semiconductor memory device 1 may include a cell area CLR where memory cells are disposed, and a main peripheral area PRR surrounding the cell area CLR.

According to an embodiment, sub-peripheral areas SPR that separate cell blocks SCB may be included in the cell area CLR. A plurality of memory cells may be disposed in the cell blocks SCB. The term “cell block SCB” used herein refers to an area where the memory cells are regularly arranged at uniform intervals, and the cell block SCB may be referred to as a sub-cell block.

Logic cells for inputting/outputting electrical signals to/from the memory cells may be disposed in the main peripheral area PRR and the sub-peripheral area SPR. In some embodiments, the main peripheral are PRR may be referred to as a peripheral circuit area, and the sub-peripheral area SPR may be referred to as a core circuit area. A peripheral area PR may include the main peripheral area PRR and the sub-peripheral areas SPR. That is, the peripheral area PR may be a core and peripheral circuit area including the peripheral circuit area and the core circuit area. In some embodiments, at least a portion of the sub-peripheral area SPR may be provided only as a space for separating the cell blocks SCB from each other.

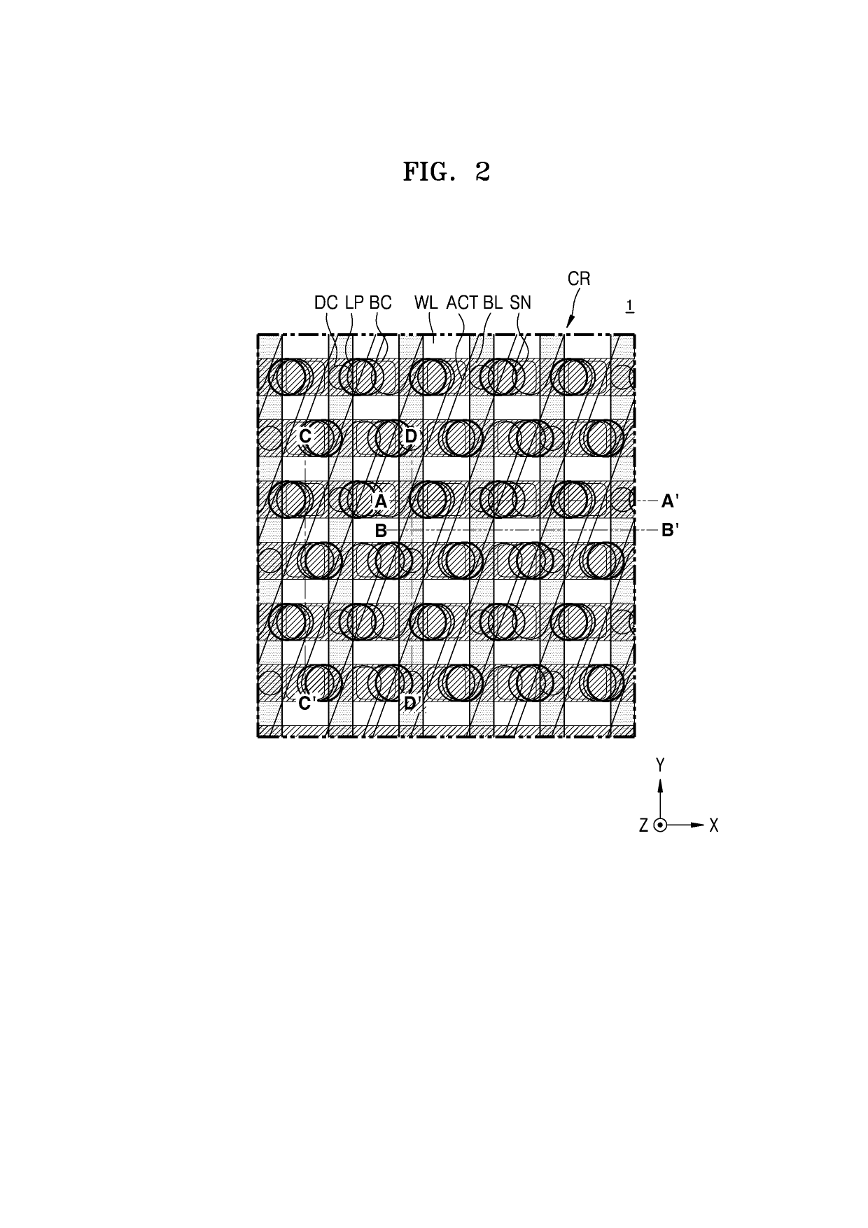

FIG. 2 is a schematic planar layout for describing main components of a semiconductor memory device, according to embodiments.

Referring to FIG. 2, the semiconductor memory device 1 includes a memory cell area CR. The semiconductor memory device1 may include a plurality of active areas ACT disposed in the memory cell area CR. The memory cell area CR may be the cell block SCB where a plurality of memory cells shown in FIG. 1 are disposed. The plurality of active areas ACT disposed in the memory cell area CR may have a long axis in a diagonal direction with respect to a first horizontal direction (X direction) and a second horizontal direction (Y direction). In some embodiments, the plurality of active areas ACT may be arranged in columns in the diagonal direction with respect to the first horizontal direction (X direction) and the second horizontal direction (Y direction), and may be arranged in columns in the second horizontal direction (Y direction).

A plurality of word lines WL may extend across the plurality of active areas ACT in the memory cell area CR to be parallel to each other along the first horizontal direction (X direction). In some embodiments, one pair of word lines WL may extend parallel to each other along the first horizontal direction (X direction) on one active area ACT. A plurality of bit lines BL may extend on the plurality of word lines WL to be parallel to each other along the second horizontal direction (Y direction) intersecting the first horizontal direction (X direction). In some embodiments, one bit line BL may extend on one active area ACT along the second horizontal direction (Y direction). The plurality of bit lines BL may be connected to the plurality of active areas ACT through a plurality of direct contacts DC. The plurality of direct contacts DC may be disposed at intersections between the plurality of bit lines BL and the plurality of active areas ACT.

In some embodiments, a plurality of buried contacts BC may be formed between two adjacent bit lines BL among the plurality of bit lines BL. In some embodiments, the plurality of buried contacts BC may be arranged in a line along the first horizontal direction (X direction) and the second horizontal direction (Y direction). In some embodiments, one pair of buried contacts BC may be connected to one active area ACT. For example, one buried contact BC may be connected to each of both ends of one active area ACT.

A plurality of landing pads LP may be formed on the plurality of buried contacts BC. The plurality of landing pads LP may at least partially overlap the plurality of buried contacts BC. In some embodiments, the plurality of landing pads LP may extend to be above one of two adjacent bit lines BL.

A plurality of storage nodes SN may be formed on the plurality of landing pads LP. The plurality of storage nodes SN may be formed above the plurality of bit lines BL. The plurality of storage nodes SN may be respectively lower electrodes of a plurality of capacitors. The storage node SN may be connected to the active area ACT through the landing pad LP and the buried contact BC.

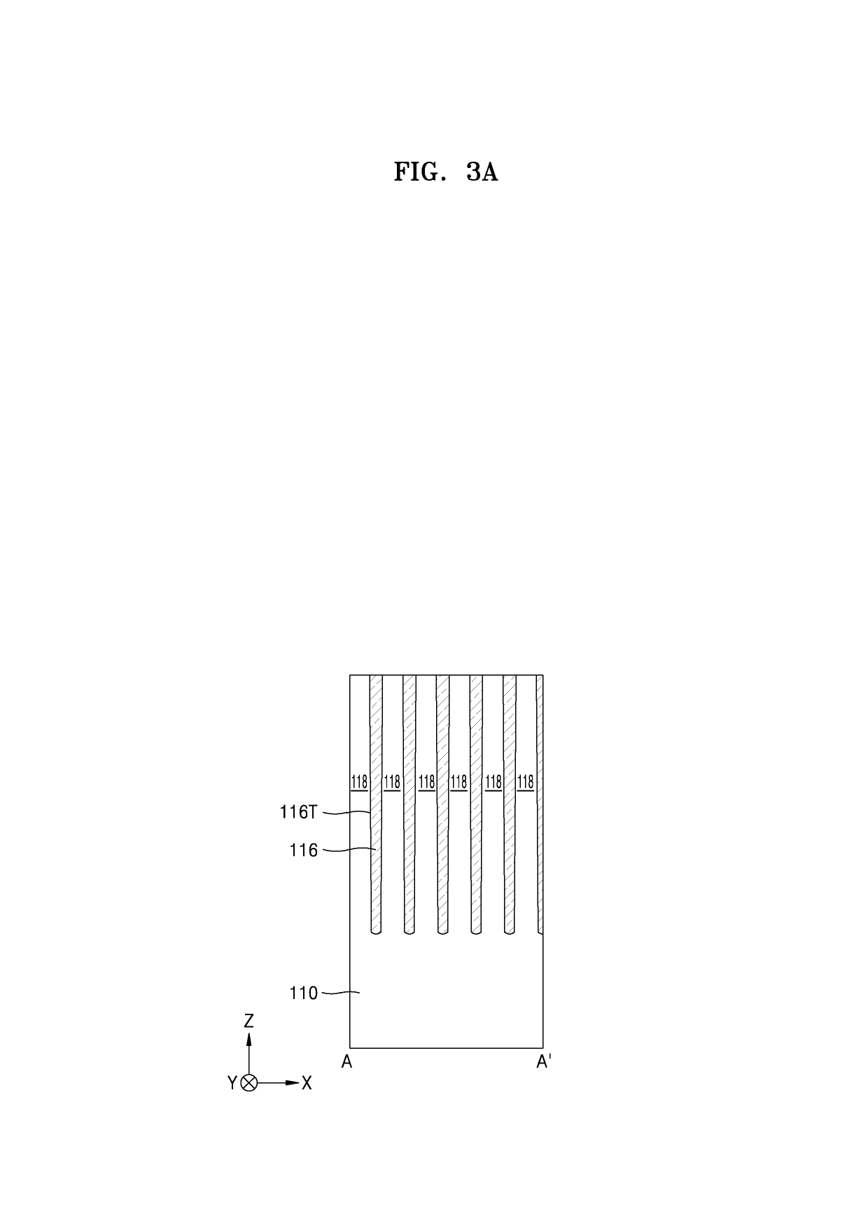

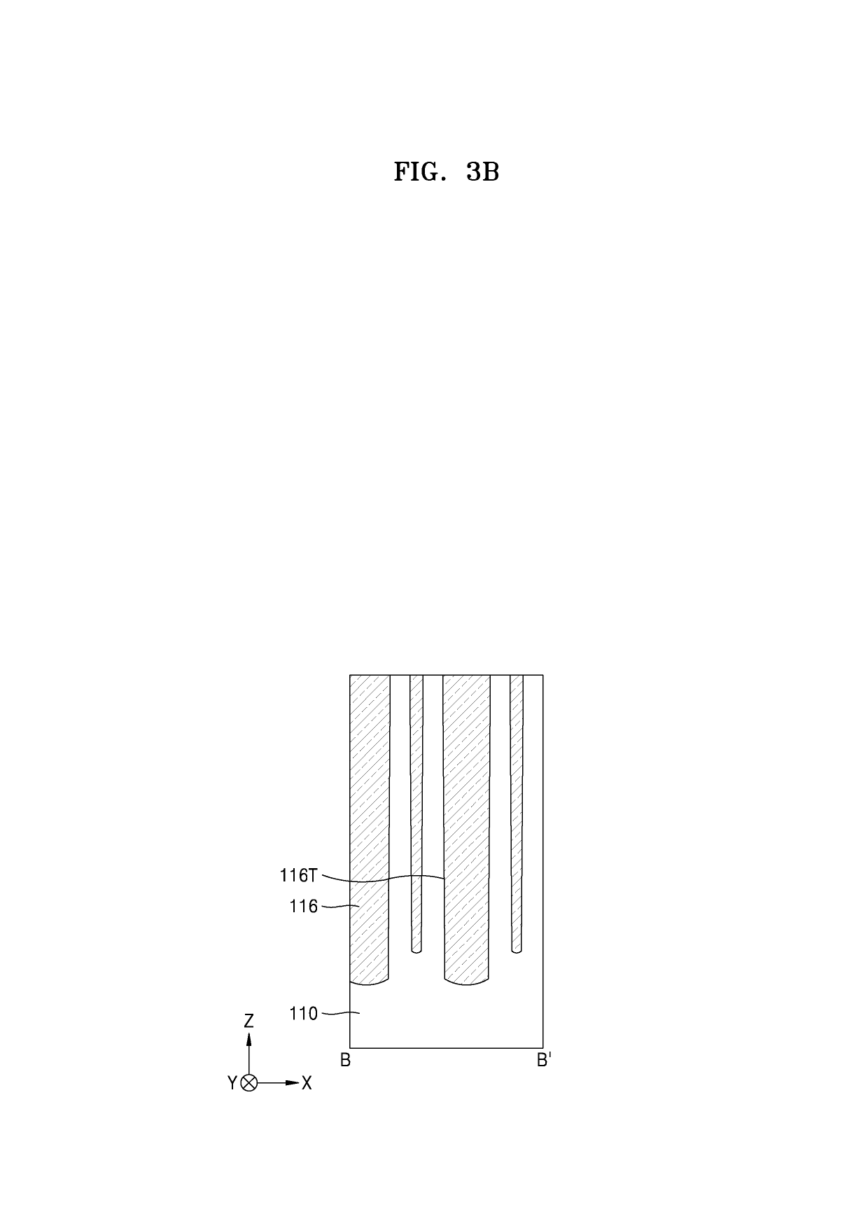

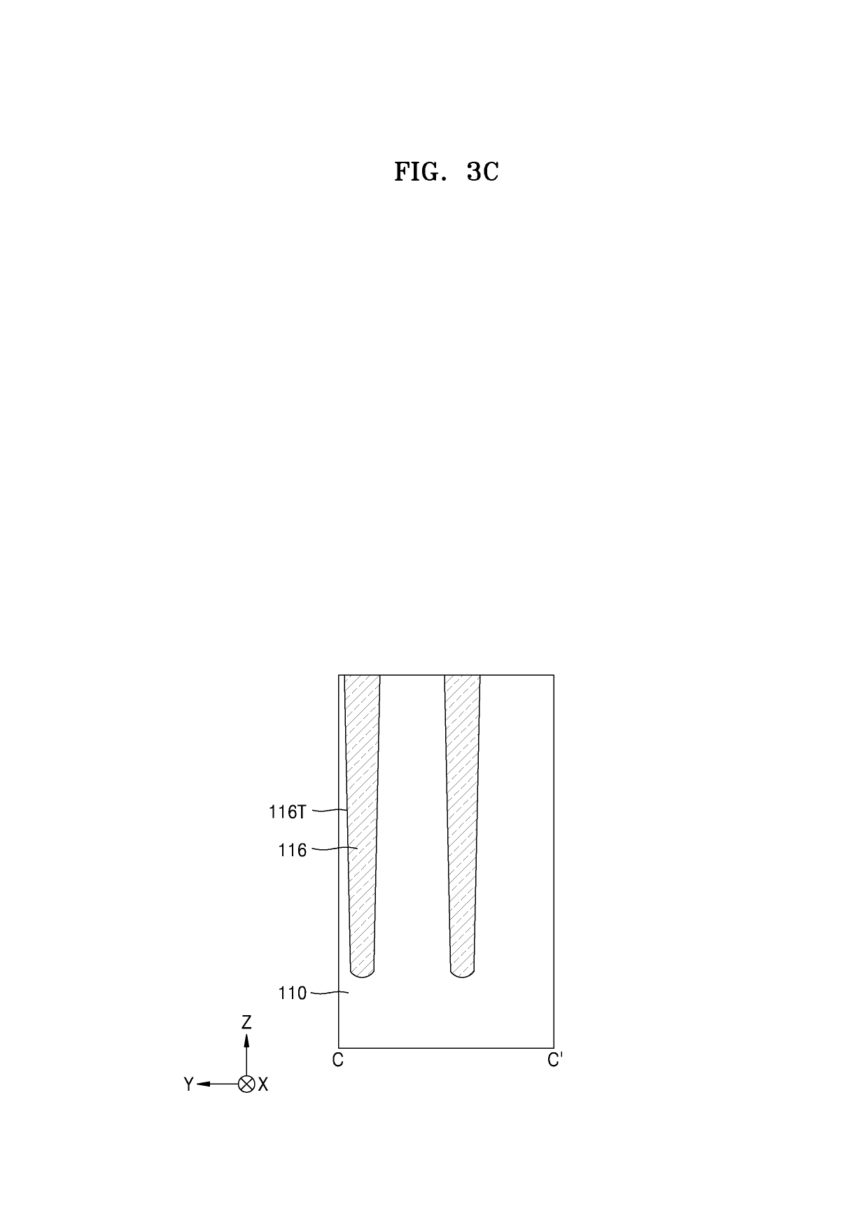

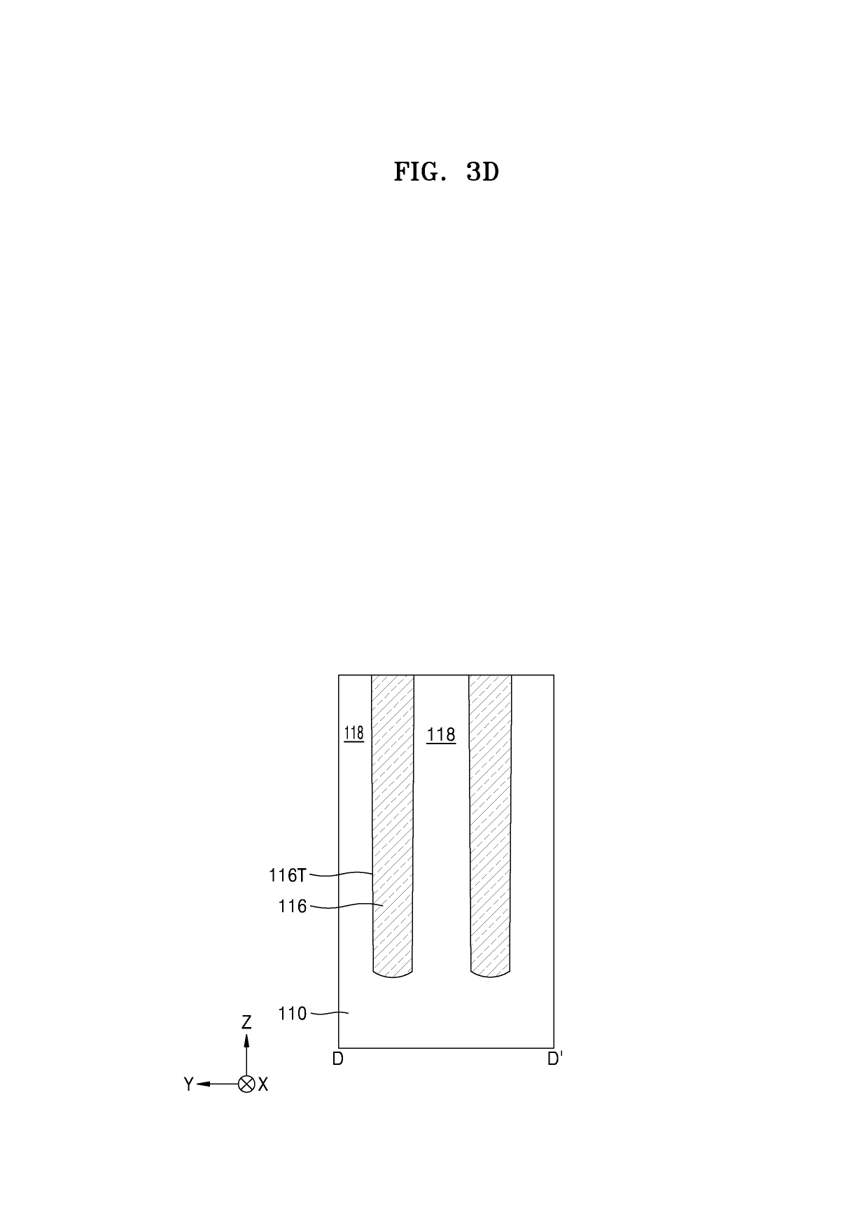

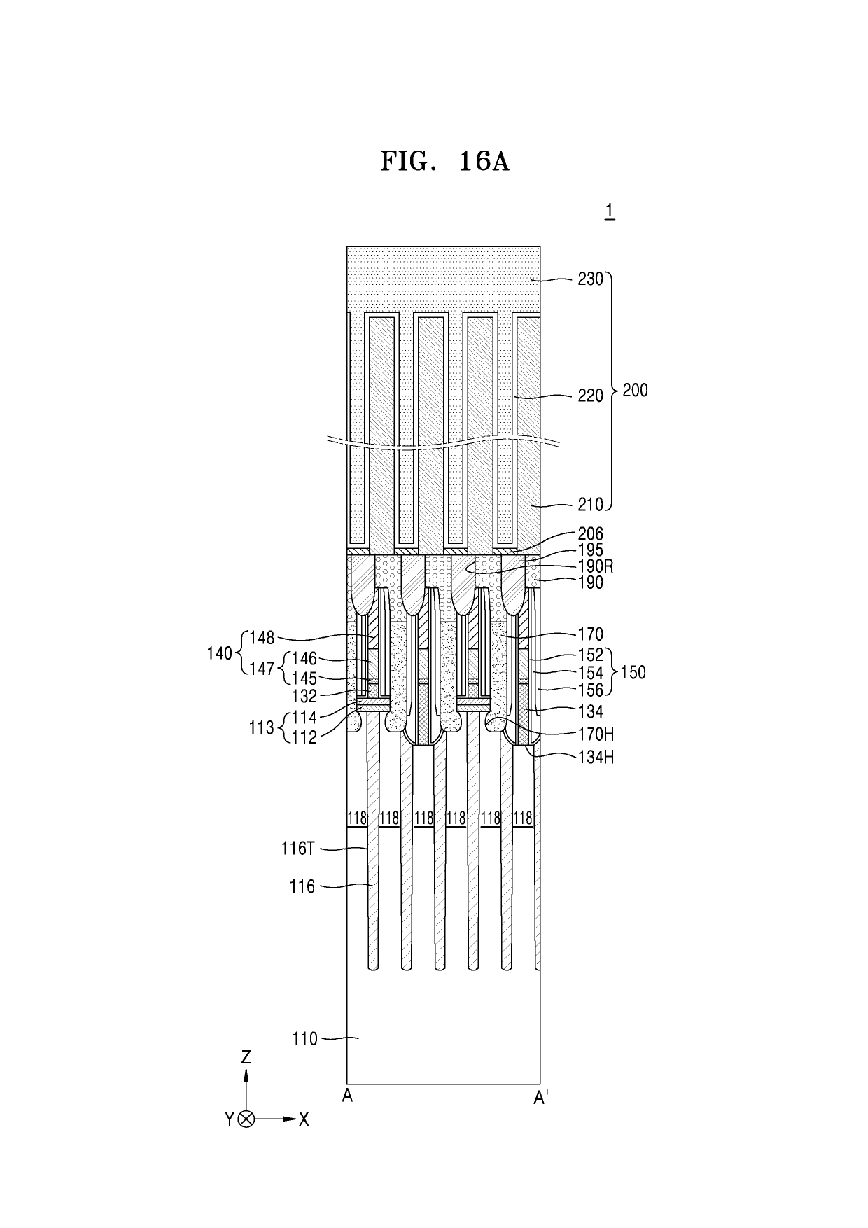

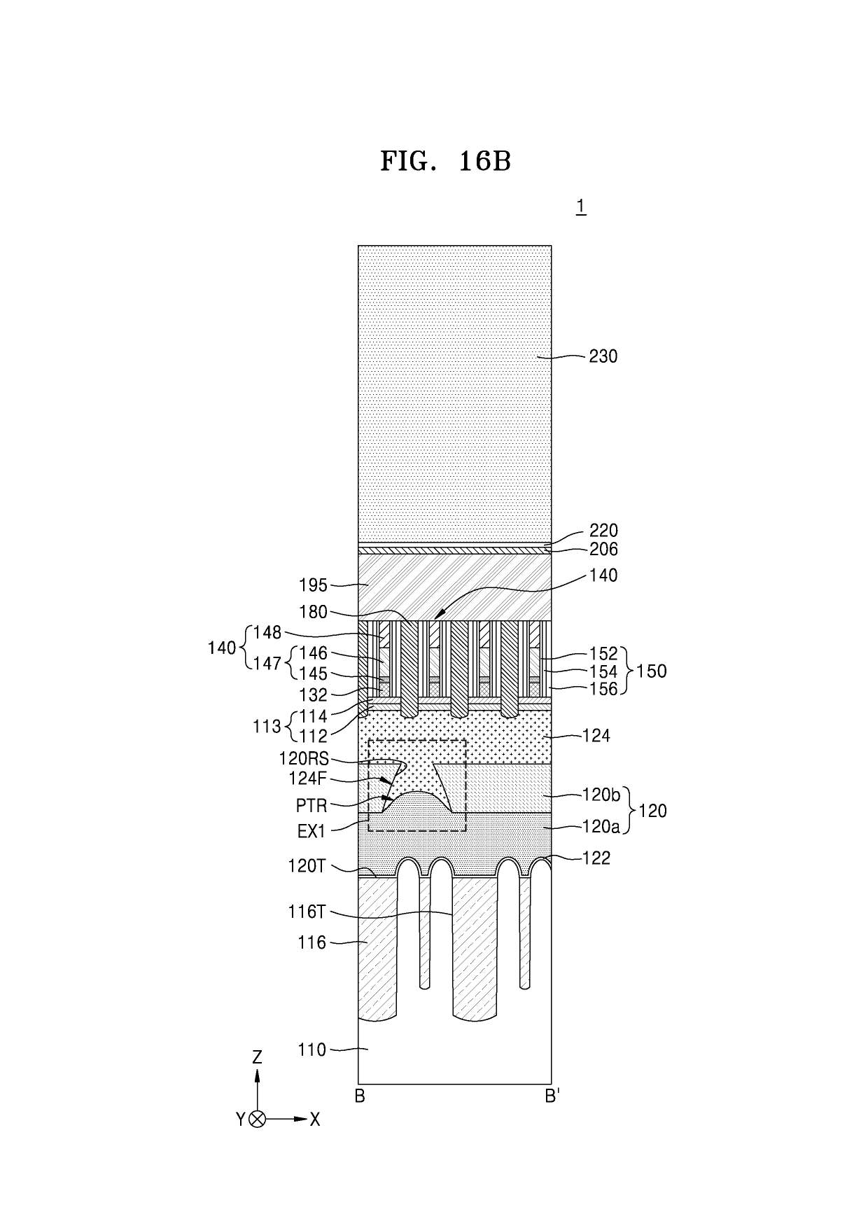

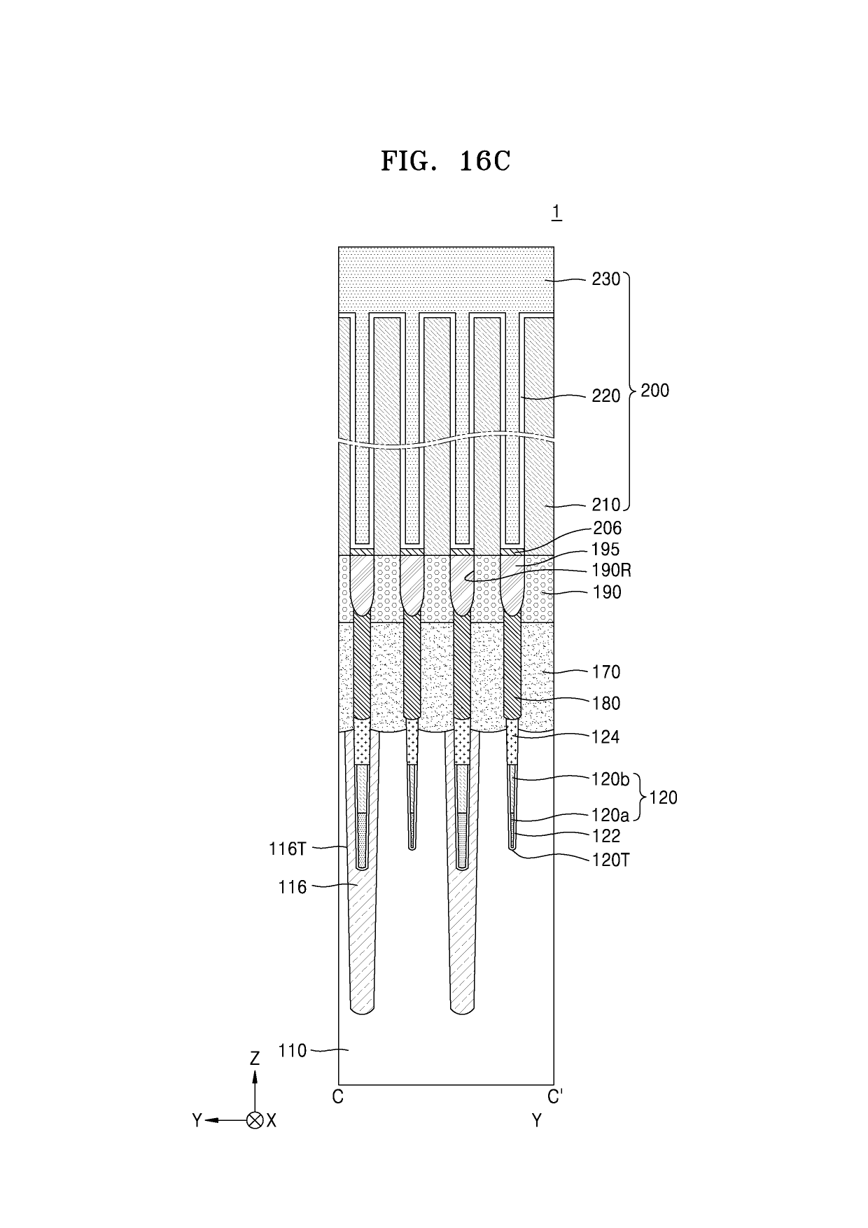

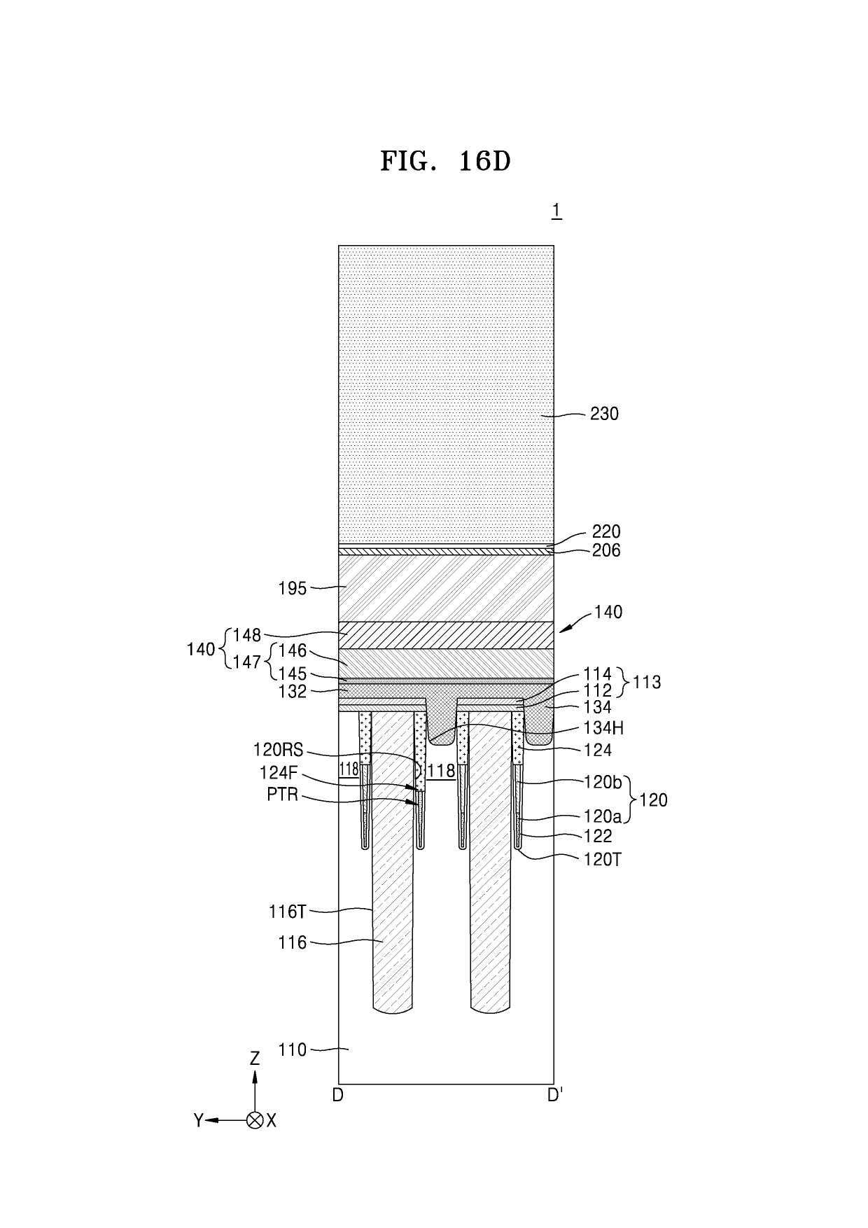

FIGS. 3A to 3D, FIGS. 4A to 4D, FIGS. 5A to 5D, FIGS. 6A to 6D, FIGS. 7A to 7D, FIGS. 8A to 8D, FIGS. 9A to 9D, FIGS. 10A to 10D, FIGS. 11A to 11D, FIGS. 12A to 12D, FIGS. 13A to 13D, FIGS. 14A to 14D, and FIGS. 15A to 15D are cross-sectional views for describing a method of manufacturing a semiconductor device, according to embodiments. FIGS. 16A to 16D are cross-sectional views for describing a semiconductor memory device, according to embodiments. In detail, FIGS. 3A, 4A, 5A, 6A, 7A, 8A, 9A, 10A, 11A, 12A, 13A, 14A, 15A, FIGS. and FIG.16A are cross-sectional views taken along line A-A’ of FIG. 2, FIGS. 3B, 4B, 5B, 6B, 7B, 8B, 9B, 10B, 11B, 12B, 13B, 14B, 15B, FIGS. and 16B are cross-sectional views taken along line B-B’ of FIG. 2, FIGS. 3C, 4C, 5C, 6C, 7C, 8C, 9C, 10C, 11C, 12C, 13C, 14C, 15C, FIGS. and 16C are cross-sectional view taken along line C-C’ of FIG. 2, and FIGS. 3D, 4D, 5D, 6D, 7D, 8D, 9D, 10D, 11D, 12D, 13D, 14D, 15D, FIGS. and 16D are cross-sectional views taken along line D-D’ of FIG. 2.

Referring to FIGS. 3A to 3D, a device isolation trench 116T may be formed in a substrate 110, and a device isolation film 116 filling the device isolation trench 116T may be formed. In the memory cell area CR, a plurality of active areas 118 may be defined in the substrate 110 by the device isolation trench 116T and the device isolation film 116.

The substrate 110 may include, for example, silicon (Si), crystalline Si, polycrystalline Si, or amorphous Si. In some embodiments, the substrate 110 may include a semiconductor element such as germanium (Ge), or at least one compound semiconductor selected from among silicon germanium (SiGe), silicon carbide (SiC), gallium arsenide (GaAs), indium arsenide (InAs), and indium phosphide (InP). In some embodiments, the substrate 110 may have a silicon-on-insulator (SOI) structure. For example, the substrate 110 may include a buried oxide layer (BOX). The substrate 110 may include a conductive region, for example, a well doped with impurities or a structure doped with impurities. The device isolation film 116 may be formed of a material including at least one of, for example, silicon oxide, silicon nitride, and silicon oxynitride. The device isolation film 116 may have a single-layer structure including one type of insulating film, a double-layer structure including two types of insulating films, or a multi-layer structure including at least three types of insulating films. For example, the device isolation film 116 may have a double-layer structure or a multi-layer structure including an oxide film and a nitride film. However, a configuration of the device isolation film 116 is not limited thereto.

The active area 118 may have a short axis and a long axis in a plan view, like the active area ACT of FIG. 2, and may have a relatively long island shape extending in a direction of the long axis. The plurality of active areas 118 may be arranged in columns in a diagonal direction with respect to the first horizontal direction (X direction) and the second horizontal direction (Y direction), and may be arranged in columns in the second horizontal direction (Y direction).

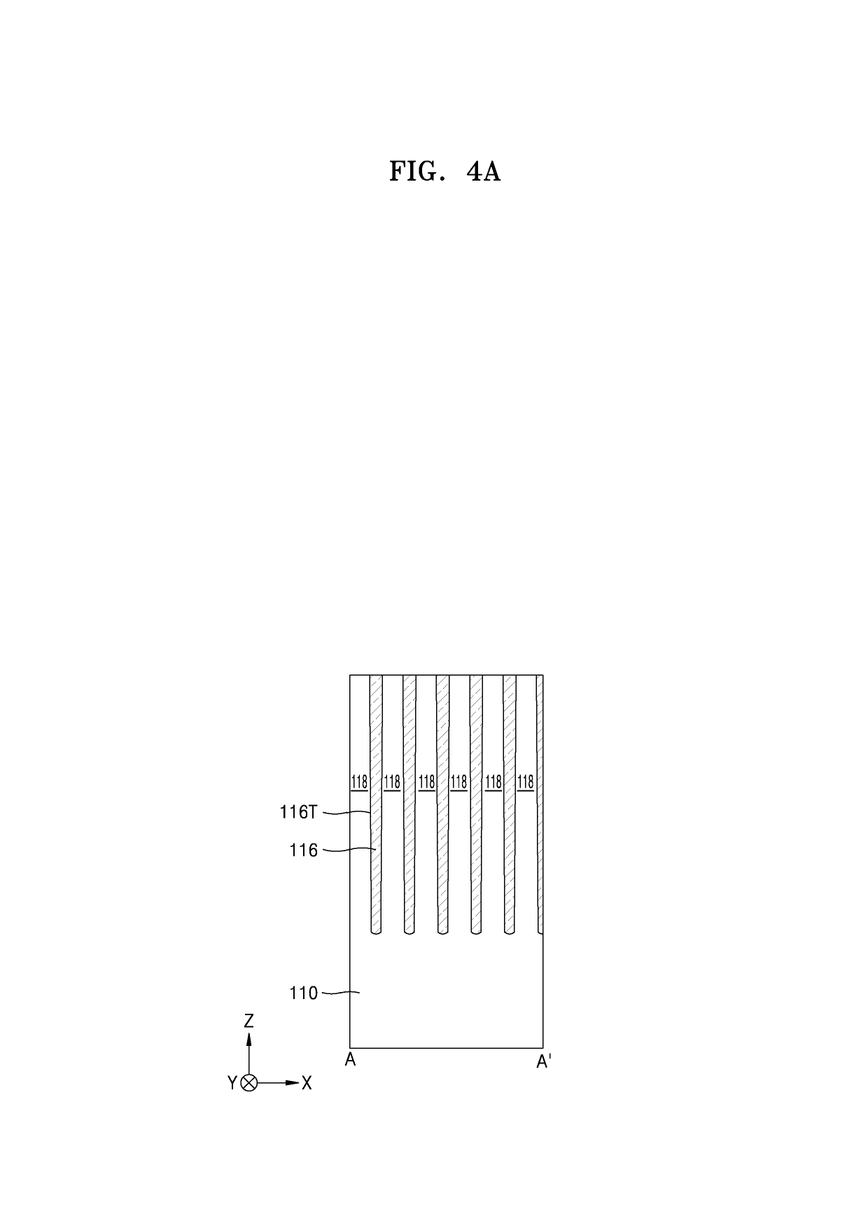

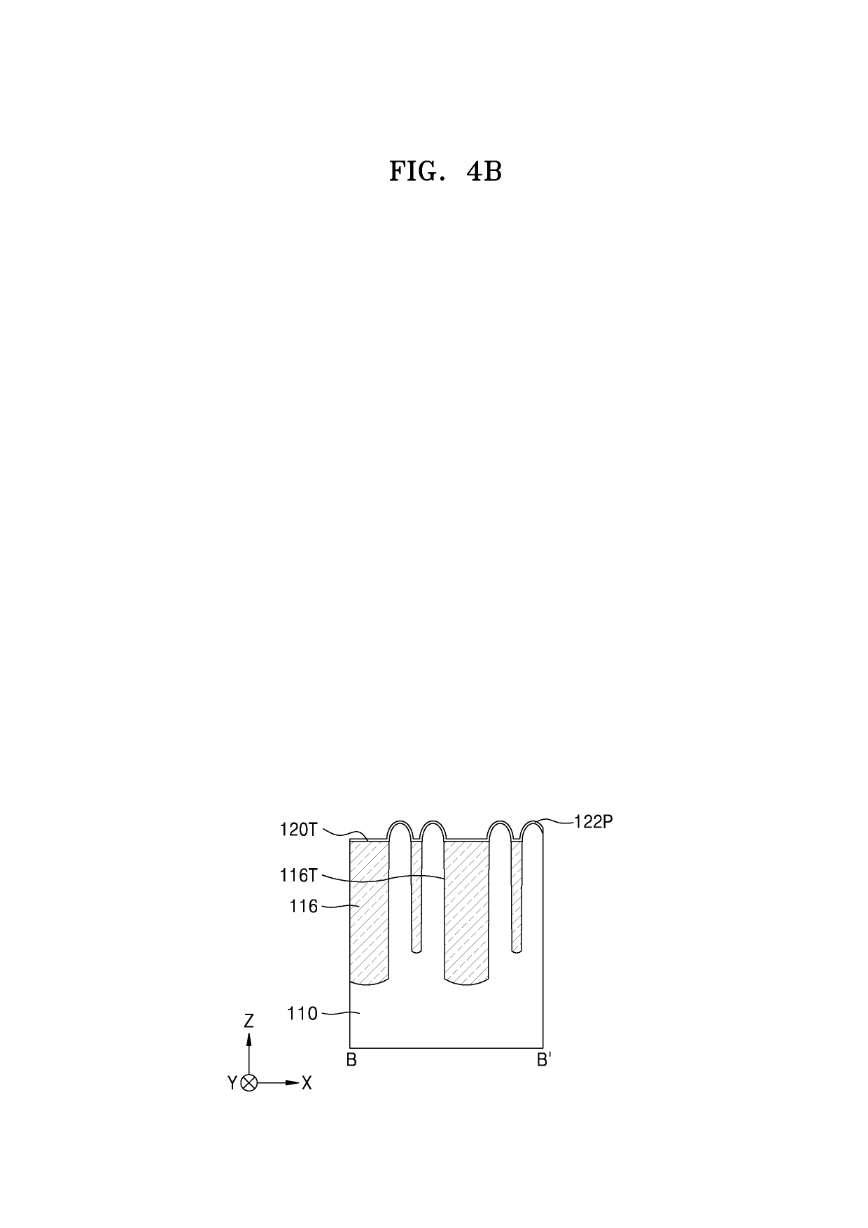

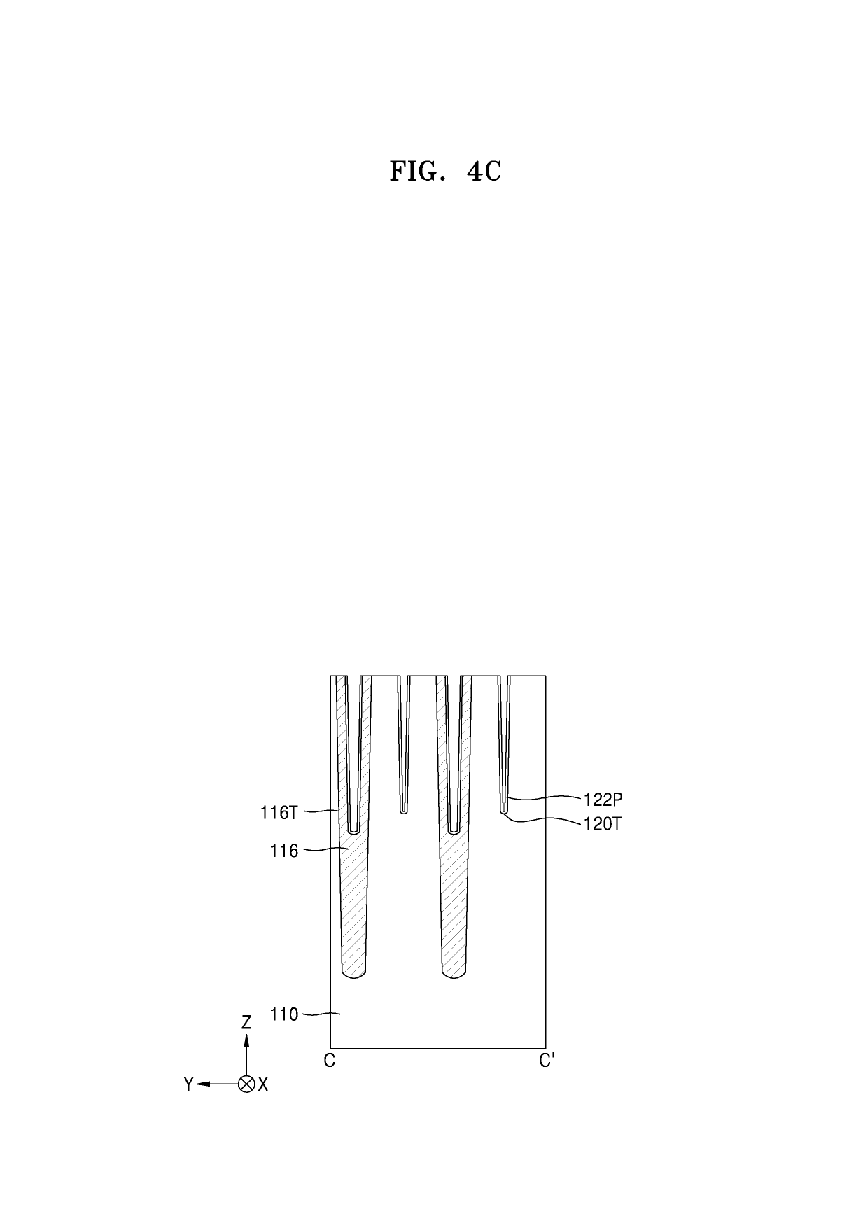

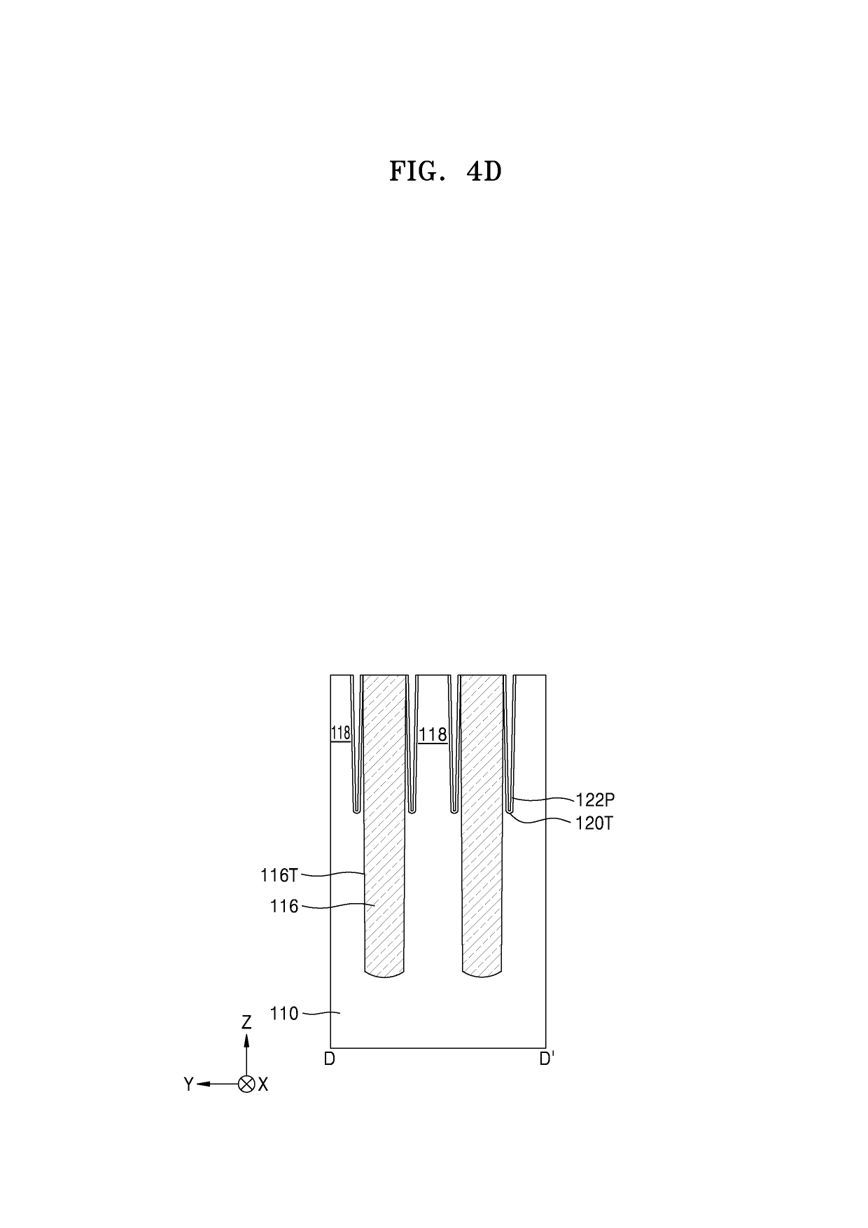

Referring to FIGS. 4A to 4D, a plurality of word line trenches 120T are formed in the substrate 110 by removing a portion of the active area 118 and a portion of the device isolation film 116. The plurality of word line trenches 120T may extend parallel to each other in the first horizontal direction (X direction), and may each have a line shape that crosses the active area 118 and is disposed to have a substantially equal interval along the second horizontal direction (Y direction). In some embodiments, a stepped portion may be formed on a bottom surface of each of the plurality of word line trenches 120T.

Next, a dielectric material layer 122P covering inner surfaces of the plurality of word line trenches 120T is formed. The dielectric material layer 122P may be formed conformably on a surface of the substrate 110 exposed at bottom surfaces and side surfaces of the plurality of word line trenches 120T. The dielectric material layer 122P may be formed of at least one selected from among silicon oxide, silicon nitride, silicon oxynitride, oxide/nitride/oxide (ONO), and a high-k dielectric material having a dielectric constant higher than that of silicon oxide. For example, the dielectric material layer 122P may have a dielectric constant of about 10 to 25. For example, the high-k dielectric material may be formed of at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

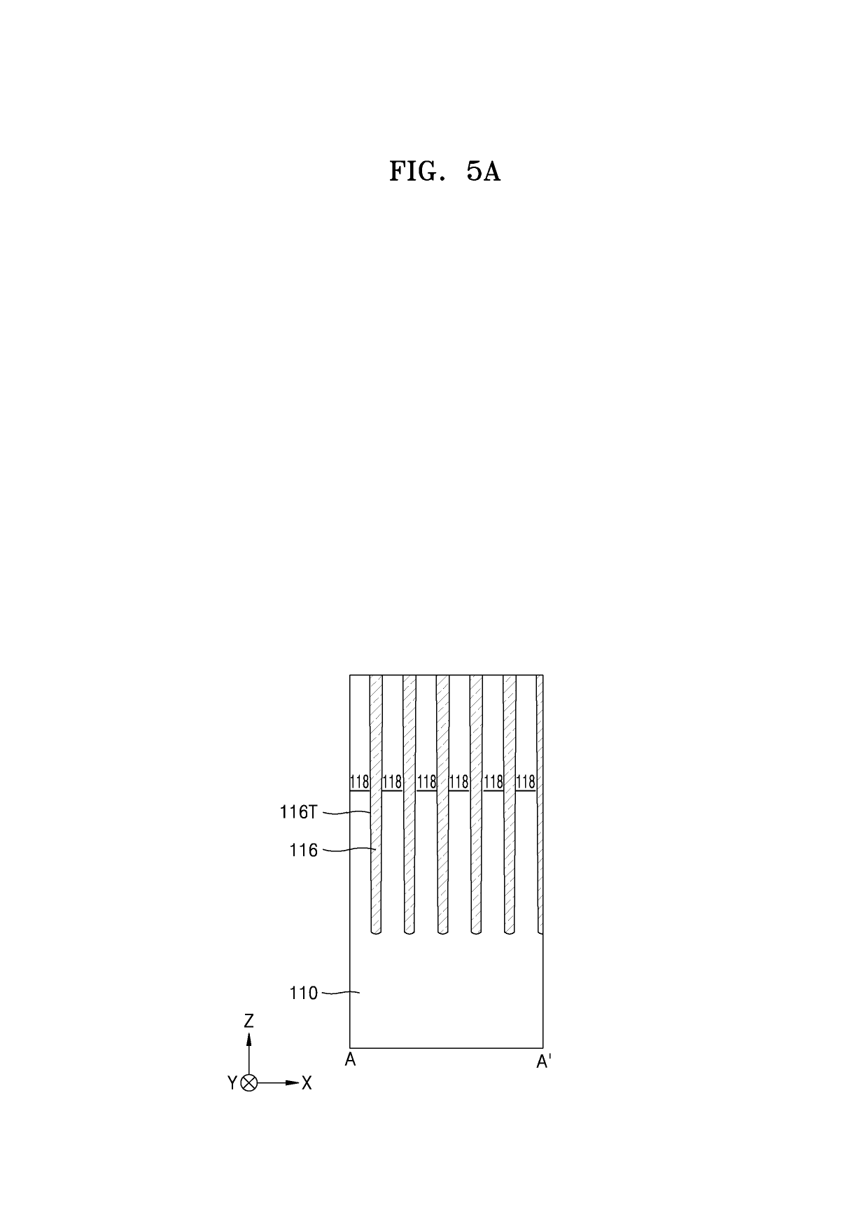

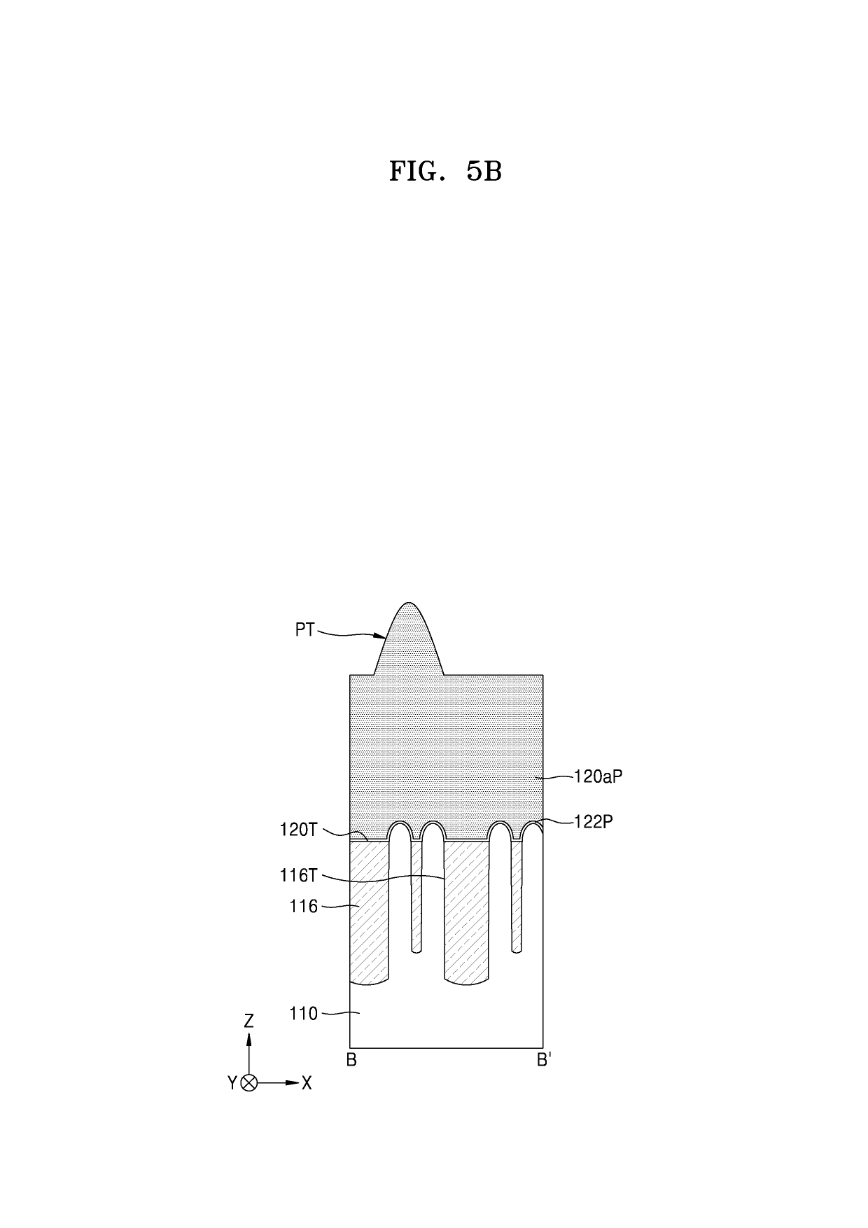

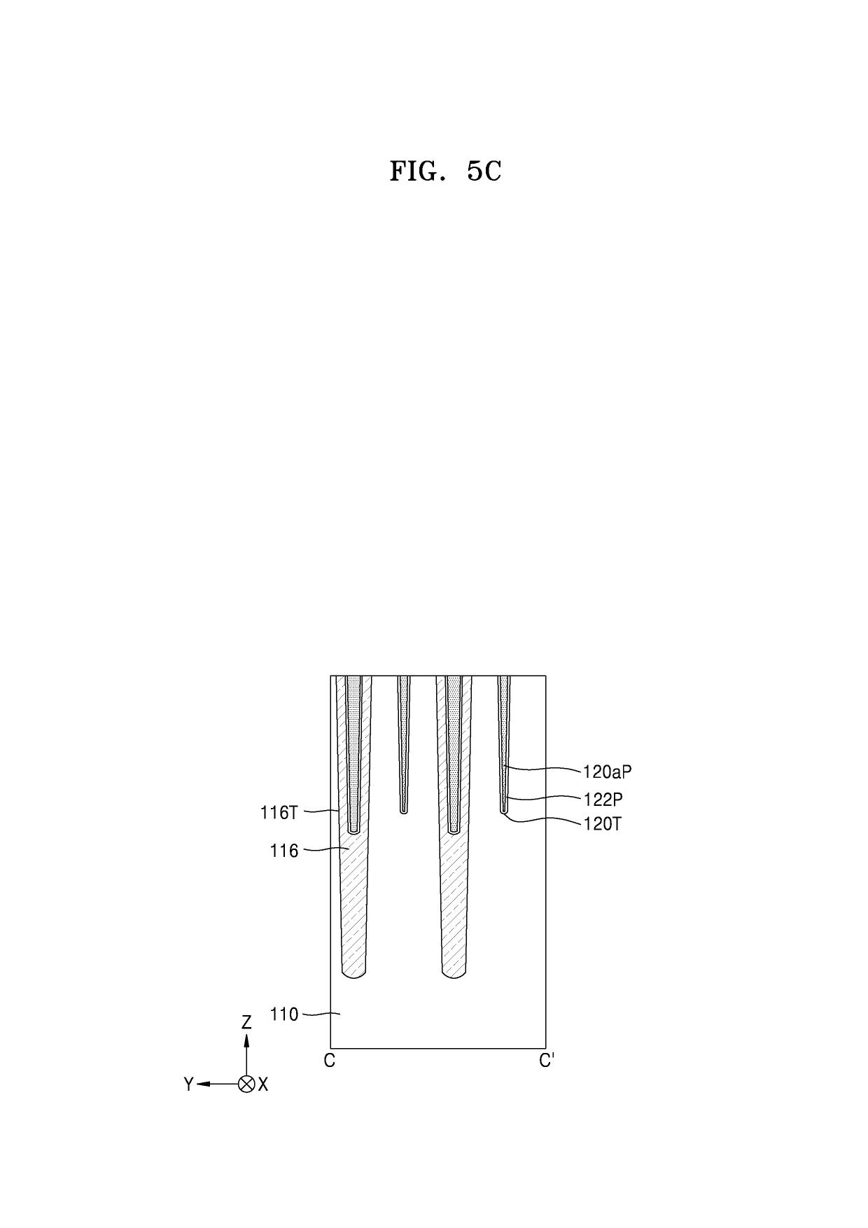

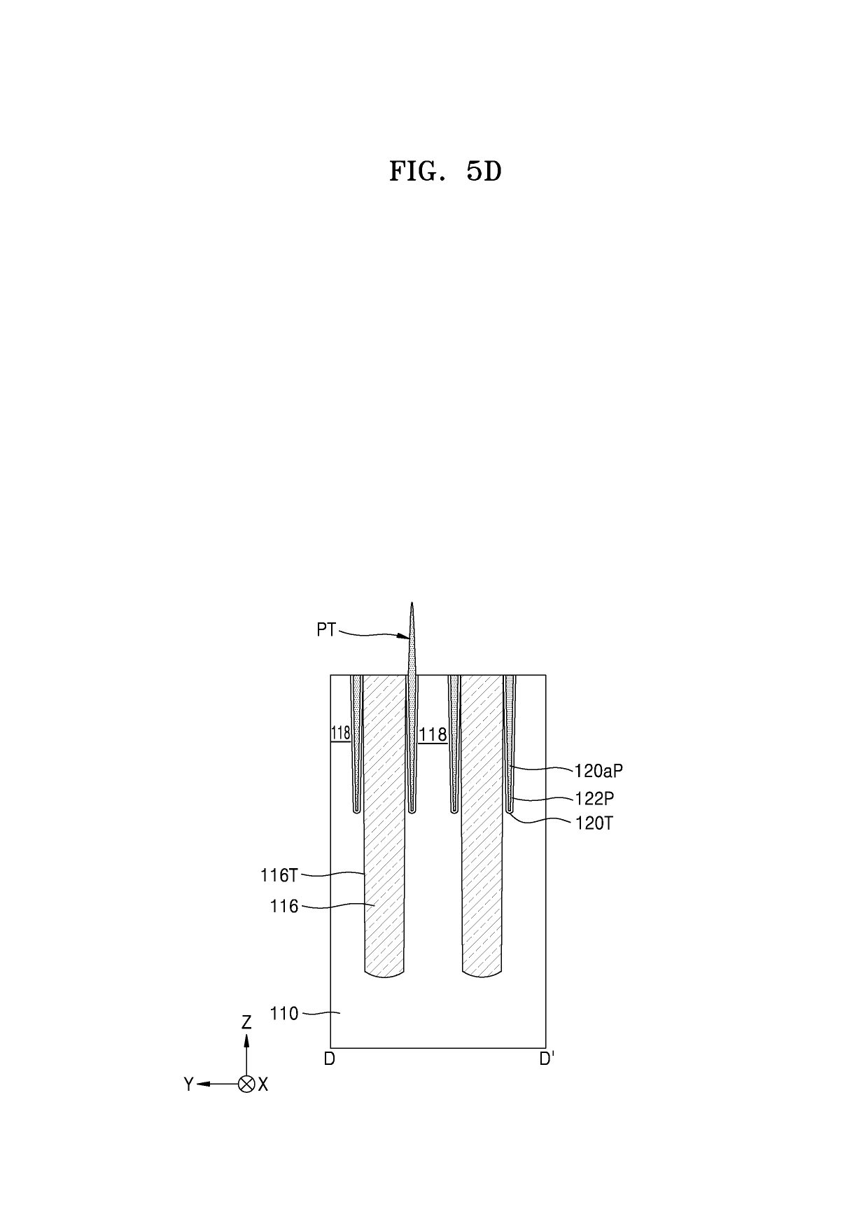

Referring to FIGS. 5A to 5D, a first preliminary conductive layer 120aP filling at least a portion of each of the plurality of word line trenches 120T is formed. The first preliminary conductive layer 120aP may be formed by using a deposition process such as chemical vapor deposition (CVD), plasma enhanced CVD (PECVD), or atomic layer deposition (ALD). The first preliminary conductive layer 120aP may include a material containing metal atoms. For example, the first preliminary conductive layer 120aP may be formed of a metal, conductive metal nitride, or a combination thereof. In some embodiments, the first preliminary conductive layer 120aP may be formed of Ti, TiN, Ta, TaN, W, WN, TiSiN, WSiN, Mo, or a combination thereof.

The first preliminary conductive layer 120aP may include a defect PT. The defect PT may be formed due to particles or abnormal growth occurring in a process of forming the first preliminary conductive layer 120aP. The defect PT may protrude upward in a vertical direction (Z direction) more than other portions of the first preliminary conductive layer 120aP. Although top surfaces of portions of the first preliminary conductive layer 120aP other than the defect PT are at the same vertical level as a top surface of the substrate 110 in FIGS. 5B to 5D, this is only an example and embodiments are not limited thereto. In some embodiments, the first preliminary conductive layer 120aP may cover a top surface of the substrate 110. For example, top surfaces of portions of the first preliminary conductive layer 120aP other than the defect PT may be at a higher vertical level than a top surface of the substrate 110.

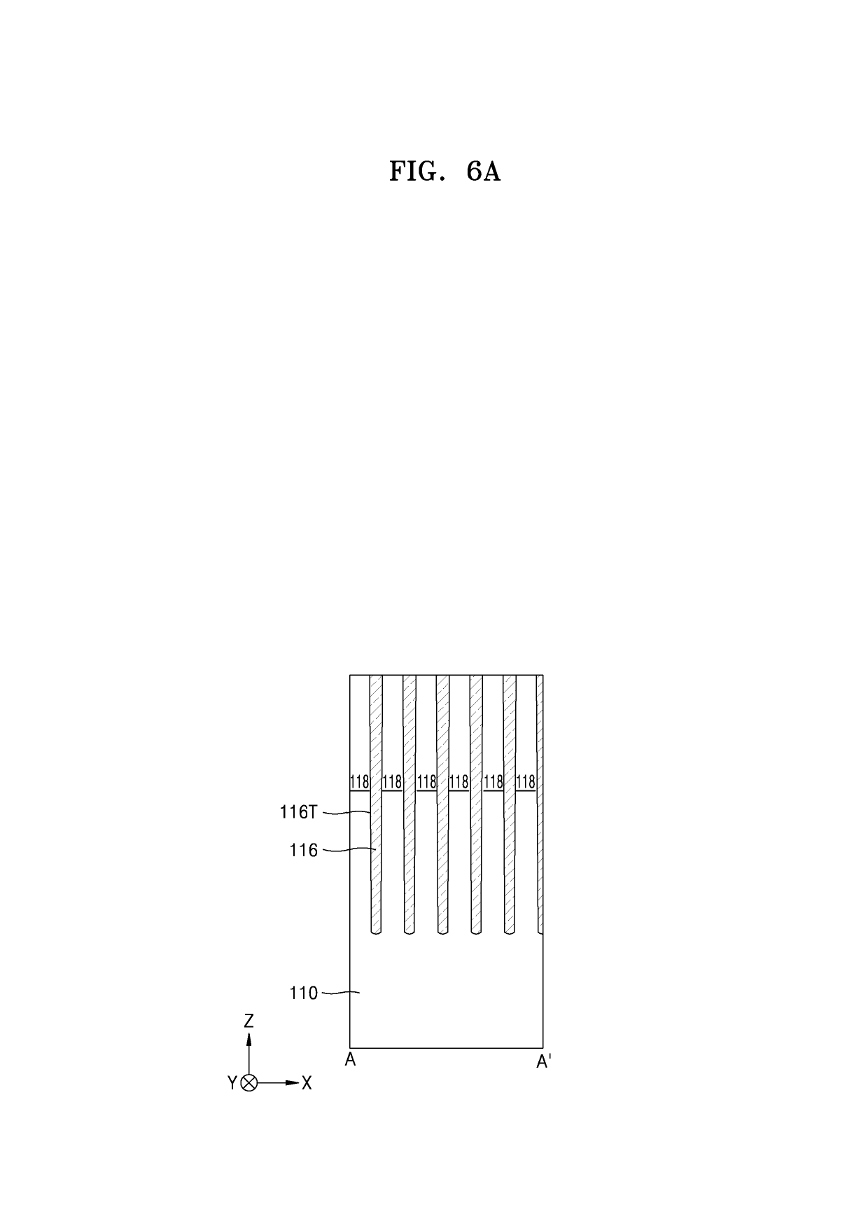

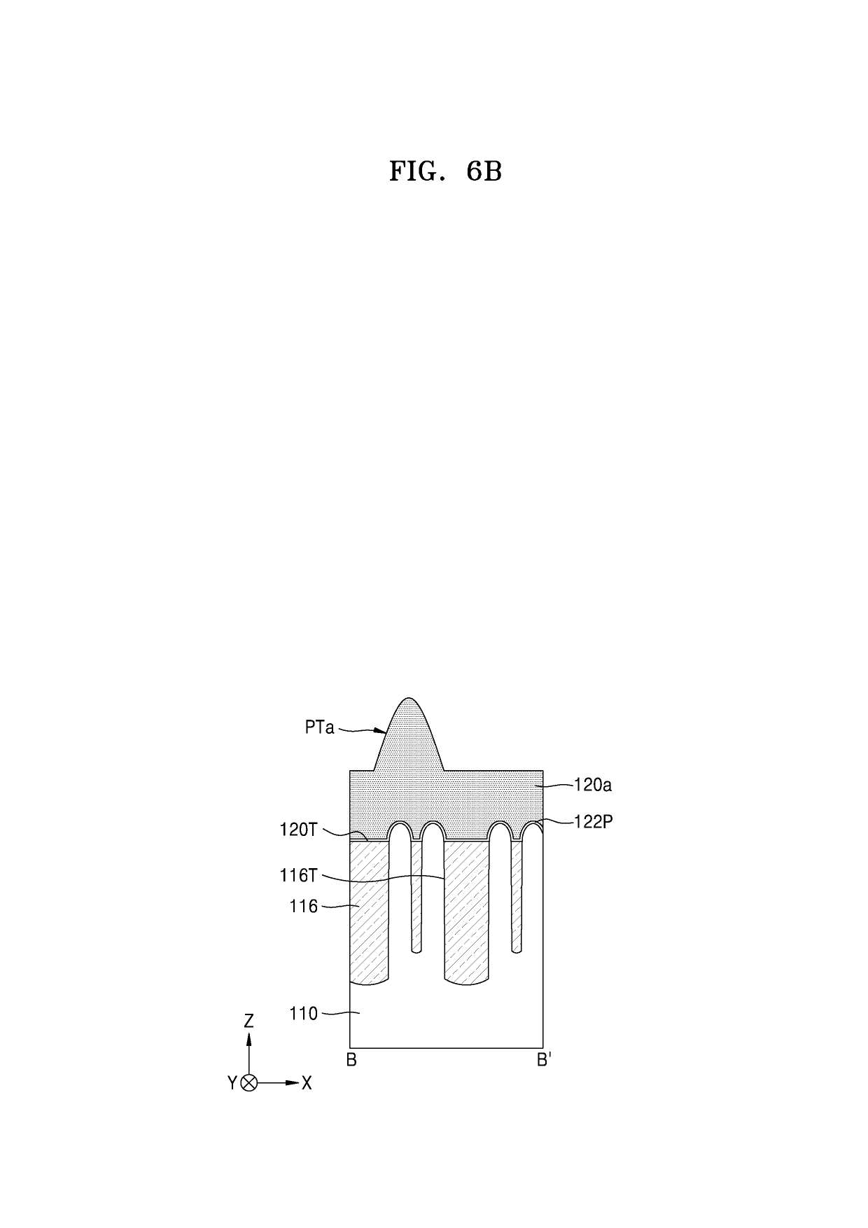

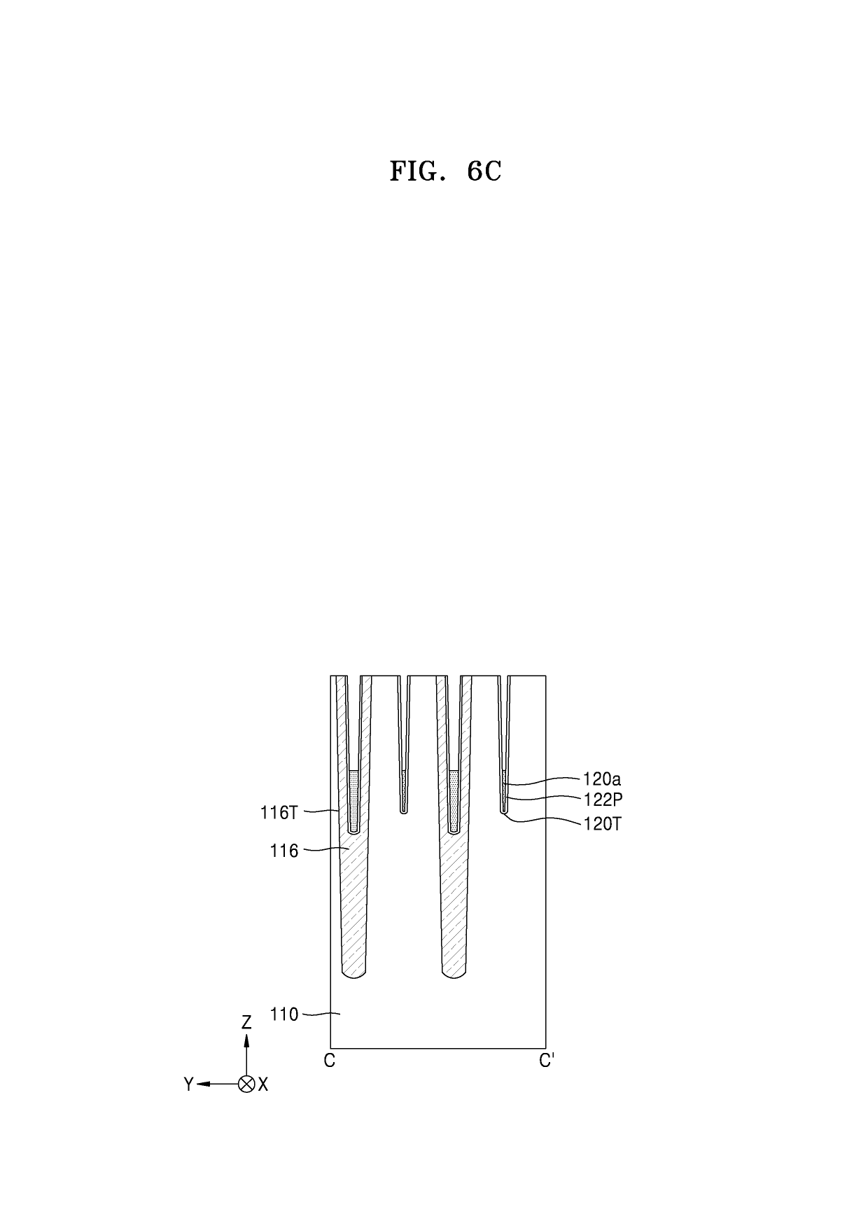

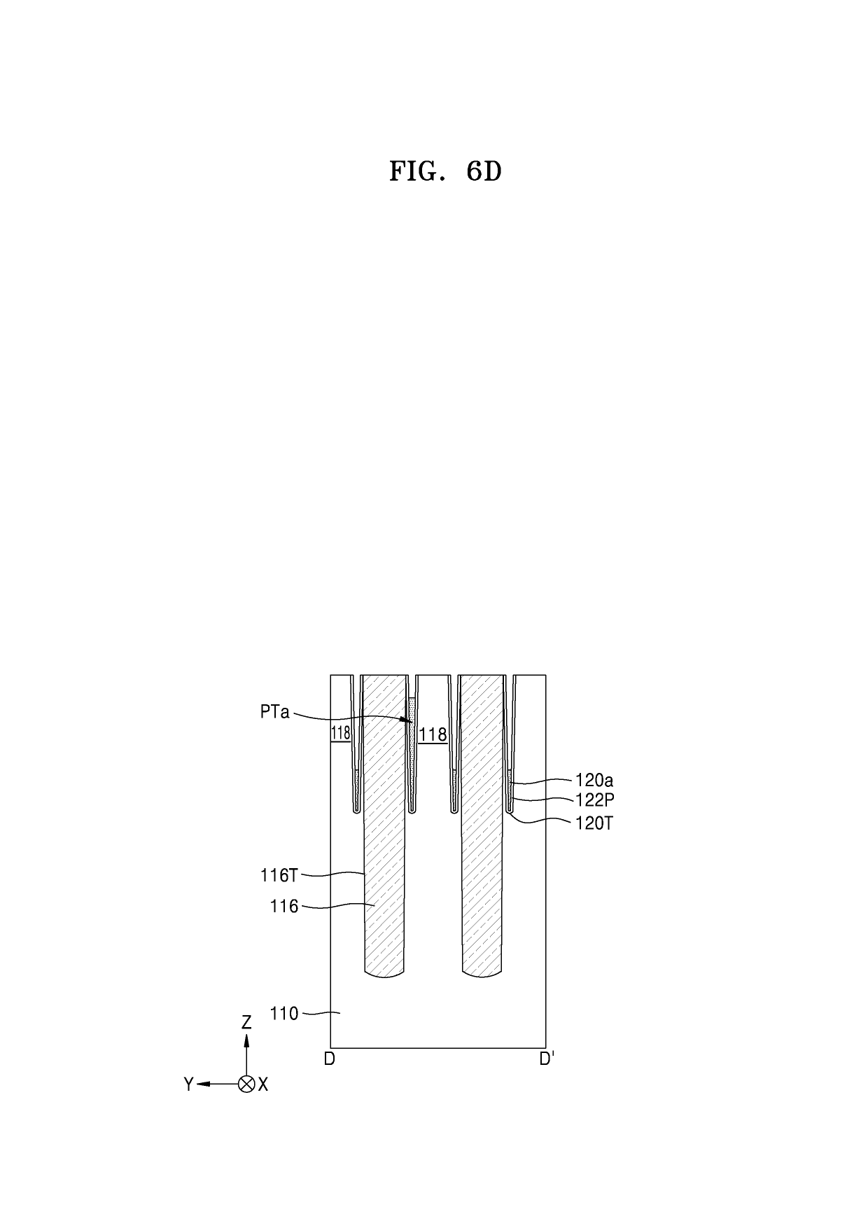

Referring to FIGS. 5A to 5D and FIGS. 6A to 6D, an upper portion of the first preliminary conductive layer 120aP is removed to form a plurality of lower word line layers 120a filling lower portions of the plurality of word line trenches 120T. The plurality of lower word line layers 120a may be formed by removing an upper portion of the first preliminary conductive layer 120aP by performing an anisotropic dry etching process. The plurality of lower word line layers 120a may be formed by removing an upper portion of the first preliminary conductive layer 120aP by performing an anisotropic dry etching processing having a high etch selectivity of the first preliminary conductive layer 120aP with respect to the substrate 110. An anisotropic dry etching process of removing an upper portion of the first preliminary conductive layer 120aP in order to form the plurality of lower word line layers 120a may be referred to as a first etching process, a first dry etching process, a first anisotropic etching process, or a first anisotropic dry etching process.

At least some of the plurality of lower word line layers 120a may include a defect PTa. The defect PTa may be formed when the defect PT included in the first preliminary conductive layer 120aP is transferred in a process of removing an upper portion of the first preliminary conductive layer 120aP. The defect PTa may protrude upward in the vertical direction (Z direction) more than other portions of the lower word line layer 120a. Each of the plurality of lower word line layers 120a may be formed of a material containing metal atoms. For example, each of the plurality of lower word line layers 120a may be formed of a metal, conductive metal nitride, or a combination thereof. In some embodiments, each of the plurality of lower word line layers 120a may be formed of Ti, TiN, Ta, TaN, W, WN, TiSiN, WSiN, or a combination thereof.

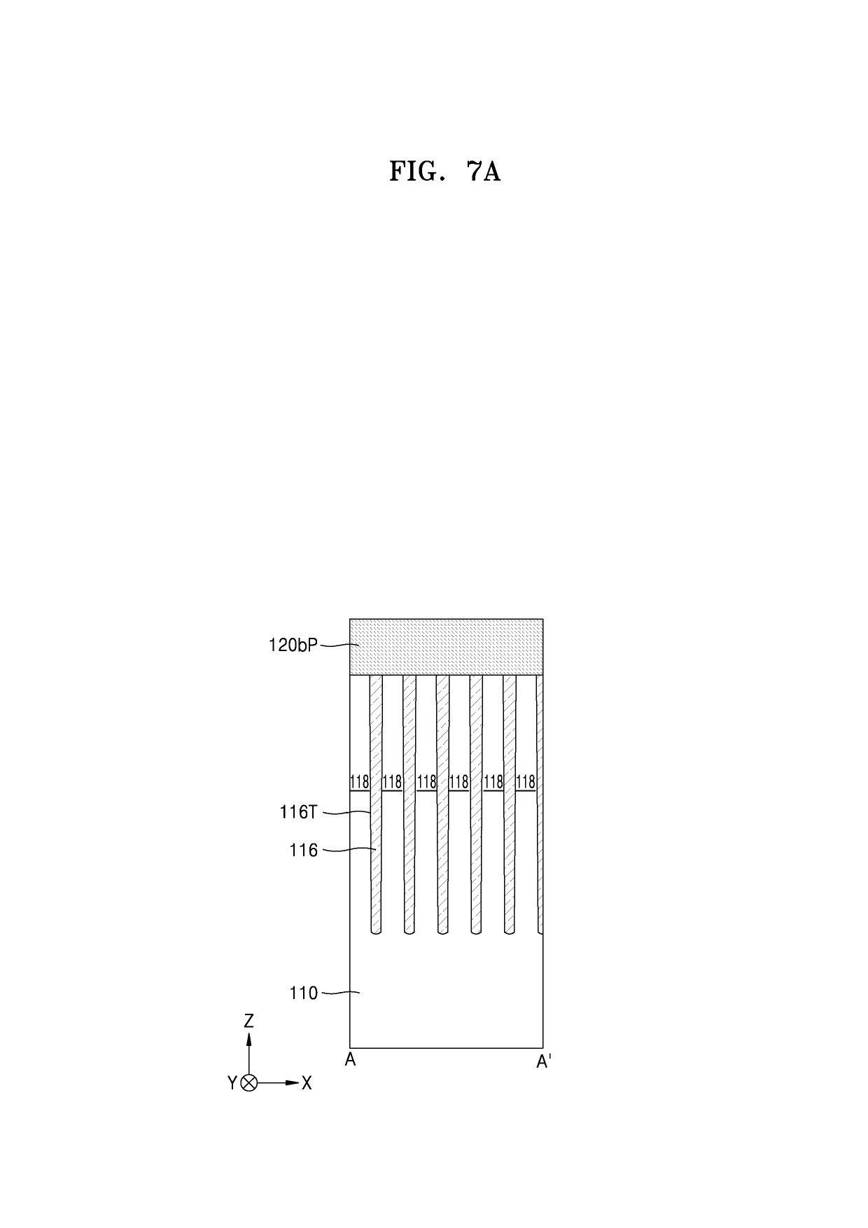

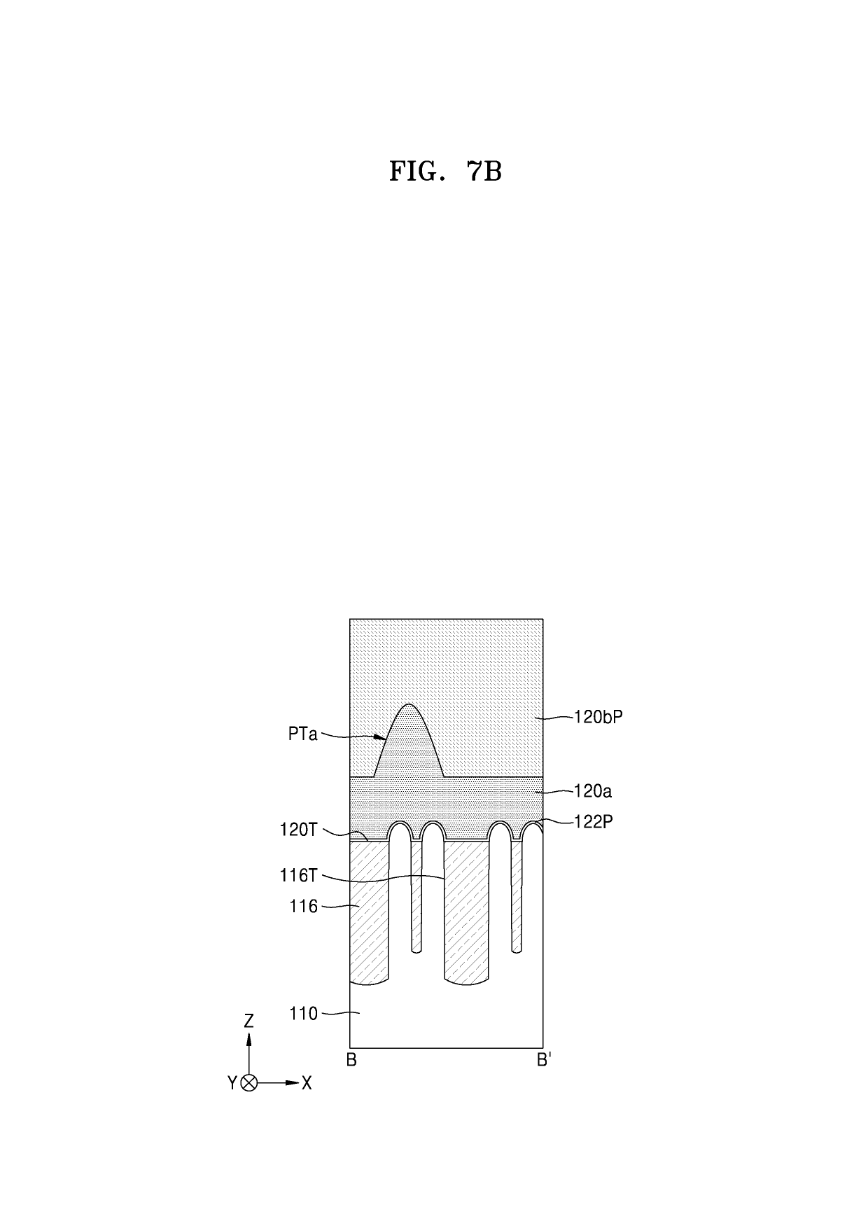

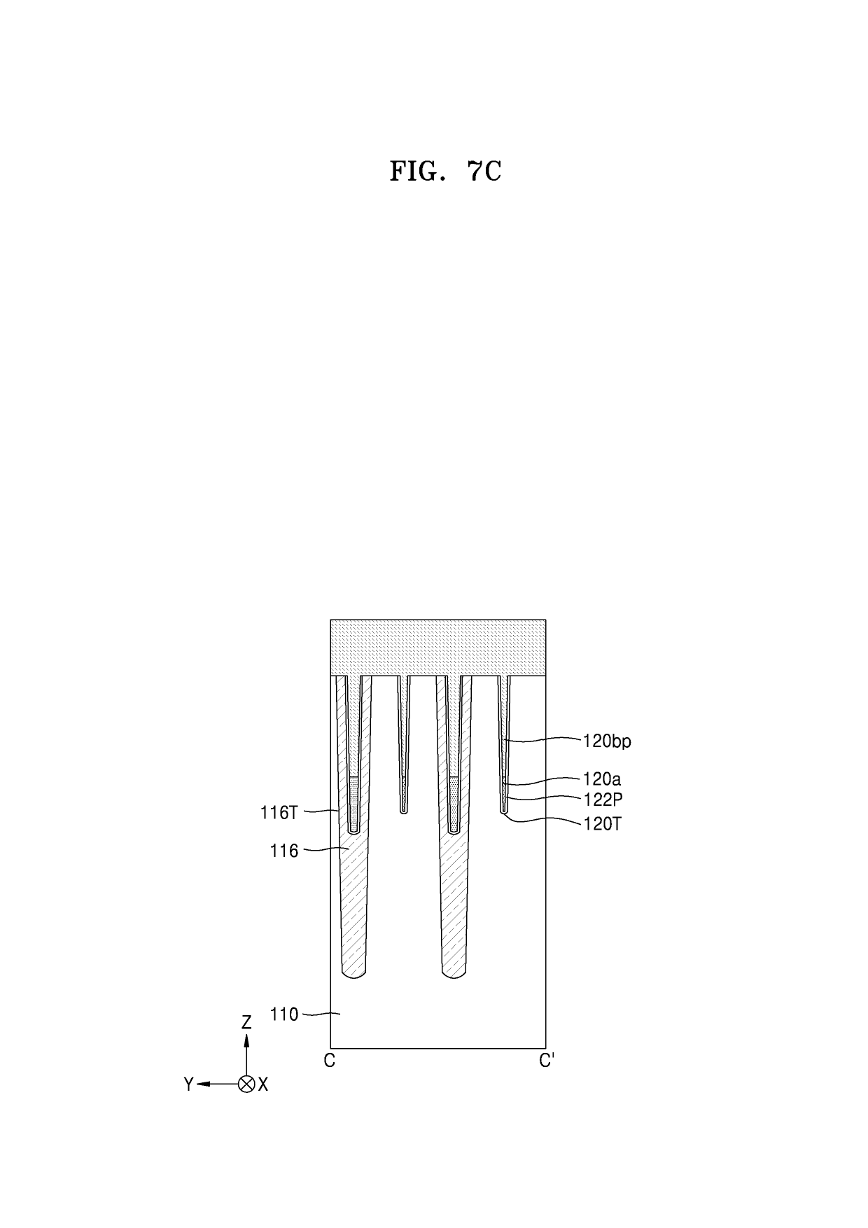

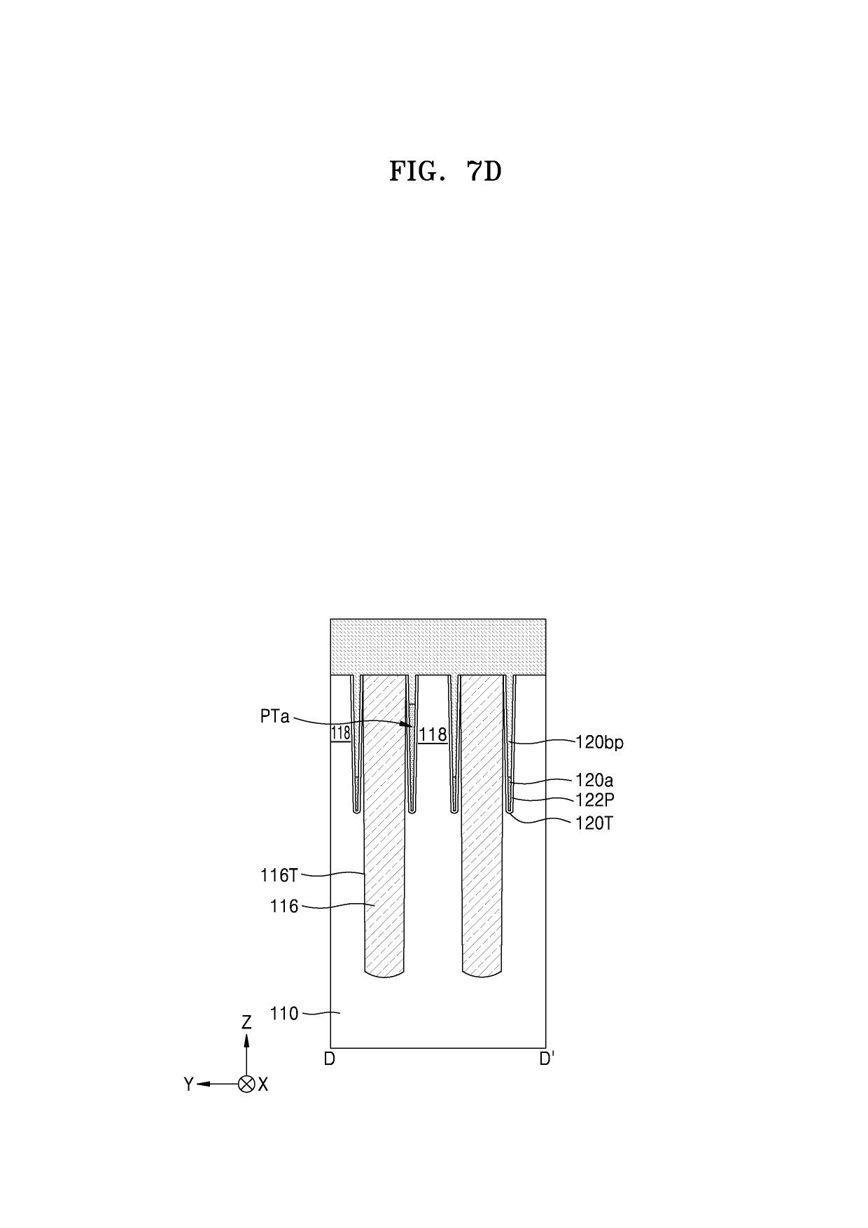

Referring to FIGS. 7A to 7D, a second preliminary conductive layer 120bP covering the plurality of lower word line layers 120a and filling the plurality of word line trenches 120T is formed. The second preliminary conductive layer 120bP may be formed by using a deposition process such as CVD, PECVD, or ALD. The second preliminary conductive layer 120bP may include a semiconductor material. For example, the second preliminary conductive layer 120bP may be formed of doped polysilicon. The second preliminary conductive layer 120bP may cover the defect PTa included in the plurality of lower word line layers 120a. In some embodiments, the second preliminary conductive layer 120bP may fill all of the plurality of word line trenches 120T and may cover a top surface of the substrate 110. The second preliminary conductive layer 120bP may have a planar upper surface. Along the vertical direction (Z direction), the second preliminary conductive layer 120bP may be thinner at portions that overlap the defect PTa.

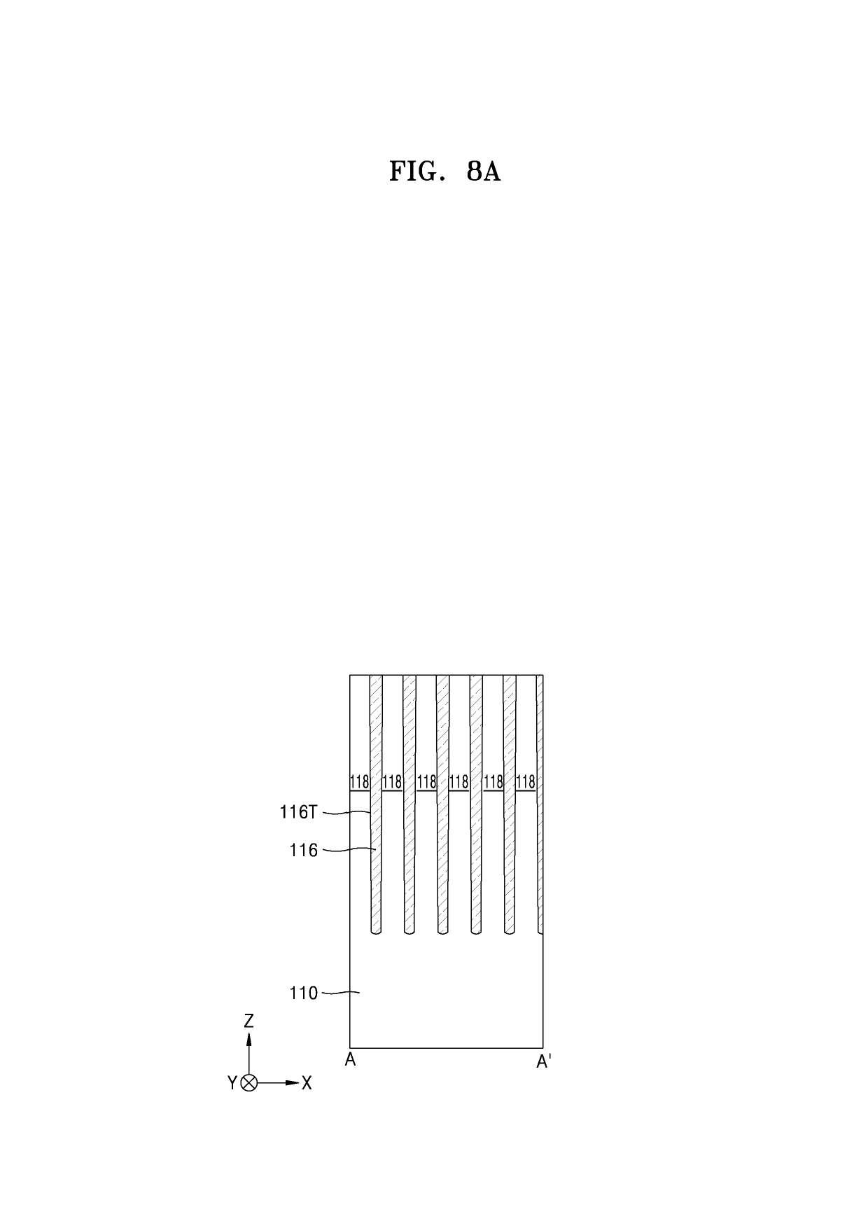

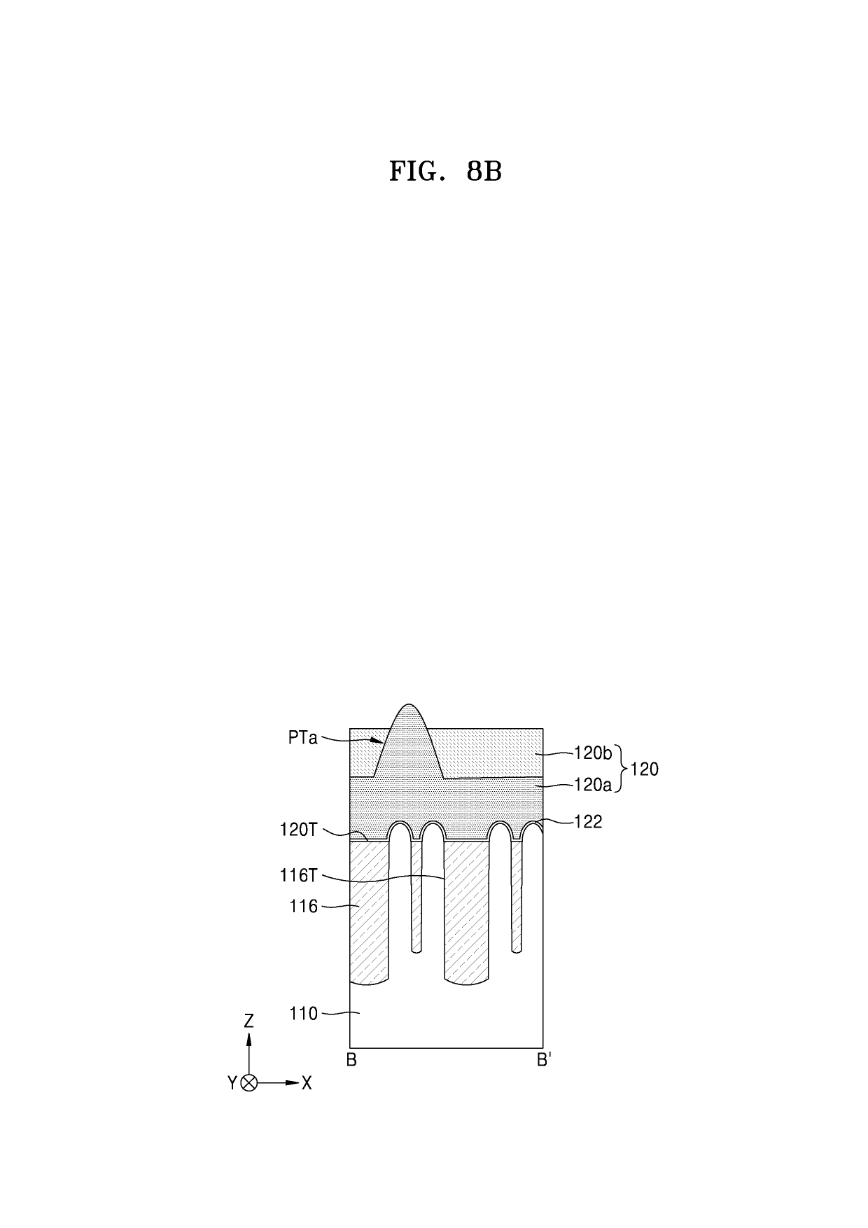

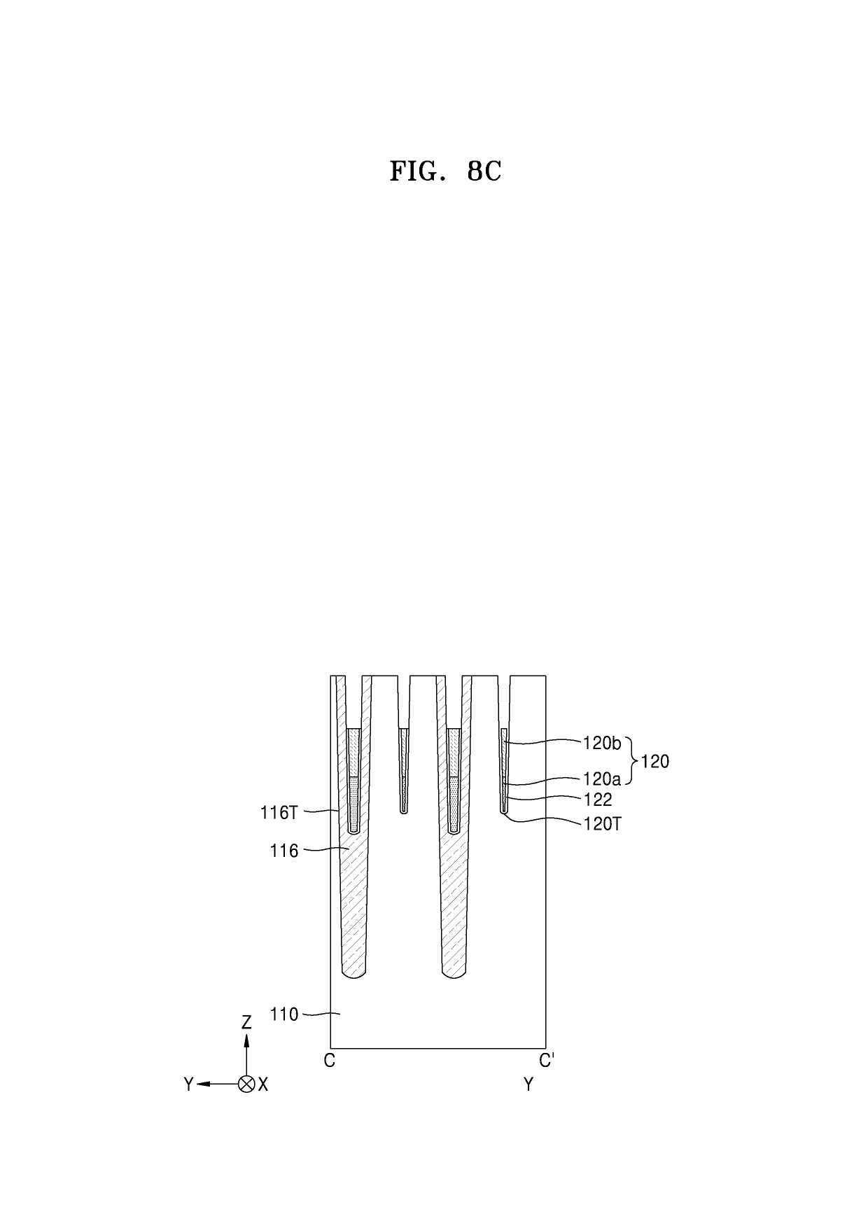

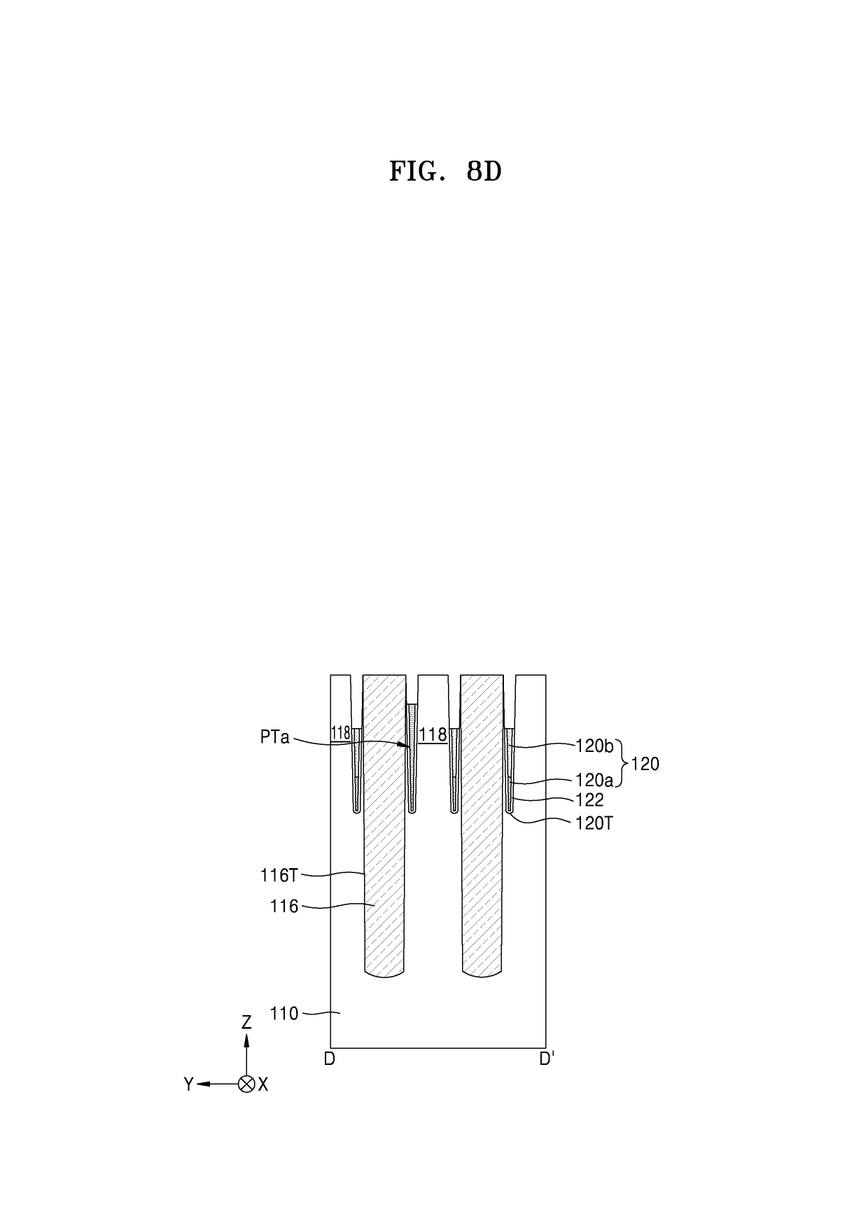

Referring to FIGS. 7A to 7D and 8A to 8D, an upper portion of the second preliminary conductive layer 120bP is removed to form a plurality of upper word line layers 120b on the plurality of lower word line layers 120a and filling portions of the plurality of word line trenches 120T. The plurality of lower word line layers 120a and the plurality of upper word line layers 120b may constitute a plurality of word lines 120. The plurality of word lines 120 may constitute the plurality of word lines WL of FIG. 2. For example, each of the plurality of word lines 120 may have a stacked structure including the lower word line layer 120a and the upper word line layer 120b. The plurality of word lines 120 each having a stacked structure including the lower word line layer 120a and the upper word line layer 120b may extend parallel to each other in the first horizontal direction (X direction). The plurality of word lines 120 may extend parallel to each other in the first horizontal direction (X direction), and may each have a line shape that crosses the active area 118 and is disposed to have a substantially equal interval along the second horizontal direction (Y direction). A top surface of each of the plurality of word lines 120 may be at a lower level than a top surface of the substrate 110. Bottom surfaces of the plurality of word lines 120 may have an uneven shape, and a saddle fin-type transistor FinFET may be formed in the plurality of active areas 118. The plurality of upper word line layers 120b may be formed by removing an upper portion of the second preliminary conductive layer 120bP by performing an anisotropic dry etching process. Each of the plurality of upper word line layers 120b may include a semiconductor material. For example, each of the plurality of upper word line layers 120b may be formed of doped polysilicon. The plurality of upper word line layers 120b may be formed by removing an upper portion of the second preliminary conductive layer 120bP by performing an anisotropic dry etching process having a high etch selectivity of the second preliminary conductive layer 120bP with respect to the lower word line layer 120a. An anisotropic dry etching process of removing an upper portion of the second preliminary conductive layer 120bP in order to form the plurality of upper word line layers 120b may be referred to as a second etching process, a second dry etching process, a second anisotropic etching process, or a second anisotropic dry etching process.

A source region and a drain region may be formed in the plurality of active areas 118 by injecting impurity ions into portions of the active area 118 of the substrate 110 on both sides of the plurality of word lines 120. In some embodiments the impurity ions may be injected into the portions of the active area before the plurality of word lines 120 are formed. In some embodiments the impurity ions may be injected into the portions of the active area after the plurality of word lines 120 are formed.

In a process of forming the plurality of upper word line layers 120b, the defect PTa included in the plurality of lower word line layers 120a may not be removed. For example, the defect PTa may include the same material as the plurality of lower word line layers 120a. As the anisotropic dry etching process has a high etch selectivity of the second preliminary conductive layer 120bP with respect to the lower word line layer 120a, the defect PTa may not be removed by the anisotropic dry etching process. Thus, in a process of removing an upper portion of the second preliminary conductive layer 120bP in order to form the plurality of upper word line layers 120b, the defect PTa included in the plurality of lower word line layers 120a may be exposed. For example, the defect PTa may protrude upward in the vertical direction (Z direction) more than top surfaces of the plurality of upper word line layers 120b. Some of the plurality of upper word line layers 120b may be separated by the defect PTa while extending in the first horizontal direction (X direction). For example, some of the plurality of upper word line layers 120b may be separated into two portions by the defect PTa so as to be spaced apart from each other in the first horizontal direction (X direction).

In some embodiments, in a process of forming the plurality of word lines 120, portions of the dielectric material layer 122P may be removed to form a plurality of gate dielectric films 122. The plurality of gate dielectric films 122 may be disposed between the plurality of word lines 120 and the substrate 110. In some embodiments, in each of a process of forming the plurality of lower word line layers 120a and a process of forming the plurality of upper word line layers 120b, portions of the dielectric material layer 122P may be removed to form the plurality of gate dielectric films 122. The plurality of gate dielectric films 122 may conformally cover at least a portion of a surface of the substrate 110 located on bottom surfaces and side surfaces of the plurality of word line trenches 120T. In some embodiments, uppermost ends of the plurality of gate dielectric films 122 and top surfaces of the plurality of upper word line layers 120b may be at the same vertical level, but embodiments are not limited thereto. For example, uppermost ends of the plurality of gate dielectric films 122 may be at a higher vertical level than top surfaces of the plurality of upper word line layers 120b. Each of the plurality of gate dielectric films 122 may be formed of at least one selected from among silicon oxide, silicon nitride, silicon oxynitride, oxide/nitride/oxide (ONO), and a high-k dielectric material having a dielectric constant higher than that of silicon oxide. For example, each of the plurality of gate dielectric films 122 may have a dielectric constant of about 10 to 25. For example, the high-k dielectric material may be formed of at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

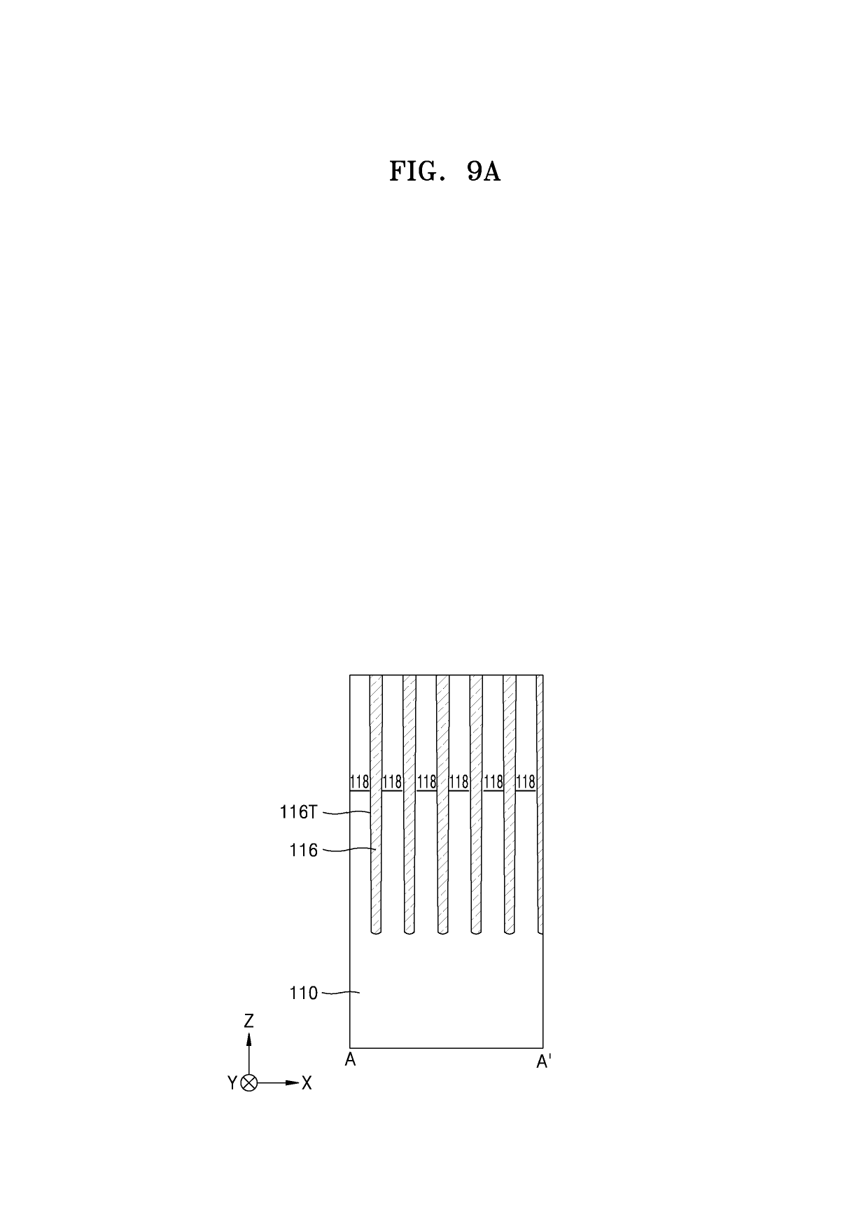

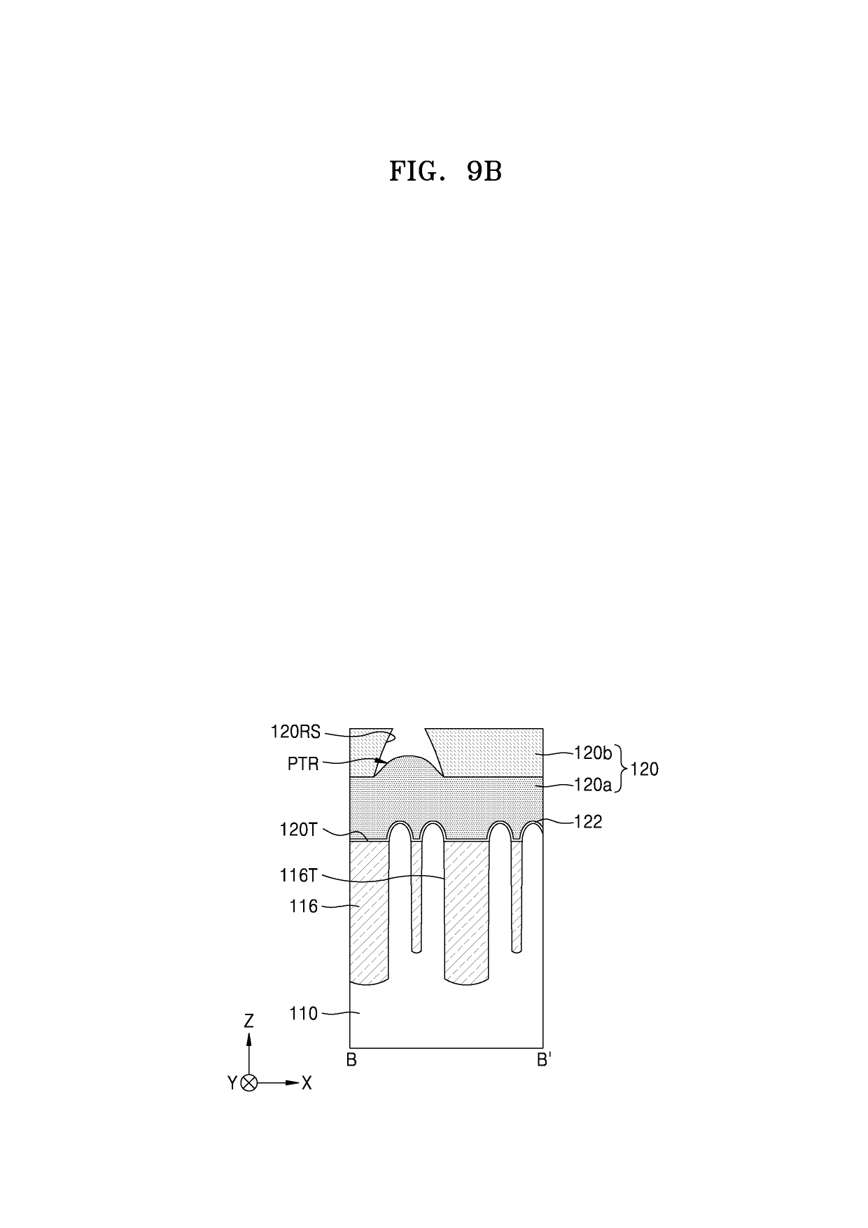

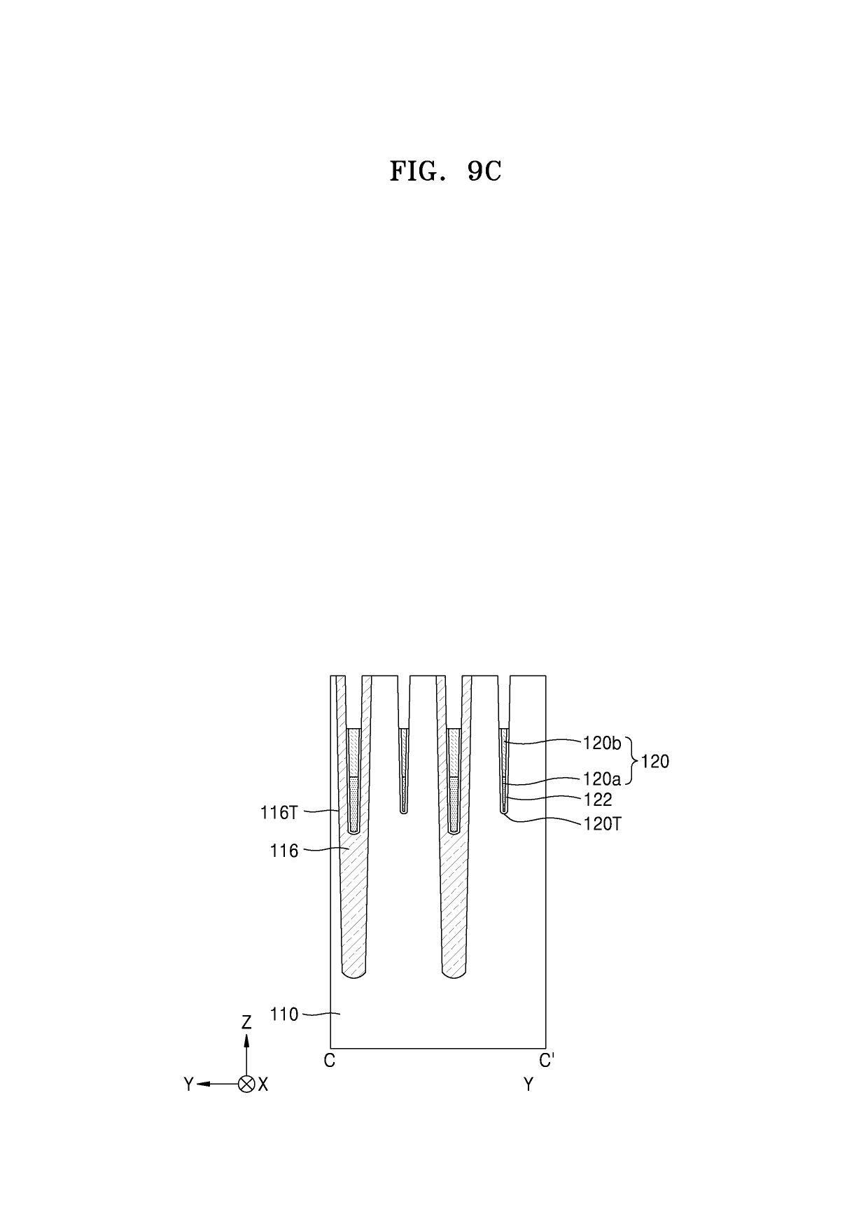

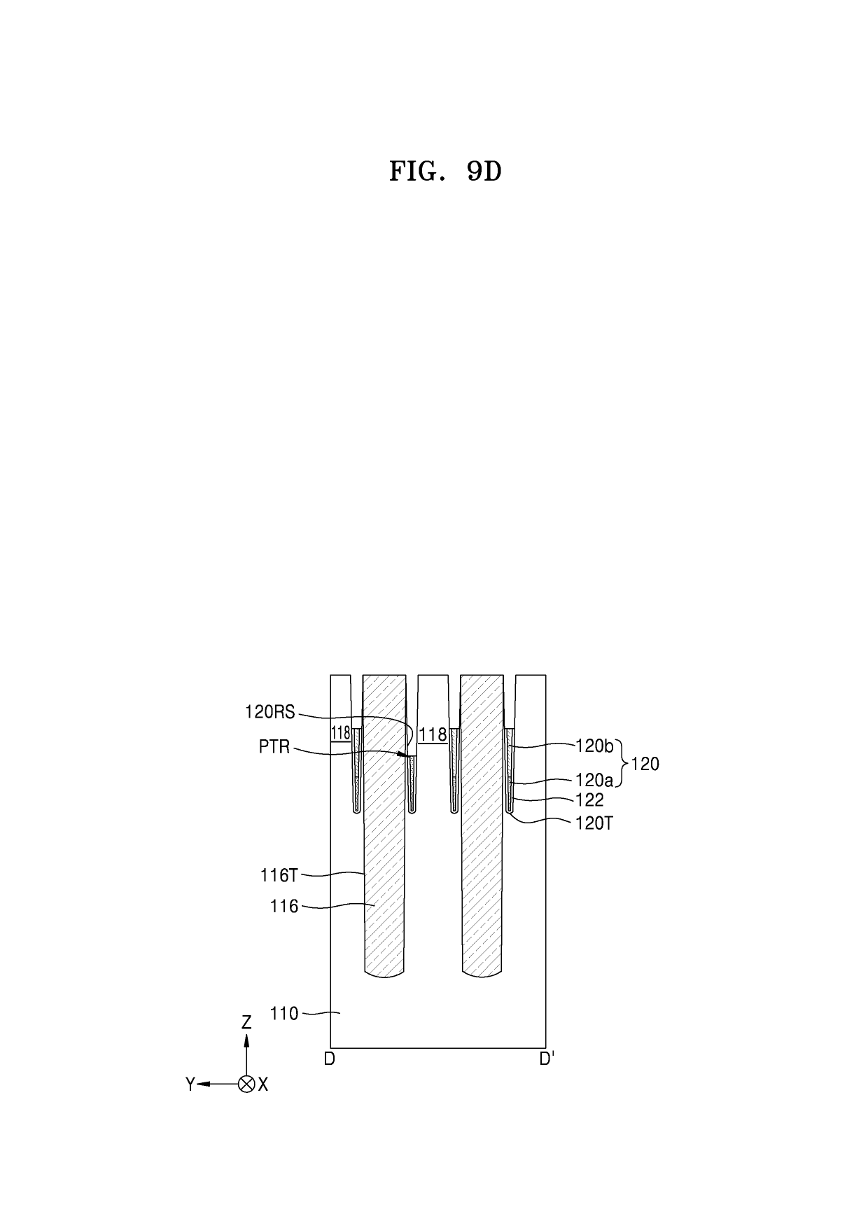

Referring to FIGS. 8A to 8D and 9A to 9D, at least a portion of the defect PTa included in the plurality of lower word line layers 120a is removed. The defect PTa included in the plurality of lower word line layers 120a may be removed by performing an isotropic wet etching process. For example, the defect PTa included in the plurality of lower word line layers 120a may be removed by performing a wet etching process using an etchant including sulfuric acid. At least a portion of the defect PTa included in the plurality of lower word line layers 120a may be removed by performing an isotropic etching process having a high etch selectivity of the lower word line layer 120a with respect to the upper word line layer 120b. An isotropic wet etching process of removing at least a portion of the defect PTa included in the plurality of lower word line layers 120a may be referred to as a third etching process, a wet etching process, or an isotropic etching process.

At least some of the plurality of word lines 120 may include an electrode recess 120RS, which is a space where at least a portion of the defect PTa included in the plurality of lower word line layers 120a is removed. The electrode recess 120RS may be referred to as a defect-removed space. In some embodiments, a portion of the defect PTa included in the plurality of lower word line layers 120 may not be removed and may remain as a protrusion PTR. For example, at least some of the plurality of lower word line layers 120a may include the protrusion PTR. The protrusion PTR may protrude toward the electrode recess 120RS in the vertical direction (Z direction) more than other portions of the lower word line layer 120a.

Some of the plurality of upper word line layers 120b may be separated by the electrode recess 120RS while extending in the first horizontal direction (X direction). For example, some of the plurality of upper word line layers 120b may be separated into two portions by the electrode recess 120RS so as to be spaced apart from each other in the first horizontal direction (X direction). For example, along the first horizontal direction (X direction), the protrusion PTR may overlap the plurality of upper word line layers 120b.

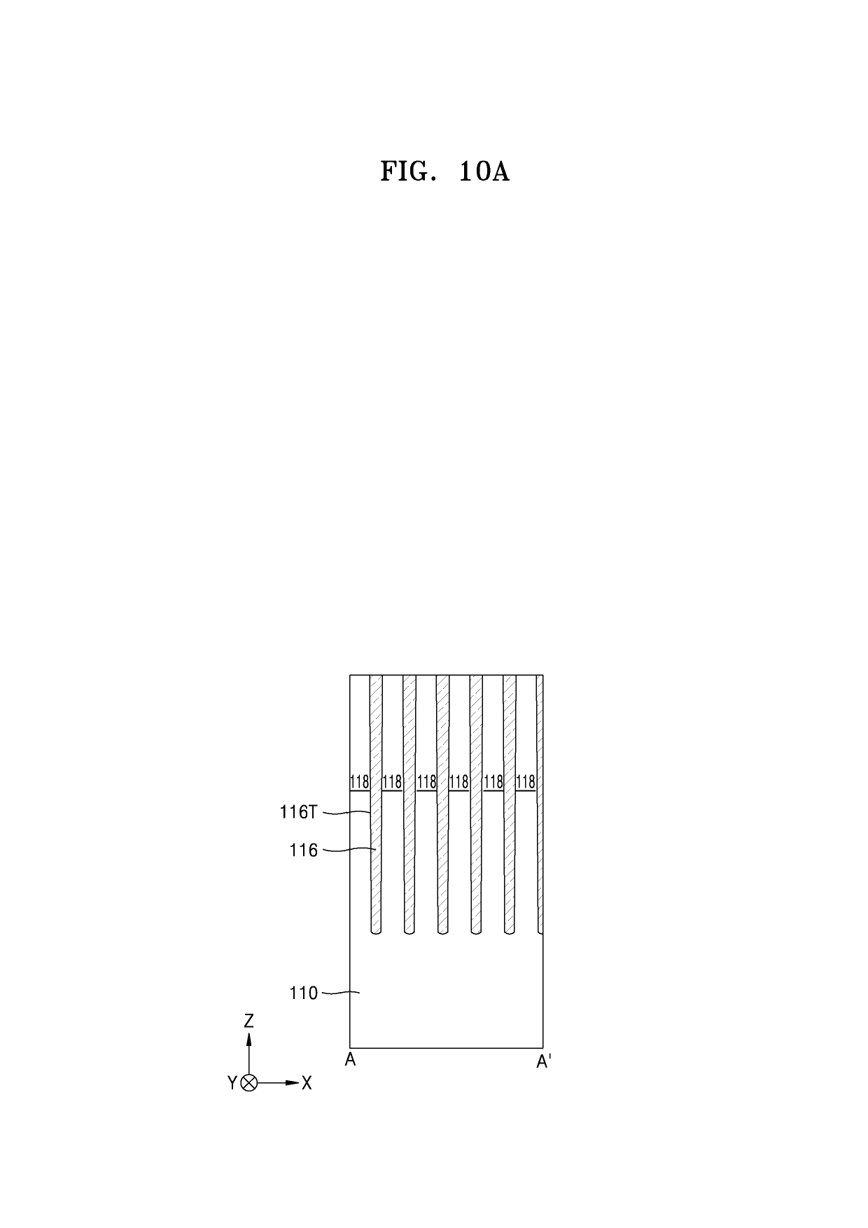

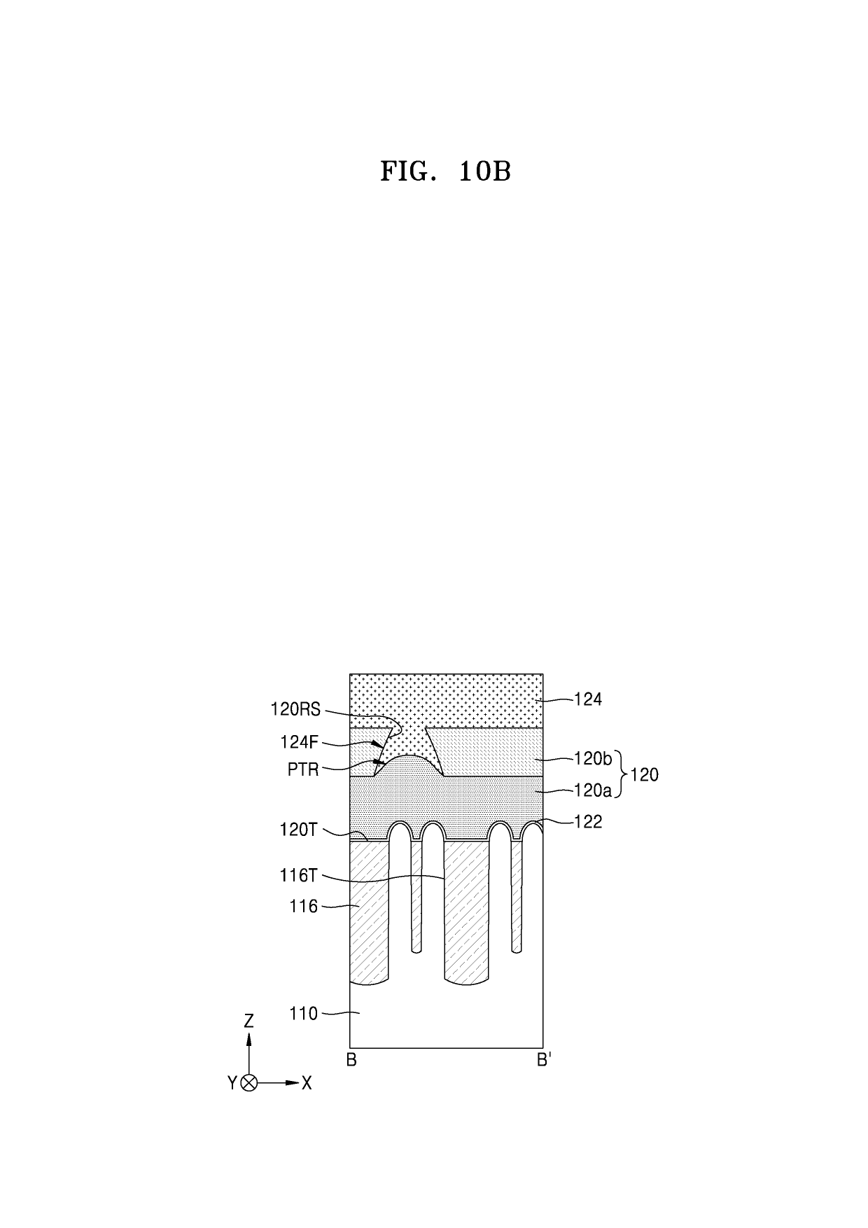

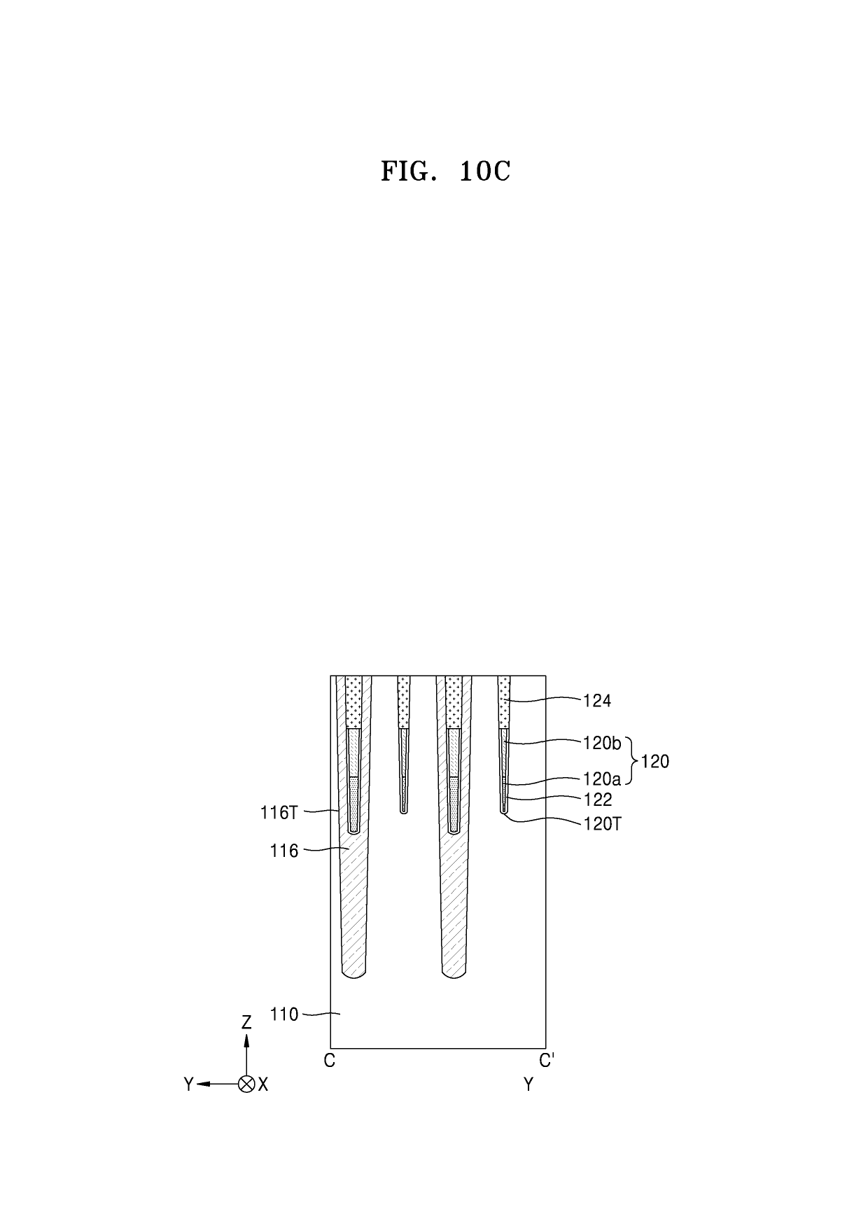

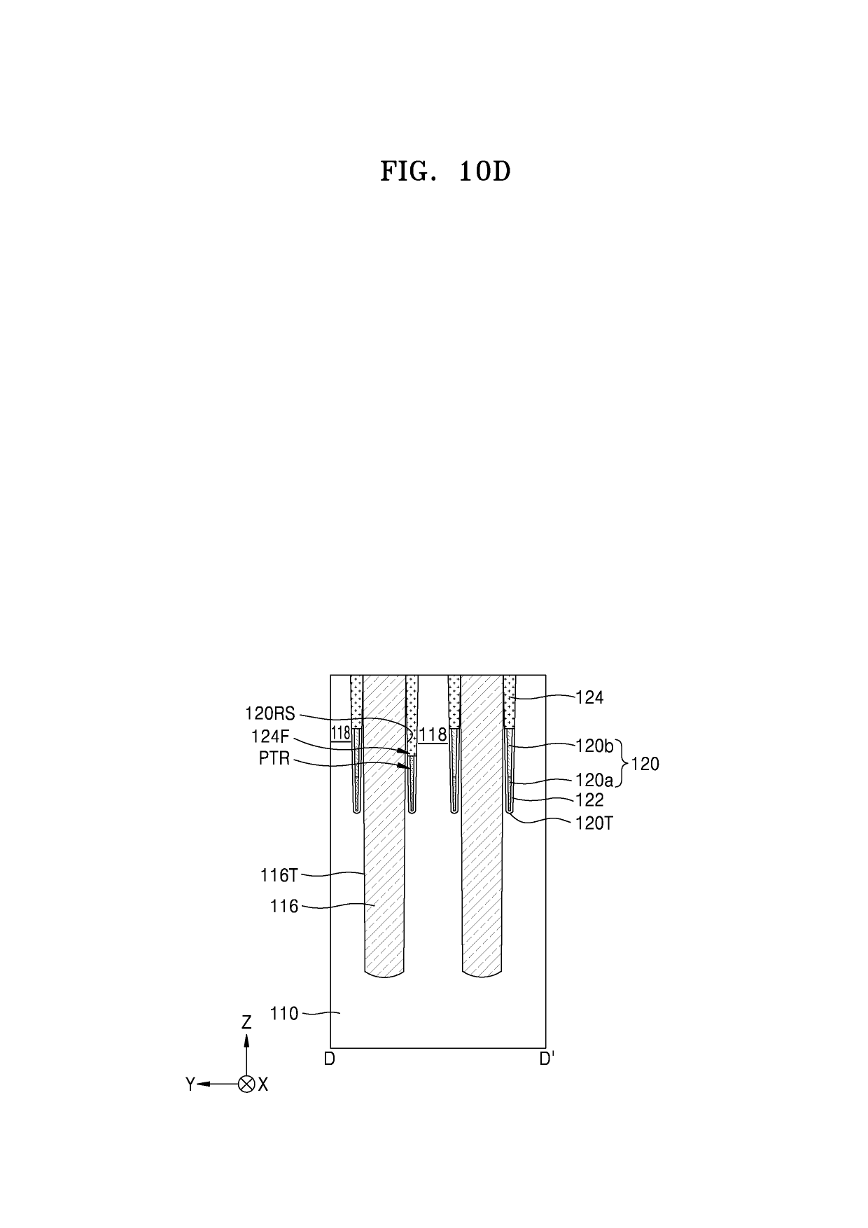

Referring to FIGS. 10A to 10D, a plurality of buried insulating films 124 covering the plurality of word lines 120 and filling the plurality of word line trenches 120T are formed. The plurality of buried insulating films 124 may extend parallel to each other in the first horizontal direction (X direction) on the plurality of word lines 120. The plurality of gate dielectric films 122, the plurality of word lines 120, and the plurality of buried insulating films 124 may fill all of the plurality of word line trenches 120T. The buried insulating film 124 may be formed of at least one material selected from among silicon oxide, silicon nitride, silicon oxynitride, and a combination thereof.

In some embodiments, in a process of forming the plurality of gate dielectric films 122, the plurality of word lines 120, and the plurality of buried insulating films 124, an upper portion of the device isolation film 116 may be removed. A top surface of the substrate 110, a top surface of the device isolation film 116, and top surfaces of the plurality of buried insulating films 124 may be at substantially the same vertical level to form a coplanar surface

At least some of the plurality of buried insulating films 124 may include an extension insulating portion 124F filling the electrode recess 120RS included in at least some of the plurality of word lines 120 and extending into the word line 120. The extension insulating portion 124F may contact the lower word line layer 120a. Along the vertical direction (Z direction), the plurality of buried insulating films 124 may be thicker at portions that overlap the protrusion PTR. In some embodiments, the extension insulating portion 124F may contact the protrusion PTR included in the lower word line layer 120a. Some of the plurality of upper word line layers 120b may extend in the first horizontal direction (X direction) and may be spaced apart from each other with the extension insulating portion 124F therebetween. For example, some of the plurality of upper word line layers 120b may be separated into two portions by the extension insulating portion 124F and may be spaced apart from each other in the first horizontal direction (X direction).

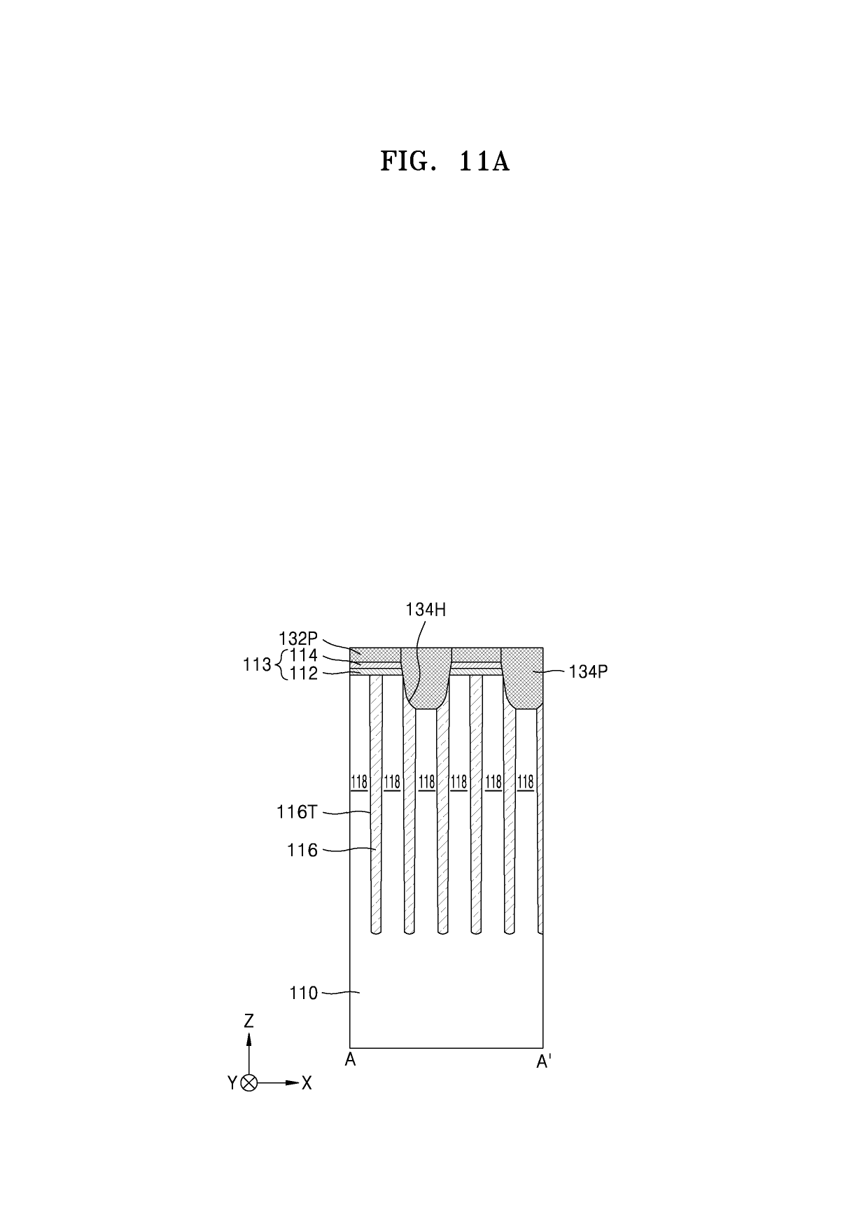

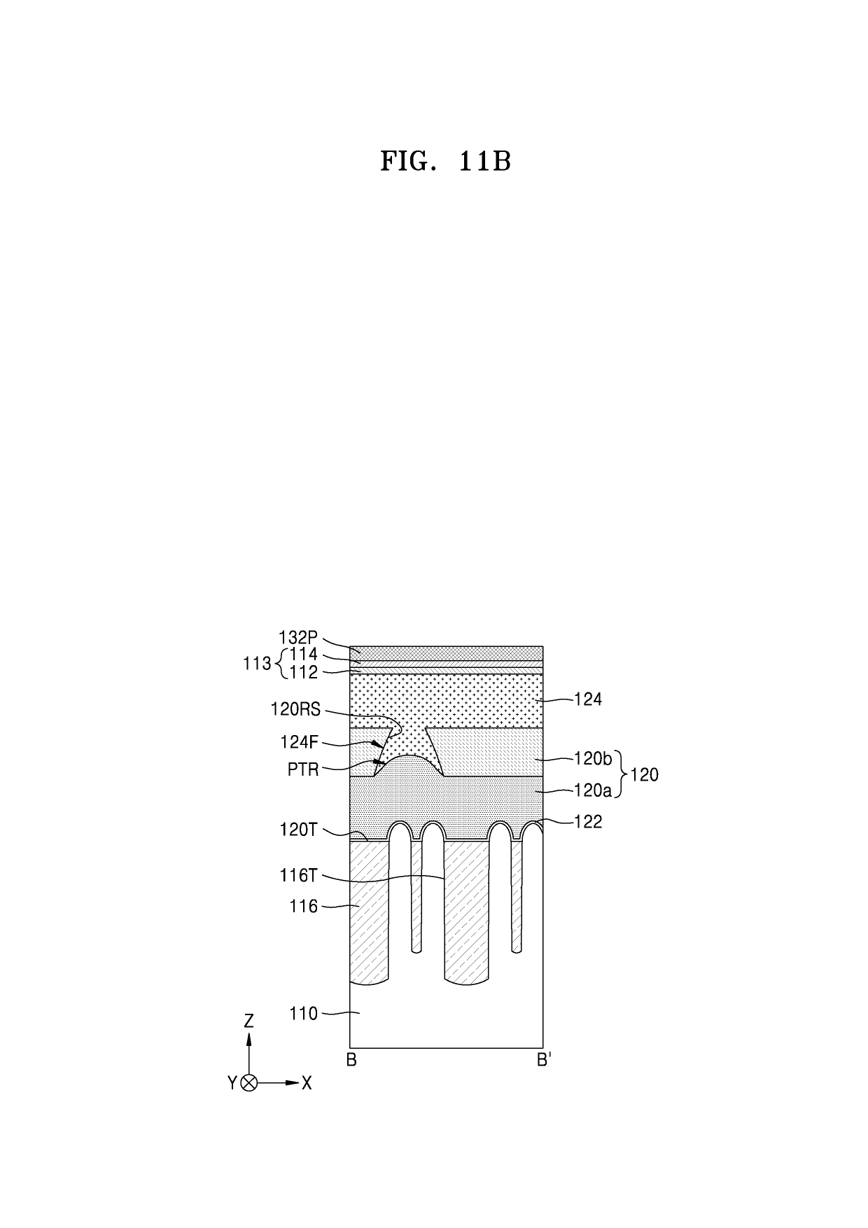

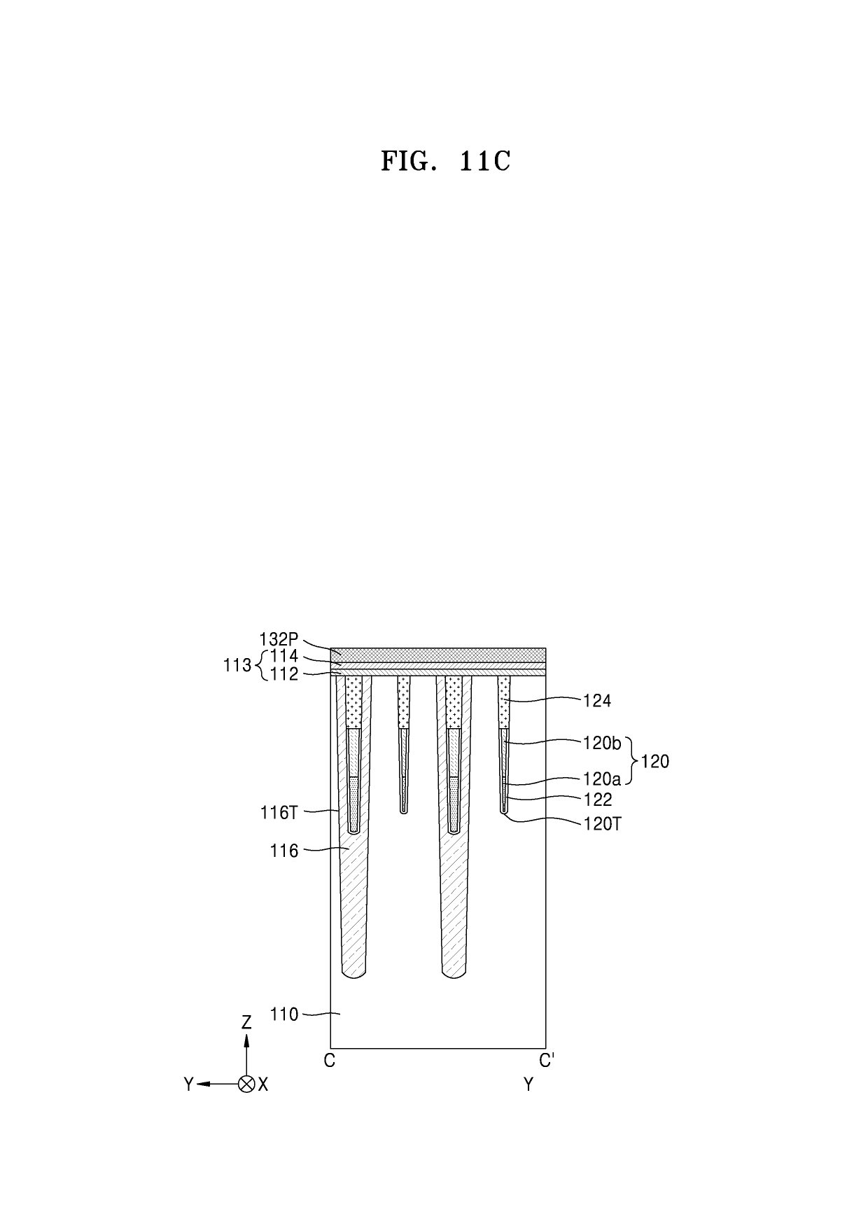

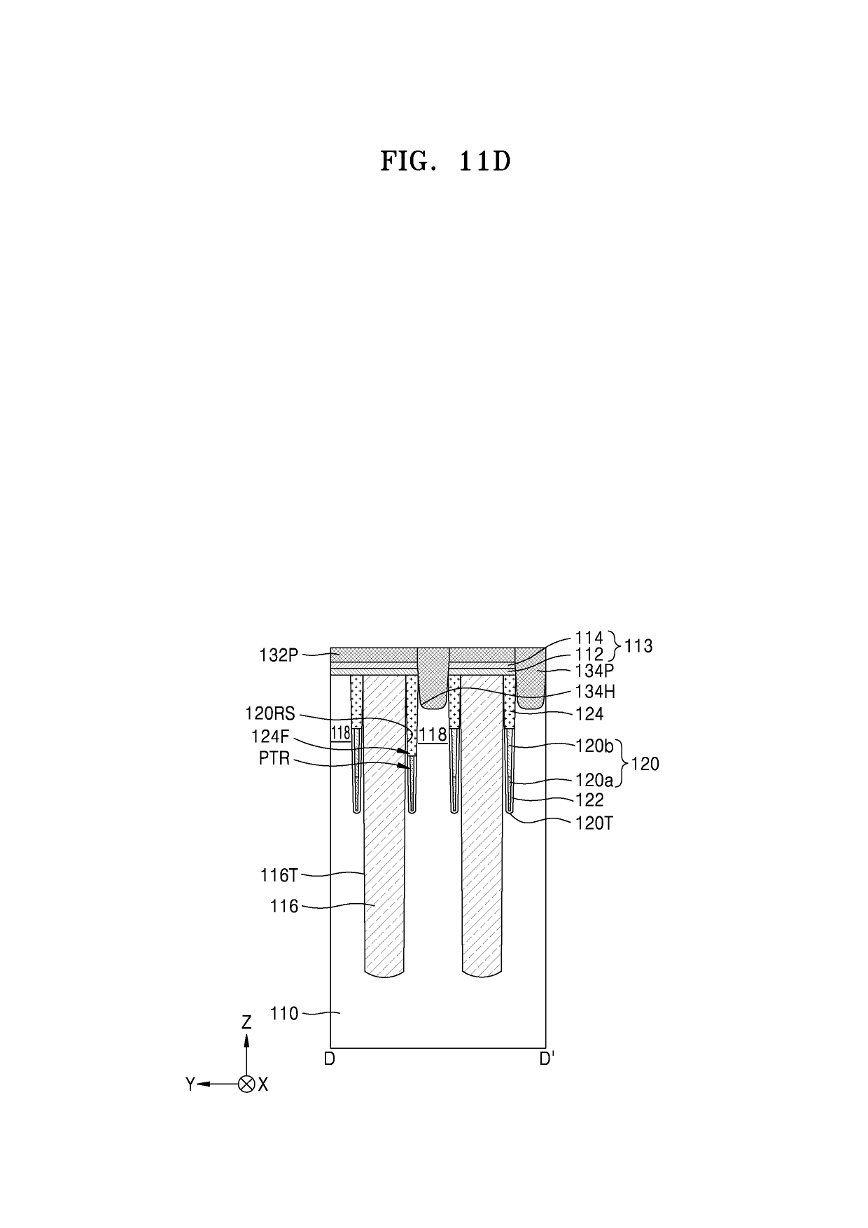

Referring to FIGS. 11A to 11D, an insulating structure 113 covering the device isolation film 116, the plurality of active areas 118, and the plurality of buried insulating films 124 is formed. For example, the insulating structure 113 may be formed of a silicon oxide film, a silicon nitride film, a silicon oxynitride film, a metal-based dielectric film, or a combination. In some embodiments, the insulating structure 113 may be formed by stacking a plurality of insulating films including a first insulating film pattern 112 and a second insulating film pattern 114. In some embodiments, the first insulating film pattern 112 may be formed of a silicon oxide film, and the second insulating film pattern 114 may be formed of a silicon oxynitride film. In some embodiments, the first insulating film pattern 112 may be formed of a non-metal-based dielectric film, and the second insulating film pattern 114 may be formed of a metal-based dielectric film.

Next, after a conductive semiconductor layer 132P is formed on the insulating structure 113, a direct contact hole 134H passing through the conductive semiconductor layer 132P and the insulating structure 113 to expose the source region in the active area 118 is formed, and a direct contact conductive layer 134P filling the direct contact hole 134H is formed. In some embodiments, the direct contact hole 134H may extend into the active area 118, that is, the source region. The conductive semiconductor layer 132P may be formed of, for example, doped polysilicon. In some embodiments, the conductive semiconductor layer 132P and the direct contact conductive layer 134P may be formed of the same type of material. For example, the direct contact conductive layer 134P may be formed of doped polysilicon. In some embodiments, the conductive semiconductor layer 132P and the direct contact conductive layer 134P may be formed of different types of materials. For example, the direct contact conductive layer 134P may be formed of an epitaxial silicon layer, a metal, or a metal compound that is a conductive material. In some embodiments, the direct contact conductive layer 134P may be formed of a metal such as Ti or W, or a conductive material that is a compound including a metal such as Ti or W and a non-metal such as Si, C, B, or N. For example, the direct contact conductive layer 134P may be formed of TiN, WC, or WSi.

When the defect PTa shown in FIGS. 8B and 8D remains without being removed, at least some of the plurality of direct contact conductive layers 134P may contact the defect PTa, and thus, a short circuit in which the plurality of direct contact conductive layers 134P and the plurality of word lines 120 are electrically connected to each other may occur. However, due to the extension insulating portion 124F filling the electrode recess 120RS where the defect PTa is removed, the plurality of direct contact conductive layers 134P and the plurality of word lines 120 may not contact each other and may be spaced apart from each other.

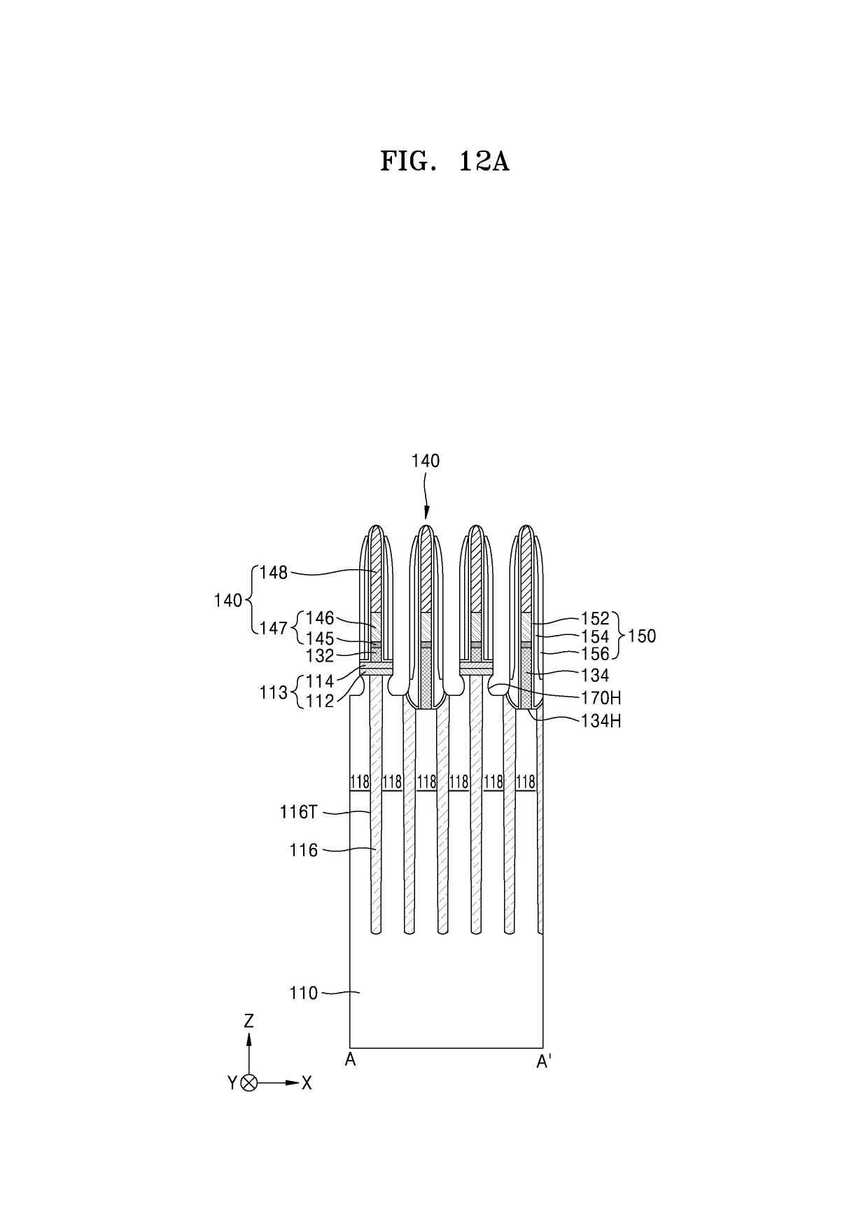

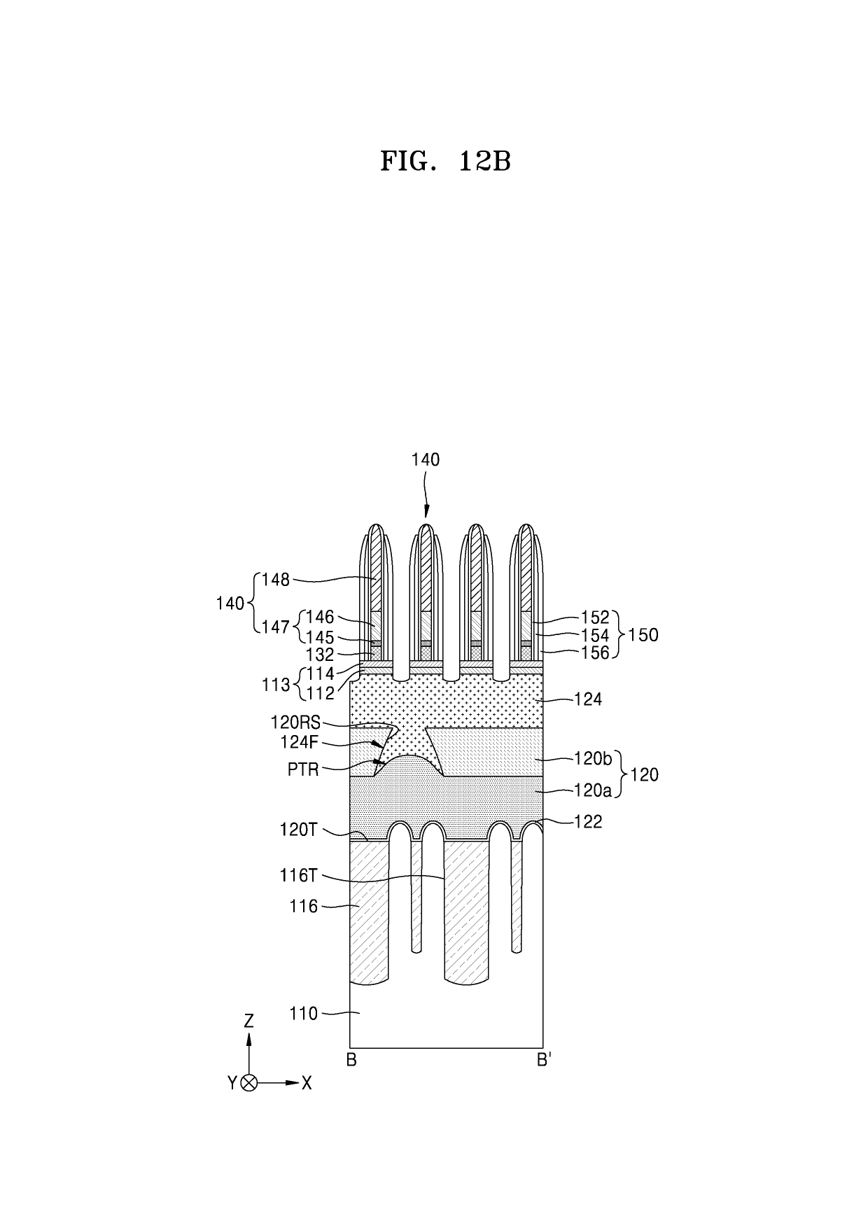

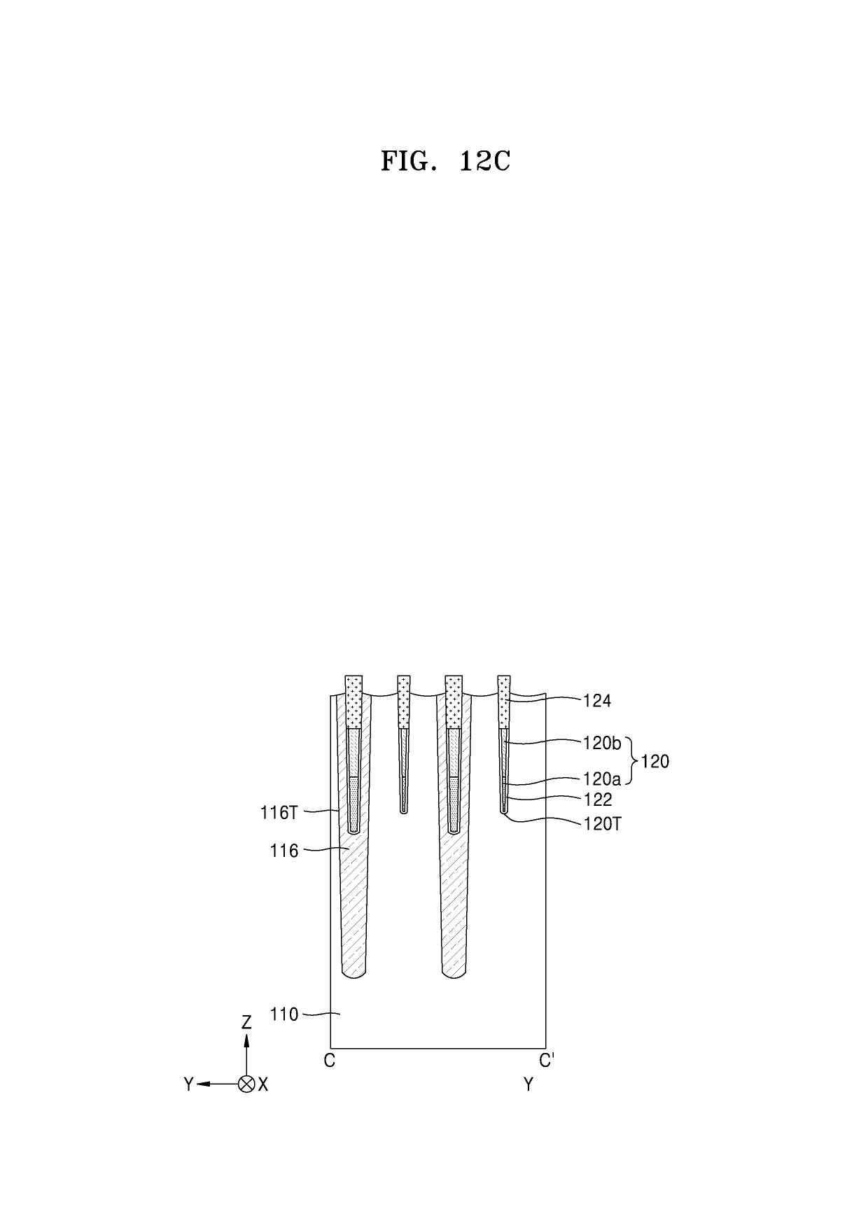

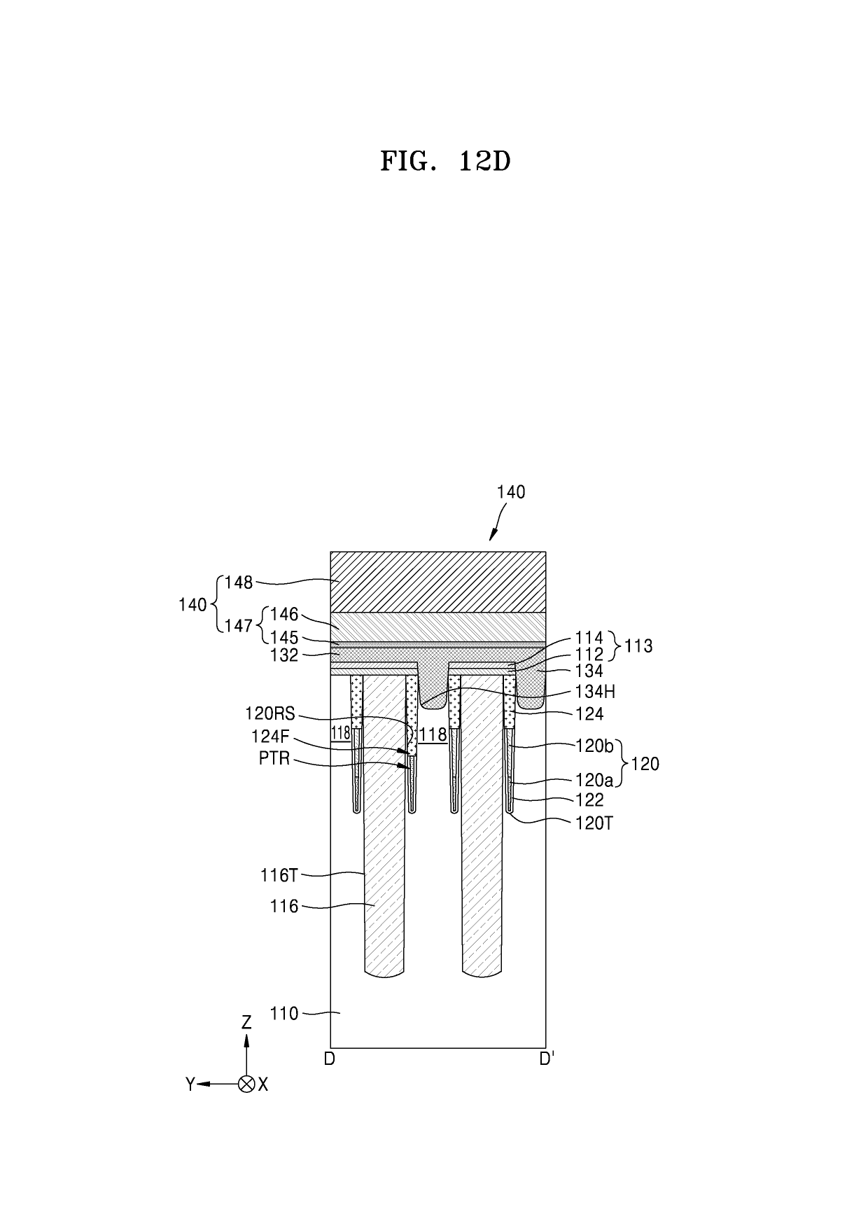

Referring to FIGS. 11A to 11D and 12A to 12D, a metal-based conductive layer and an insulating capping layer covering the conductive semiconductor layer 132P and the direct contact conductive layer 134P and used to form a bit line structure 140 are sequentially formed. In some embodiments, the metal-based conductive layer may have a stacked structure including a first metal-based conductive layer and a second metal-based conductive layer. A plurality of bit lines 147 each having a stacked structure including a first metal-based conductive pattern 145 and a second metal-based conductive pattern 146 in a line shape and a plurality of insulating capping lines 148 covering the plurality of bit lines 147 are formed by etching the first metal-based conductive layer, the second metal-based conductive layer, and the insulating capping layer.

In some embodiments, the first metal-based conductive pattern 145 may be formed of titanium nitride (TiN) or Ti-Si-N (TSN), and the second metal-based conductive pattern 146 may be formed of tungsten (W), or tungsten and tungsten silicide (WSix). In some embodiments, the first metal-based conductive pattern 145 may function as a diffusion barrier. In some embodiments, a plurality of insulating capping lines 148 may be formed of a silicon nitride film.

One bit line 147 and one insulating capping line 148 covering one bit line 147 may constitute one bit line structure 140. The plurality of bit line structures 140 each including the bit line 147 and the insulating capping line 148 covering the bit line 147 may extend parallel to each other along the second horizontal direction (Y direction) parallel to a main surface of the substrate 110. The plurality of bit lines 147 may constitute the plurality of bit lines BL of FIG. 2. In some embodiments, the bit line structure 140 may further include a conductive semiconductor pattern 132 that is a portion of the conductive semiconductor layer 132P disposed between the insulating structure 113 and the first metal-based conductive pattern 145.

In an etching process for forming the plurality of bit lines 147, a plurality of conductive semiconductor patterns 132 and a plurality of direct contact conductive patterns 134 may be formed by removing together, by using an etching process, a portion of the conductive semiconductor layer 132P and a portion of the direct contact conductive layer 134P not overlapping the bit line 147 in the vertical direction. In this case, the insulating structure 113 may function as an etching stop film in an etching process of forming the plurality of bit lines 147, the plurality of conductive semiconductor patterns 132, and the plurality of direct contact conductive patterns 134. The plurality of direct contact conductive patterns 134 may constitute the plurality of direct contacts DC of FIG. 2. The plurality of bit lines 147 may be electrically connected to the plurality of active areas 118 through the plurality of direct contact conductive patterns 134. The conductive semiconductor pattern 132 may be formed of, for example, doped polysilicon. The direct contact conductive pattern 134 may be formed of doped polysilicon, a metal, or a metal compound that is a conductive material. For example, the direct contact conductive pattern 134 may be formed of a metal such as Ti or W, or a conductive material that is a compound including a metal such as Ti or W and a non-metal such as Si, C, B, or N. In some embodiments, the direct contact conductive pattern 134 may be formed of TiN, WC, or WSi.

When the defect PTa shown in FIGS. 8B and 8D remains without being removed, at least some of the plurality of direct contact conductive patterns 134 may contact the defect PTa, and thus a short circuit in which the direct contact conductive pattern 134 and the plurality of word lines 120 are electrically connected to each other may occur. However, due to the extension insulating portion 124F filling the electrode recess 120RS where the defect PTa is removed, the direct contact conductive pattern 134 and the plurality of word lines 120 may be spaced apart from each other without contacting each other.

An insulating spacer structure 150 may cover both side walls of each of the plurality of bit line structures 140. Each of a plurality of insulating spacer structures 150 may include a first insulating spacer 152, a second insulating spacer 154, and a third insulating spacer 156. The second insulating spacer 154 may be formed of a material having a lower dielectric constant than the first insulating spacer 152 and the third insulating spacer 156. In some embodiments, the first insulating spacer 152 and the third insulating spacer 156 may be formed of a nitride film, and the second insulating spacer 154 may be formed of an oxide film. In some embodiments, the first insulating spacer 152 and the third insulating spacer 156 may be formed of a nitride film, and the second insulating spacer 154 may be formed of a material having an etch selectivity with respect to the first insulating spacer 152 and the third insulating spacer 156. For example, when each of the first insulating spacer 152 and the third insulating spacer 156 is formed of a nitride film, the second insulating spacer 154 may be formed of an oxide film, but may be removed in a subsequent process to become an air spacer.

A plurality of buried contact holes 170H may be formed between the plurality of bit lines 147. An inner space of each of the plurality of buried contact holes 170H may be defined by the active area 118 and the insulating spacer structure 150 covering a side wall of each of two adjacent bit lines 147 between the two adjacent bit lines 147 among the plurality of bit lines 147.

The plurality of buried contact holes 170H may be formed by removing a portion of the active area 118 and the insulating structure 113 by using the plurality of insulating capping lines 148, and the insulating spacer structure 150 covering both side walls of each of the plurality of bit line structures 140 as an etching mask. In some embodiments, the plurality of buried contact holes 170H may be formed by first performing an anisotropic etching process of removing a portion of the active area 118 and the insulating structure 113 by using the plurality of insulating capping lines 148, and the insulating spacer structure 150 covering both side walls of each of the plurality of bit line structures 140 as an etching mask, and then performing an isotropic etching process of further removing another portion of the active area 118 to expand a space defined by the active area 118.

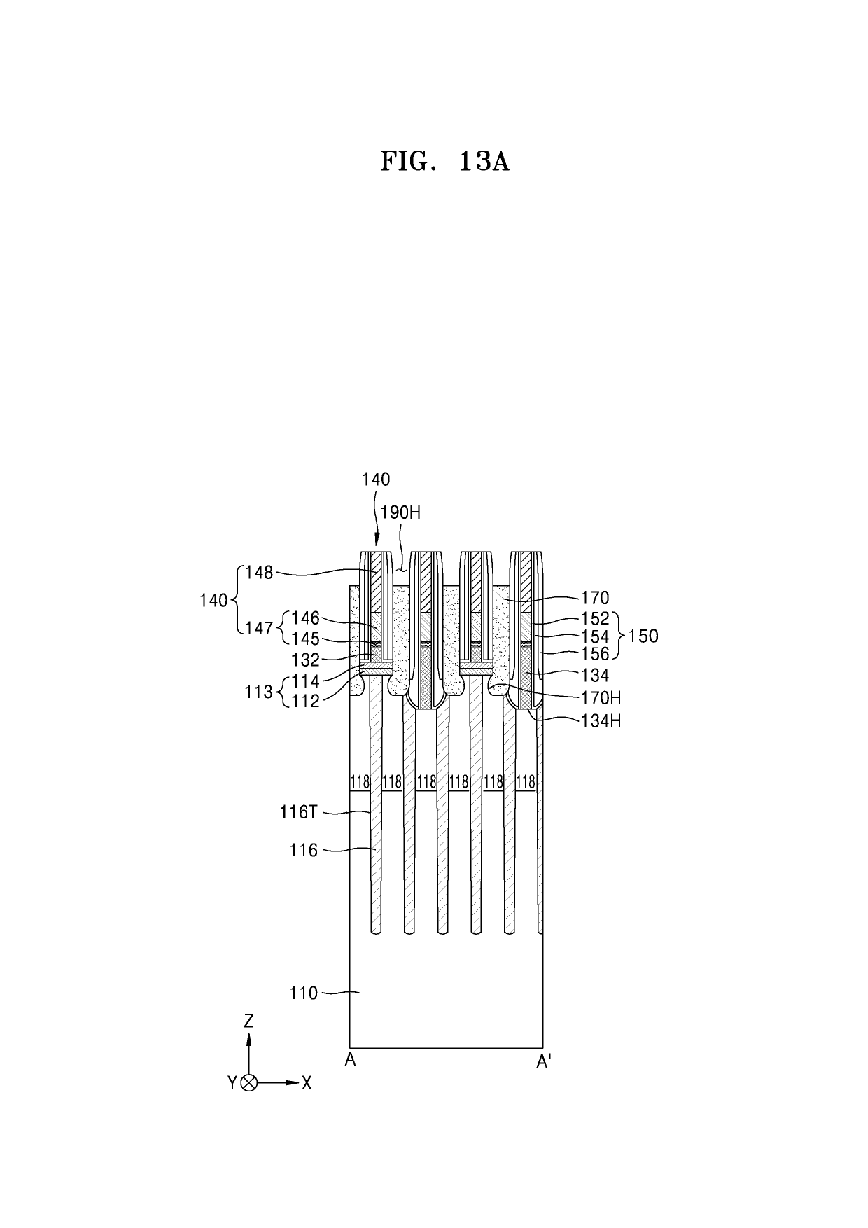

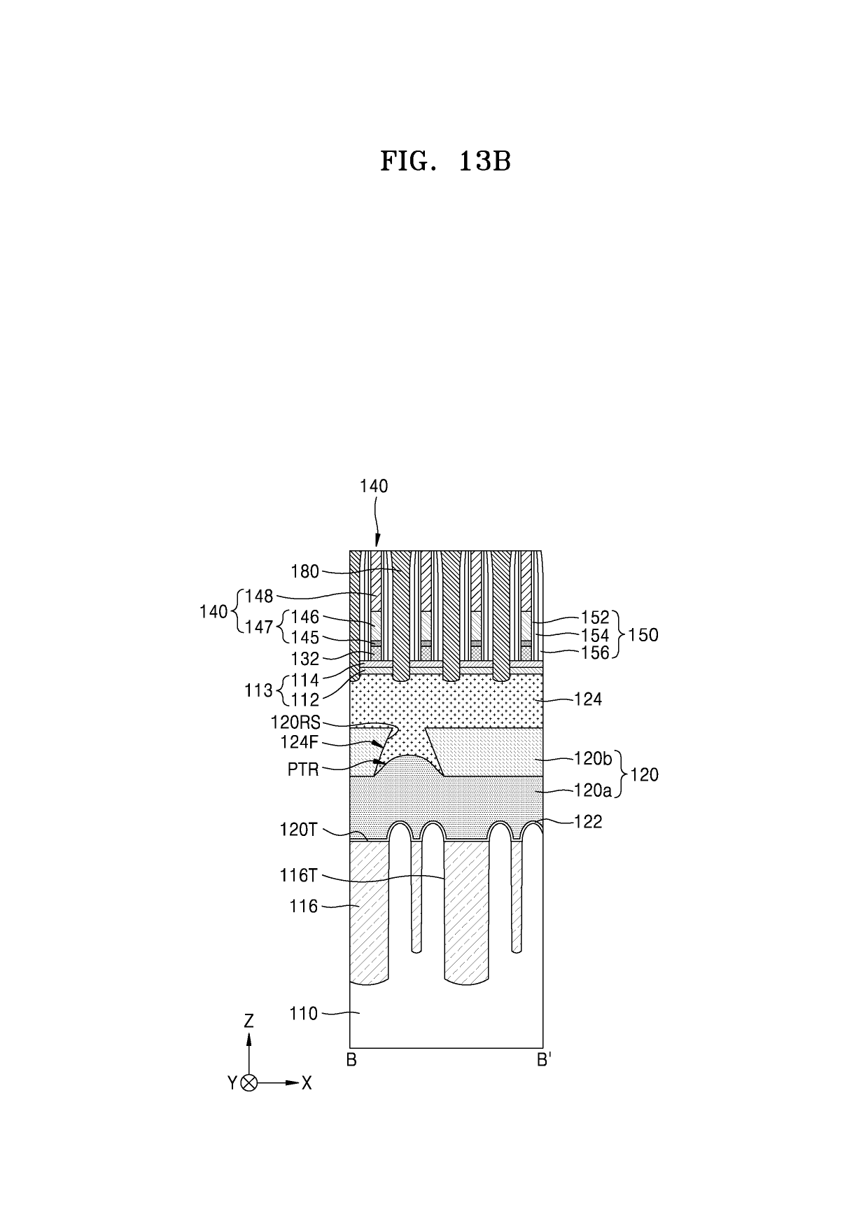

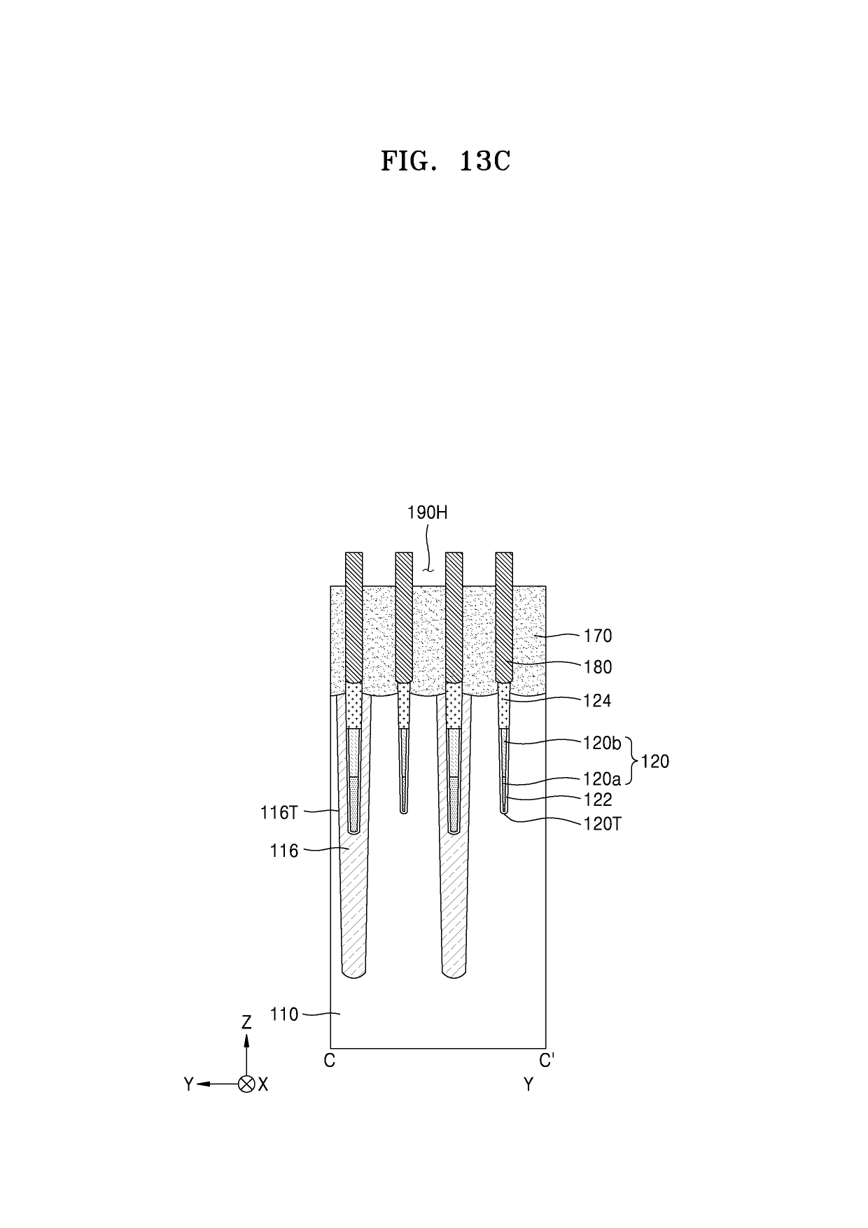

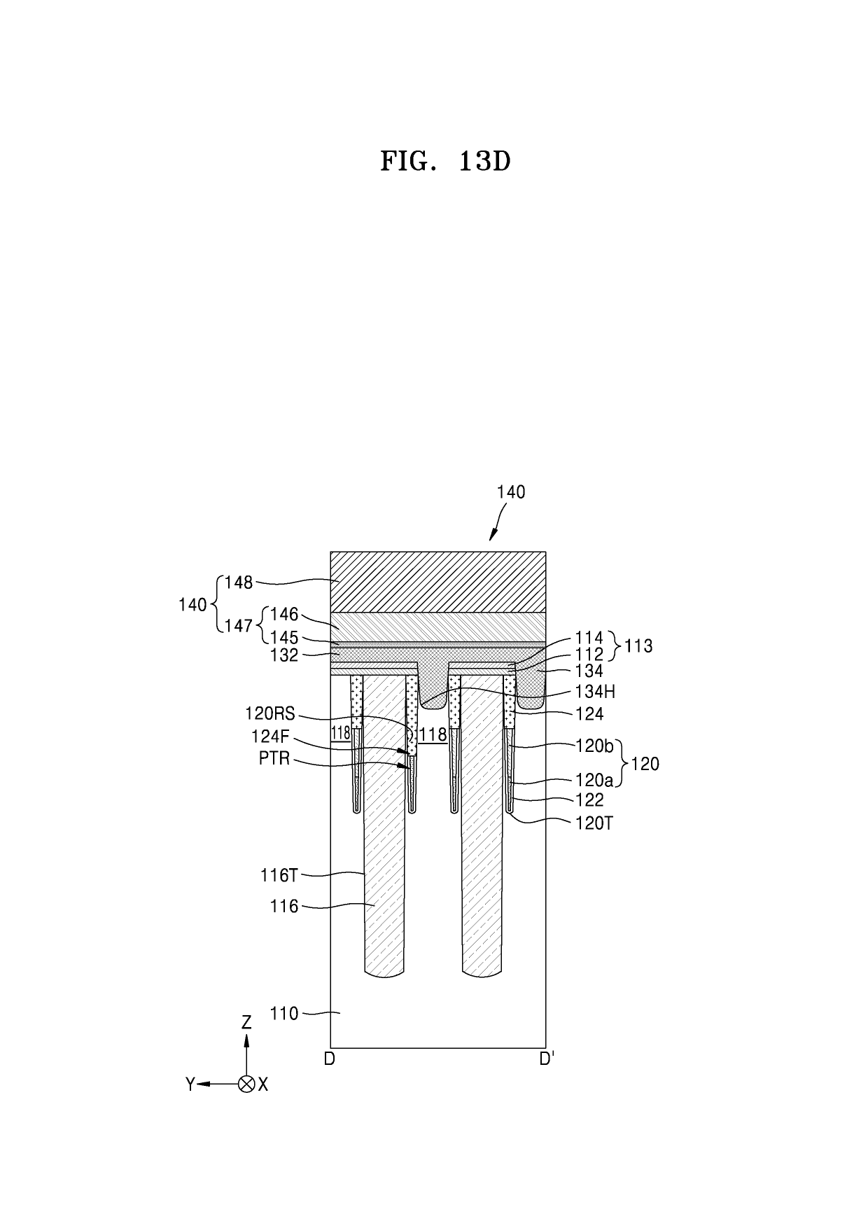

Referring to FIGS. 13A to 13D, a plurality of buried contacts 170 and a plurality of insulating fences 180 are formed in a space between the plurality of insulating spacer structures 150 covering both side walls of the plurality of bit line structures 140. The plurality of buried contacts 170 and the plurality of insulating fences 180 may be alternately arranged between one pair of insulating spacer structures 150 facing each other, that is, along the second horizontal direction (Y direction), from among the plurality of insulating spacer structures 150 covering both side walls of the plurality of bit line structures 140. For example, the plurality of buried contacts 170 may be formed of polysilicon. For example, the plurality of insulating fences 180 may be formed of a nitride film.

In some embodiments, the plurality of buried contacts 170 may be arranged in a line along the first horizontal direction (X direction) and the second horizontal direction (Y direction). Each of the plurality of buried contacts 170 may extend in the vertical direction (Z direction) perpendicular to the substrate 110 from the active area 118. The plurality of buried contacts 170 may constitute the plurality of buried contacts BC of FIG. 2.

The plurality of buried contacts 170 may be disposed in a space defined by the plurality of insulating fences 180 and the plurality of insulating spacer structures 150 covering both side walls of the plurality of bit line structures 140. The plurality of buried contacts 170 may fill a lower portion of a space between the plurality of insulating spacer structures 150 covering both side walls of the plurality of bit line structures 140.

A level of a top surface of each of the plurality of buried contacts 170 may be lower than a level of a top surface of each of the plurality of insulating capping lines 148. A top surface of each of the plurality of insulating fences 180 and a top surface of each of the plurality of insulating capping lines 148 may be at the same level in the vertical direction (Z direction).

A plurality of landing pad holes 190H may be defined by the plurality of insulating spacer structures 150 and the plurality of insulating fences 180. The plurality of buried contacts 170 may be exposed on bottom surfaces of the plurality of landing pad holes 190H.

In a process of forming the plurality of buried contacts 170 and/or the plurality of insulating fences 180, an upper portion of the insulating spacer structure 150 and the insulating capping line 148 included in the bit line structure 140 may be removed, and thus, a level of a top surface of the bit line structure 140 may be lowered.

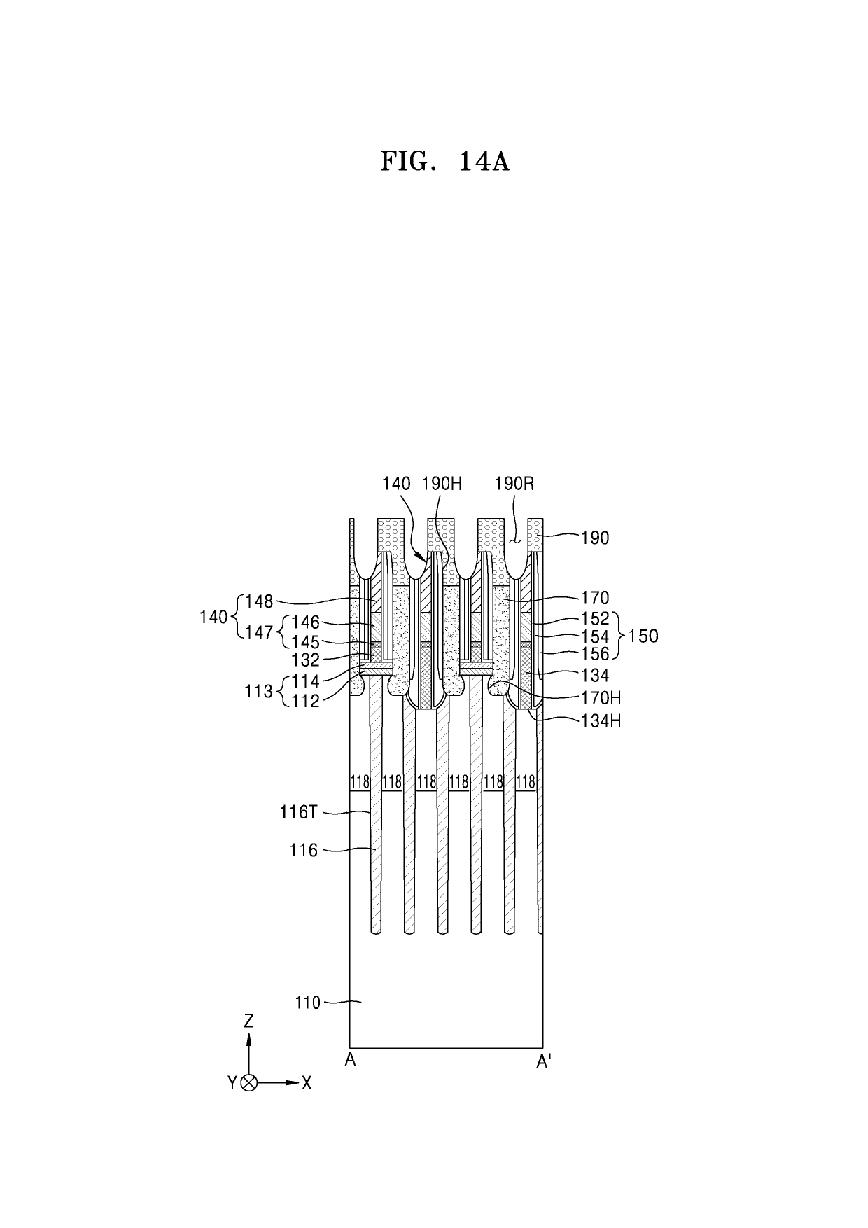

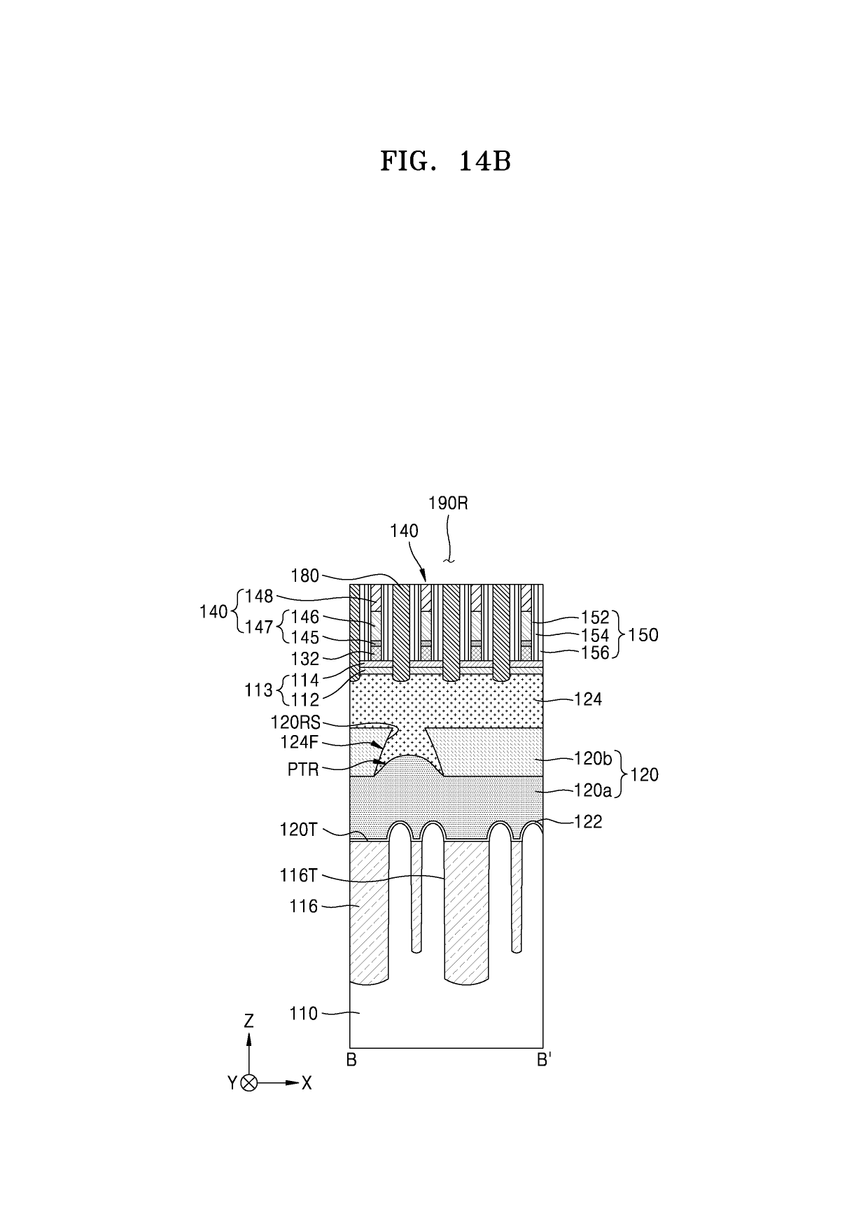

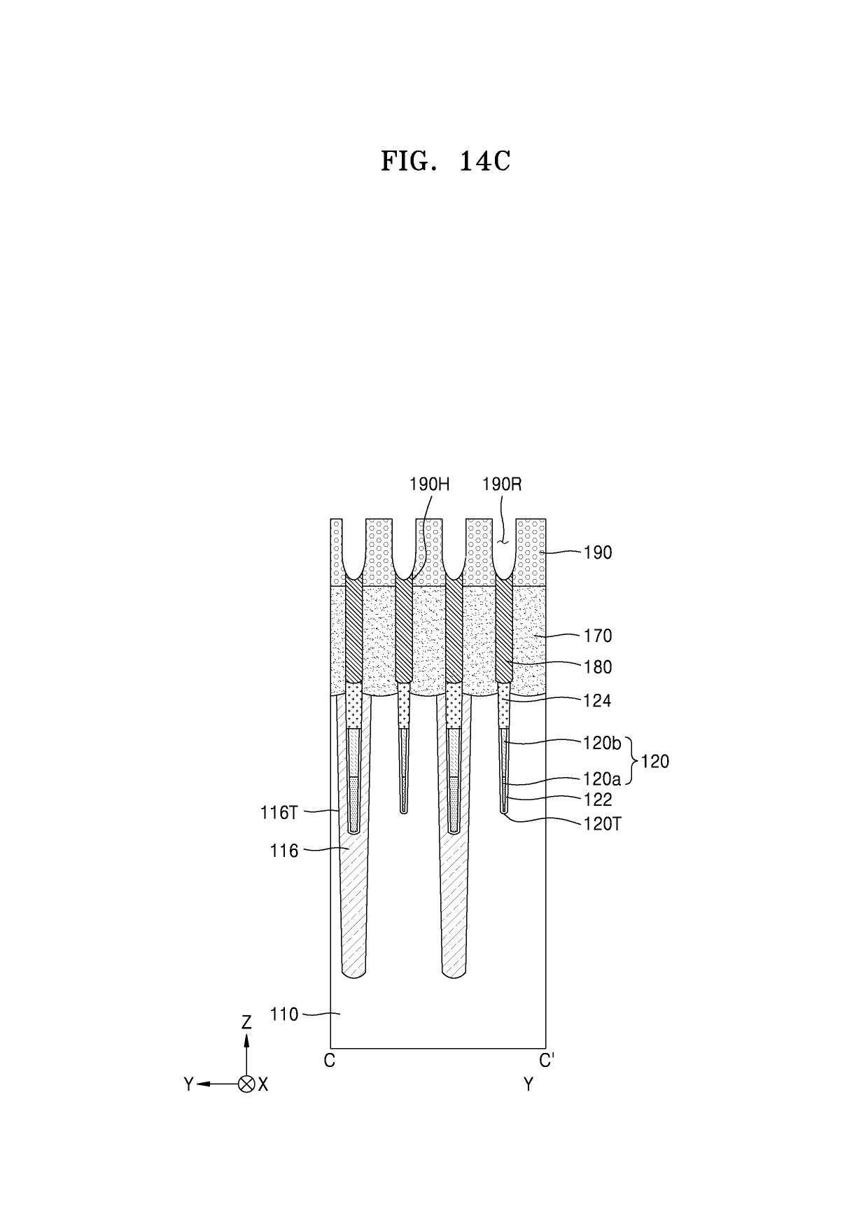

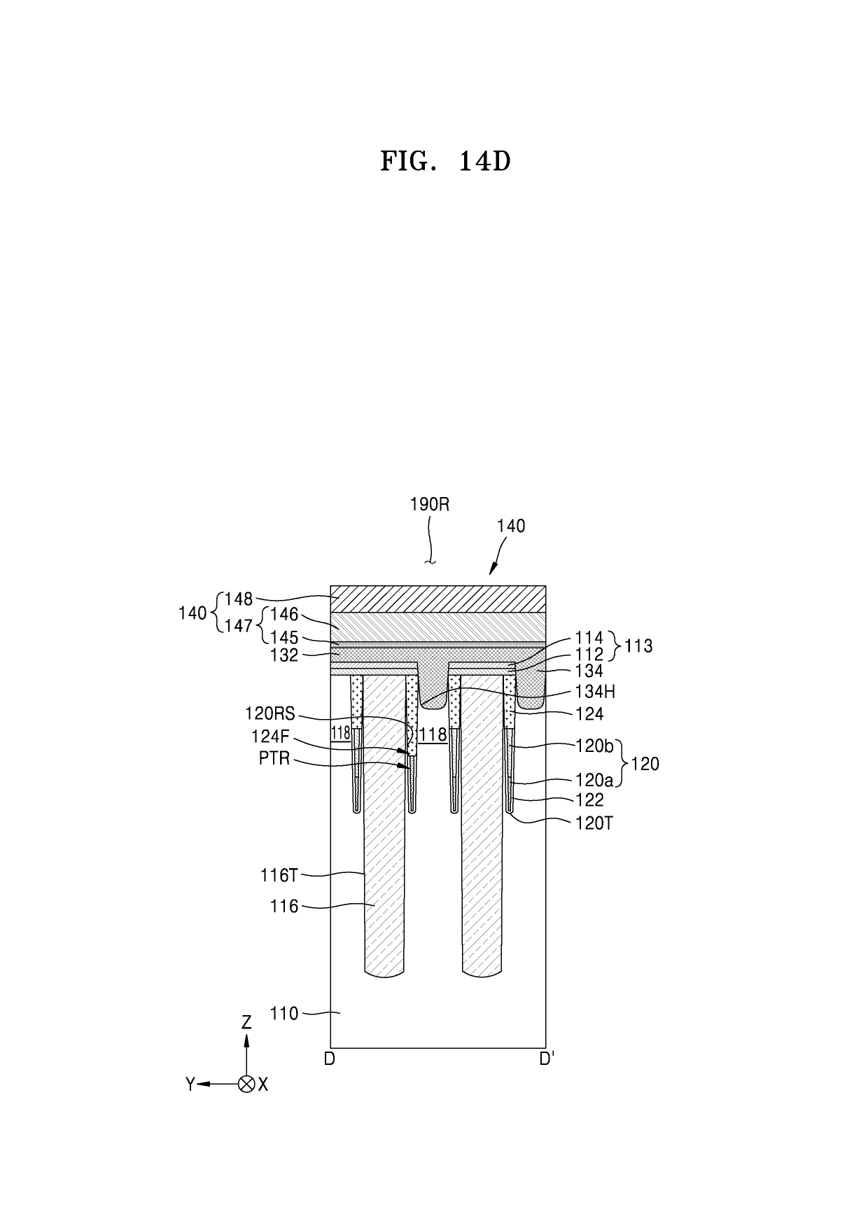

Referring to FIGS. 14A to 14D, a landing pad material layer filling the plurality of landing pad holes 190H and covering the plurality of bit line structures 140 is formed. In some embodiments, the landing pad material layer may be formed of a conductive barrier film and a conductive pad material layer on the conductive barrier film. For example, the conductive barrier film may be formed of a metal, conductive metal nitride, or a combination thereof. In some embodiments, the conductive barrier film may have a stacked structure including Ti/TiN. In some embodiments, the conductive pad material layer may include tungsten (W).

In some embodiments, before the landing pad material layer is formed, a metal silicide film may be formed on the plurality of buried contacts 170. The metal silicide film may be disposed between the plurality of buried contacts 170 and the landing pad material layer. The metal silicide film may be formed of, but is not limited to, cobalt silicide (CoSiₓ), nickel silicide (NiSiₓ), or manganese silicide (MnSiₓ).

Next, a portion of the landing pad material layer is removed, and a plurality of landing pads 190 filling at least portions of the plurality of landing pad holes 190H, extending onto the plurality of bit line structures 140, and separated into a plurality of portions by a recess portion 190R are formed.

The plurality of landing pads 190 may be spaced apart from each other with the recess portion 190R therebetween. The plurality of landing pads 190 may be disposed on the plurality of buried contacts 170 and may extend onto the plurality of bit line structures 140. In some embodiments, the plurality of landing pads 190 may extend onto the plurality of bit lines 147. The plurality of landing pads 190 may be disposed on the plurality of buried contacts 170, and the plurality of buried contacts 170 and the plurality of landing pads 190 corresponding to each other may be electrically connected to each other. The buried contact 170 and the landing pad 190 corresponding to each other may be collectively referred to as a contact plug. The plurality of landing pads 190 may be connected to the active areas 118 through the plurality of buried contacts 170. The plurality of landing pads 190 may constitute the plurality of landing pads LP of FIG. 2.

The buried contact 170 may be disposed between two adjacent bit line structures 140, and one of the plurality of landing pads 190 may extend onto one bit line structure 140 from between two bit line structures 140 adjacent to each other with the buried contact 170 therebetween.

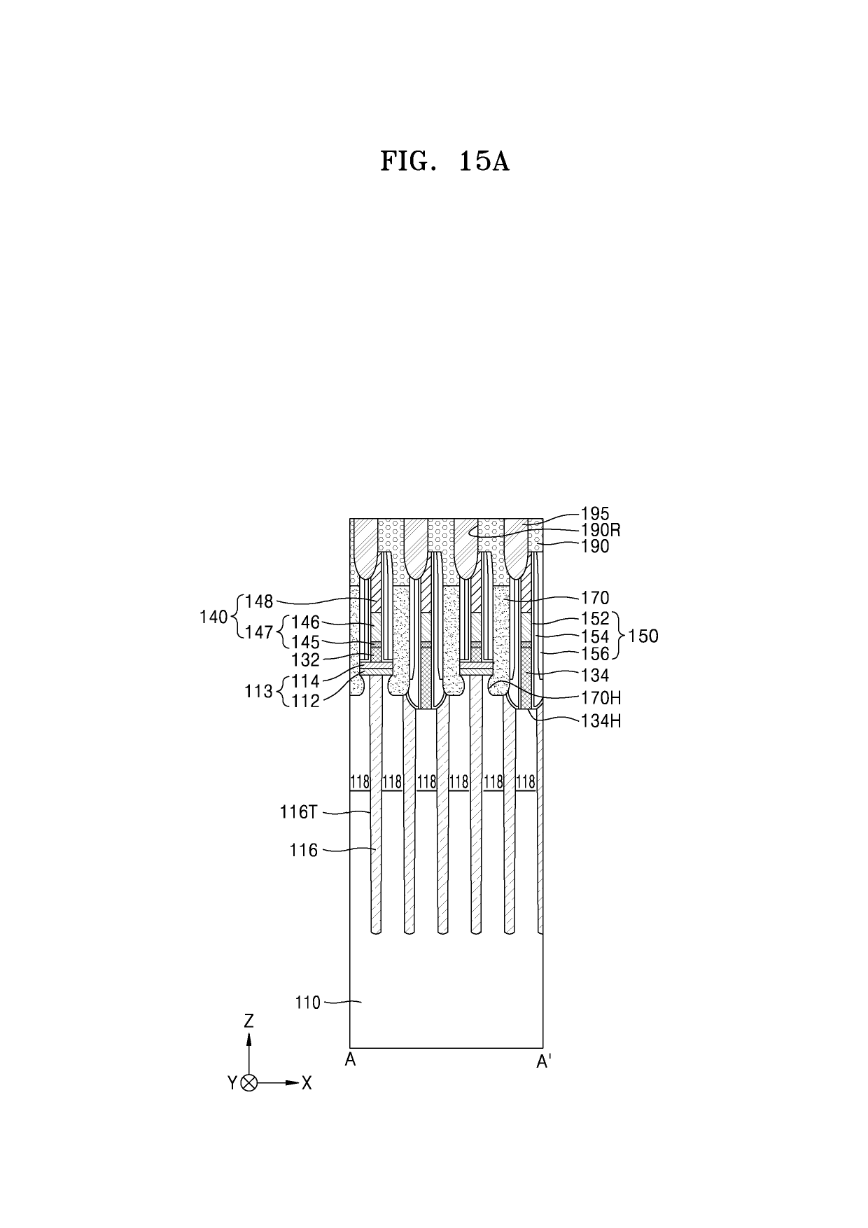

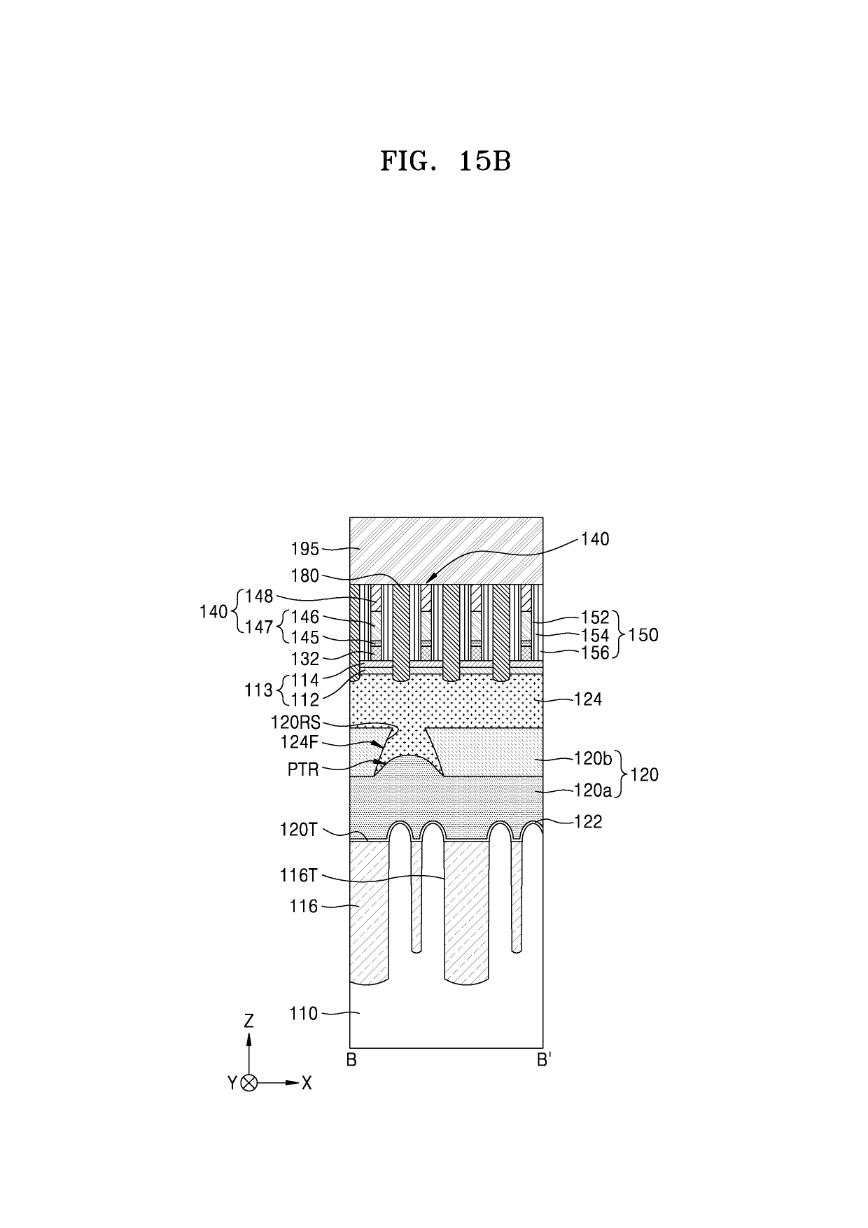

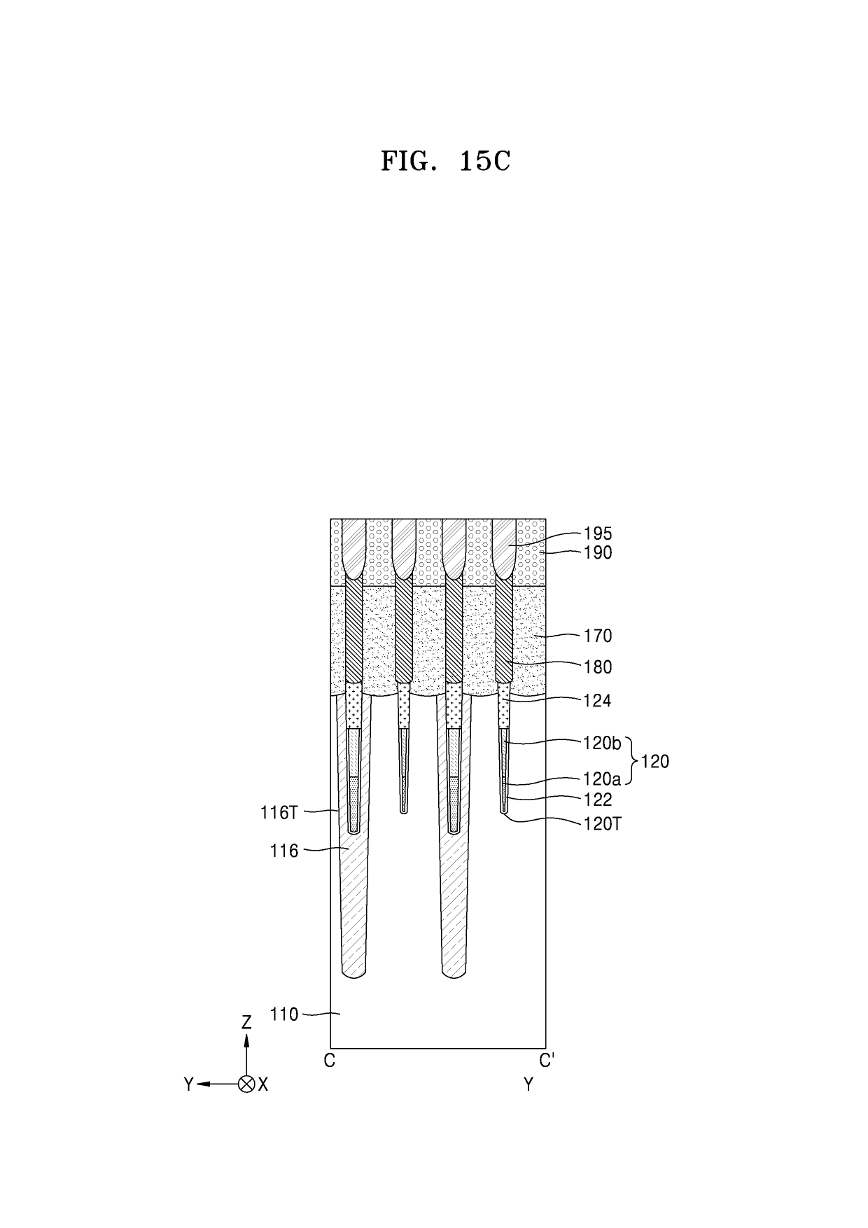

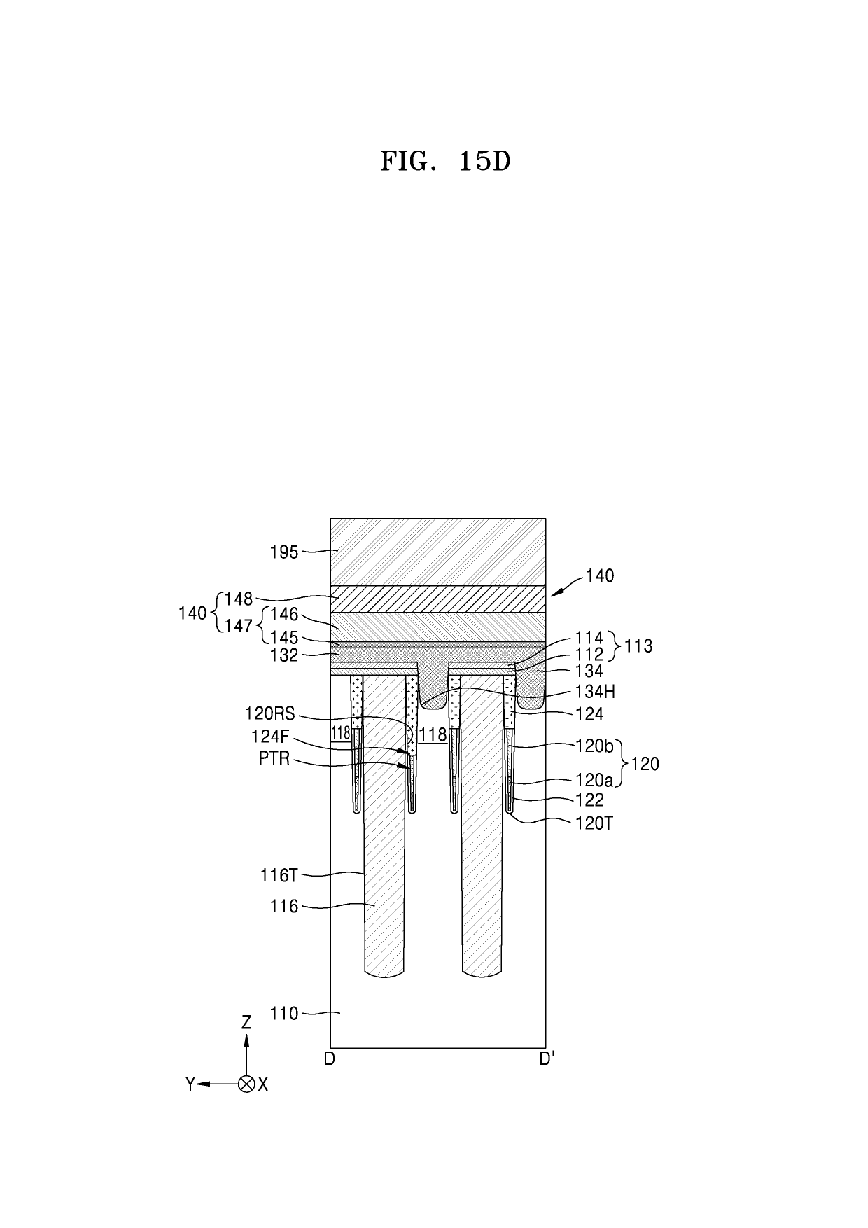

Referring to FIGS. 15A to 15D, a filling insulating layer 195 filling the recess portion 190R may be formed. In some embodiments, the filling insulating layer 195 may have a stacked structure including an oxide film and a nitride film. Although a top surface of the filling insulating layer 195 and a top surface of the landing pad 190 are at the same level in FIGS. 15A and 15C, embodiments are not limited thereto.

Referring to FIGS. 16A to 16D, an etching stop layer 206 covering the plurality of landing pads 190 and the filling insulating layer 195 is formed. For example, the etching stop layer 206 may include SiN, SiBN, SiCN, SiC, SiON, SiCO, SiCON, SiBC, SiBON, SiBCO, SiBCN, or SiBCON. A plurality of lower electrodes 210, a capacitor dielectric layer 220, and an upper electrode 230 passing through the etching stop layer 206 to contact the plurality of landing pads 190 and extending upward in the vertical direction (Z direction) are sequentially formed, and a plurality of capacitor structures 200 formed of the plurality of lower electrodes 210, the capacitor dielectric layer 220, and the upper electrode 230 are formed to form the semiconductor memory device 1.

For example, after a mold layer is formed on the etching stop layer 206 and then a plurality of mold through-holes passing through the mold layer and exposing the etching stop layer 206 on bottom surfaces are formed, at least a portion of each of the plurality of landing pads 190 may be exposed by removing portions of the etching stop layer 206 exposed on the bottom surfaces of the plurality of mold through holes. Next, after the plurality of lower electrodes 210 filling the plurality of mold through holes are formed, the mold layer may be removed. The plurality of lower electrodes 210 may constitute the plurality of storage nodes SN of FIG. 2. The plurality of lower electrodes 210 may be electrically connected to the plurality of landing pads 190, respectively. Each of the plurality of lower electrodes 210 may have a pillar shape of which the inside is filled to have a circular horizontal cross-section, but embodiments are not limited thereto. In some embodiments, each of the plurality of lower electrodes 210 may have a cylindrical shape with a closed bottom. In some embodiments, the plurality of lower electrodes 210 may be arranged in a honeycomb shape in a zigzag manner along the first horizontal direction (X direction) or the second horizontal direction (Y direction). In some embodiments, the plurality of lower electrodes 210 may be arranged in a matrix shape along each of the first horizontal direction (X direction) and the second horizontal direction (Y direction). For example, the plurality of lower electrodes 210 may be formed of silicon doped with impurities, a metal such as tungsten or copper, or a conductive metal compound such as titanium nitride. In some embodiments, the plurality of lower electrodes 210 may include titanium nitride. In some embodiments, at least one support pattern contacting side walls of the plurality of lower electrodes 210 may be further formed. For example, a plurality of support patterns contacting side walls of the plurality of lower electrodes 210 and located at different vertical levels may be further formed.

The capacitor dielectric layer 220 may be formed to conformally cover surfaces of the plurality of lower electrodes 210. The upper electrode 230 may be formed to cover the plurality of lower electrodes 210 with the capacitor dielectric layer 220 therebetween.

For example, the capacitor dielectric layer 220 may have a thickness of about 40 Å to about 70 Å and may cover surfaces of the plurality of lower electrodes 210. The capacitor dielectric layer 220 may be formed of, for example, TaO, TaAlO, TaON, AlO, AlSiO, HfO, HfSiO, ZrO, ZrSiO, TiO, TiAlO, BST((Ba,Sr)TiO), STO(SrTiO), BTO(BaTiO), PZT(Pb,Zr,Ti)O), (Pb,La)(Zr,Ti)O, Ba(Zr,Ti)O, Sr(Zr,Ti)O, or a combination thereof.

The upper electrode 230 may be formed of, for example, a semiconductor material such as doped polysilicon or doped polycrystalline silicon germanium (SiGe), a metal-based material such as W, Ru, Pt, Ir, V, Mo, Ta, Nb, In, TiN, VN, MoN, TaN, NbN, InN, RuO, PtO, IrO, TiO, VO, MoO, TaO, NbO, InO, SRO(SrRuO), BSRO((Ba,Sr)RuO), CRO(CaRuO), BaRuO, or La(Sr,Co)O, or a combination thereof. In some embodiments, the upper electrode 230 may include a metal material such as W or Ru. In some embodiments, the upper electrode 230 may have a stacked structure including a semiconductor material and a metal-based material. For example, the upper electrode 230 may have a stacked structure including at least two layers including a metal-based material and a semiconductor material covering the metal-based material, or may have a stacked structure including at least three layers including a semiconductor material, a metal-based material covering the semiconductor material, and a semiconductor material covering the metal-based material.

The semiconductor memory device 1 includes the substrate 110 including the plurality of active areas 118, the plurality of gate dielectric films 122, the plurality of word lines 120, and the plurality of buried insulating films 124 sequentially formed inside the plurality of word line trenches 120T crossing the plurality of active areas 118 in the substrate 110, the insulating structure 113 covering the device isolation film 116, the plurality of active areas 118, and the plurality of buried insulating films 124, the plurality of bit line structures 140 on the insulating structure 113, the plurality of insulating spacer structures 150 covering both side walls of the plurality of bit line structures 140, the plurality of buried contacts 170 filling a lower portion of a space defined by the plurality of insulating fences 180 and the plurality of insulating spacer structures 150 and connected to the plurality of active areas 118, the plurality of landing pads 190 filling an upper portion of the space defined by the plurality of insulating fences 180 and the plurality of insulating spacer structures 150 and extending to an upper portion of the bit line structure 140, the etching stop layer 206 disposed on the plurality of landing pads 190, and the plurality of capacitor structures 200 including the plurality of lower electrodes 210 passing through the etching stop layer 206 and connected to the plurality of landing pads 190, the capacitor dielectric layer 220, and the upper electrode 230.

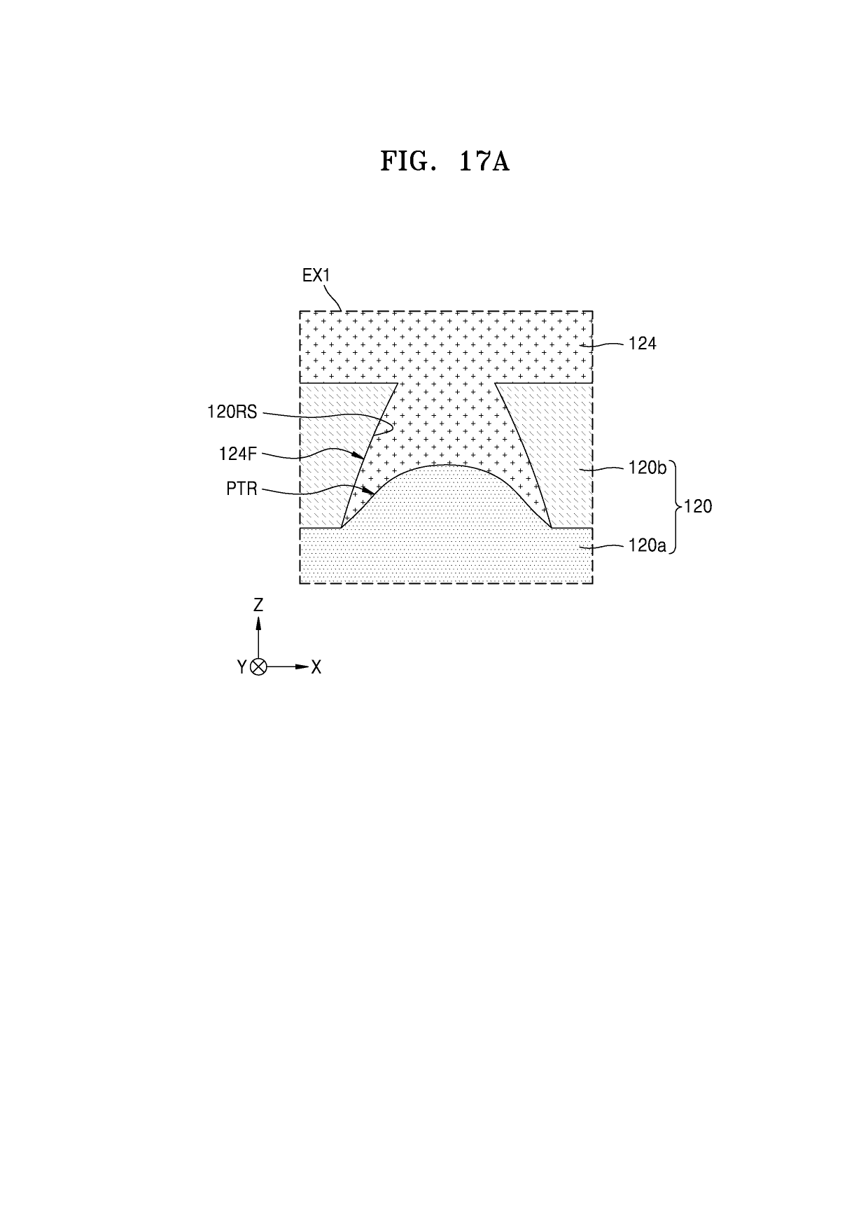

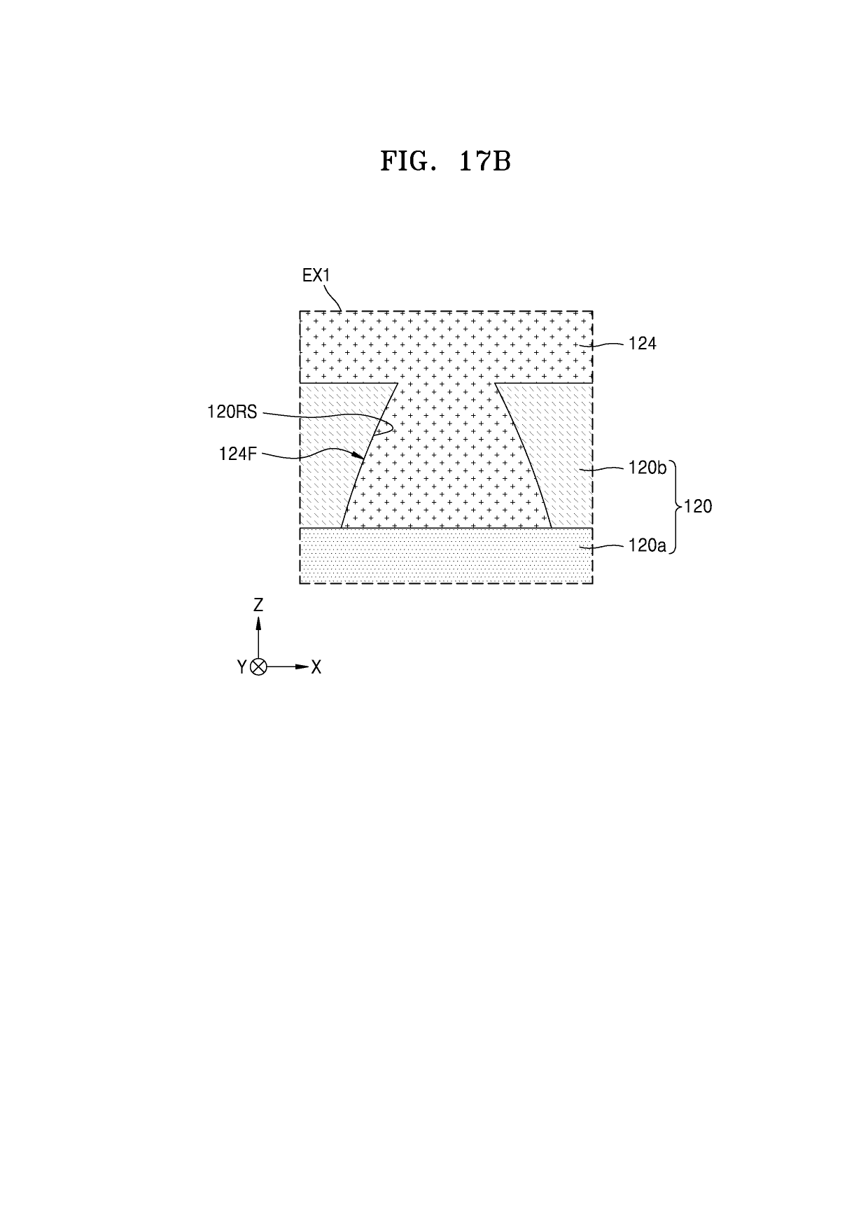

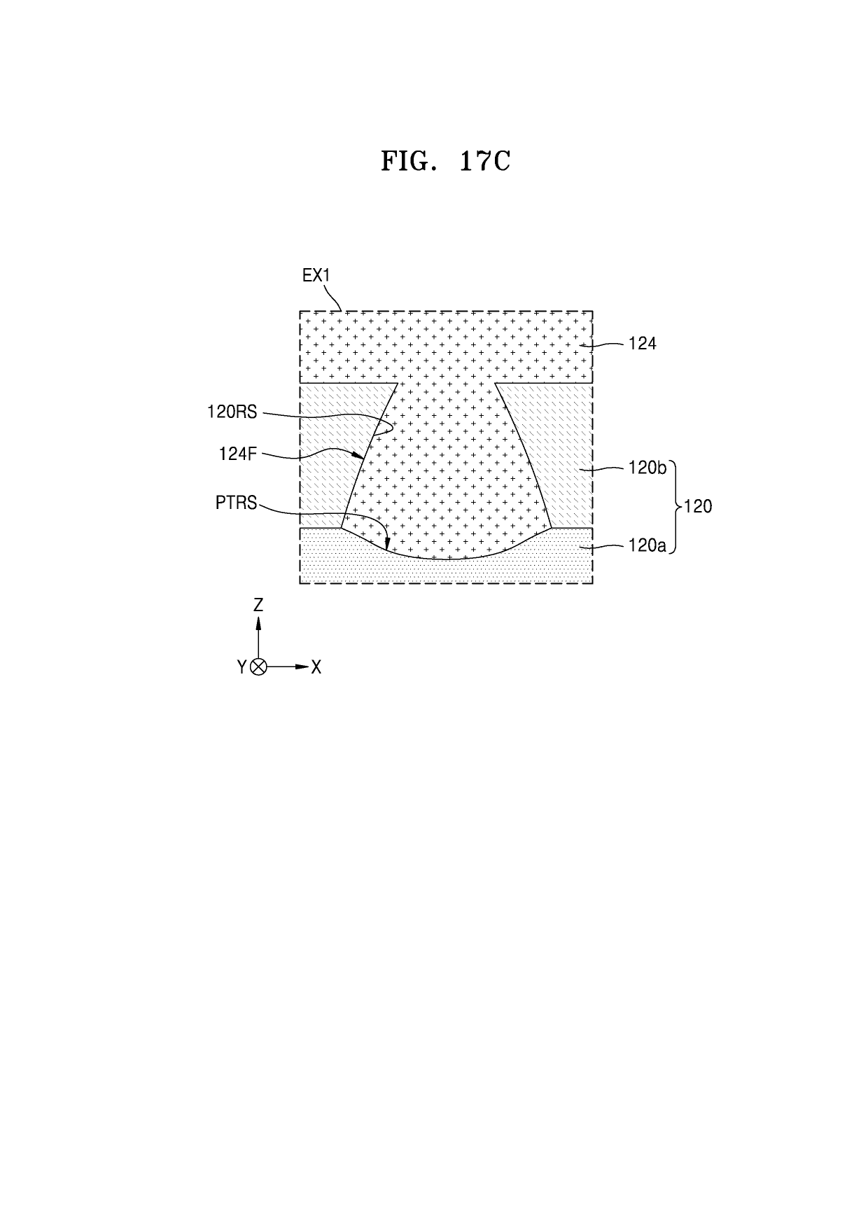

FIGS. 17A to 17C are partially enlarged views illustrating a semiconductor memory device, according to embodiments. In detail, FIGS. 17A to 17C are enlarged cross-sectional views each illustrating a portion EX1 of FIG. 16B.

Referring to FIGS. 16A to 16D and FIG. 17A, each of the plurality of word lines 120 may have a stacked structure including the lower word line layer 120a and the upper word line layer 120b. At least some of the plurality of word lines 120 may have the electrode recess 120RS. At least some of the plurality of upper word line layers 120b may be separated into two portions by the electrode recess 120RS and may be spaced apart from each other in the first horizontal direction (X direction). The plurality of buried insulating films 124 may be located on the plurality of word lines 120 and may cover the plurality of word lines 120. At least some of the plurality of lower word line layers 120a may include the protrusion PTR at a portion corresponding to the electrode recess 120RS. The protrusion PTR may protrude toward the electrode recess 120RS in the vertical direction (Z direction) more than other portions of the lower word line layer 120a.

At least some of the plurality of buried insulating films 124 may include the extension insulating portion 124F filling the electrode recess 120RS included in at least some of the plurality of word lines 120 and extending into the word line 120. The extension insulating portion 124F may contact the lower word line layer 120a. In some embodiments, the extension insulating portion 124F may contact the protrusion PTR included in the lower word line layer 120a. Some of the plurality of upper word line layers 120b may extend in the first horizontal direction (X direction) and may be spaced apart from each other with the extension insulating portion 124F therebetween. For example, some of the plurality of upper word line layers 120b may be separated into two portions by the extension insulating portion 124F and may be spaced apart from each other in the first horizontal direction (X direction). At least some of the plurality of direct contact conductive patterns 134 and the plurality of word lines 120 may be spaced apart from each other without contacting each other, due to the extension insulating portion 124F filling the electrode recess 120RS. At portions corresponding to the protrusion PTR, along the first horizontal direction (X direction), the plurality of insulating films 124 may extend between the protrusion PTR and the plurality of upper word line layers 120b.

Accordingly, the semiconductor memory device 1 and the method of manufacturing the semiconductor memory device 1 according to embodiments may prevent a short circuit in which the plurality of direct contact conductive patterns 134 and the plurality of word lines 120 are electrically connected to each other even when the defect PT is formed as shown in FIGS. 5A to 5D. Accordingly, the method of manufacturing the semiconductor memory device 1 according to embodiments may form the semiconductor memory device 1 having a high degree of integration and operational reliability.

Referring to FIGS. 16A to 16D and FIG. 17B, each of the plurality of word lines 120 may have a stacked structure including the lower word line layer 120a and the upper word line layer 120b. At least some of the plurality of word lines 120 may include the electrode recess 120RS. At least some of the plurality of upper word line layers 120b may be separated into two portions by the electrode recess 120RS, and may be spaced apart from each other in the first horizontal direction (X direction). The plurality of buried insulating films 124 may be located on the plurality of word lines 120 and may cover the plurality of word lines 120. A top surface of a portion of the lower word line layer 120a corresponding to the electrode recess 120RS may be at substantially the same vertical level as top surfaces of other portions of the lower word line layer 120a. That is, top surfaces of the plurality of lower word line layers 120a may be at substantially the same vertical level. For example, in a process of removing the defect PTa included in the plurality of lower word line layers 120 described with reference to FIGS. 8A to 8D and 9A to 9D, a portion of the defect PTa may not remain.

At least some of the plurality of buried insulating films 124 may include the extension insulating portion 124F filling the electrode recess 120RS included in at least some of the plurality of word lines 120 and extending into the word line 120. The extension insulating portion 124F may contact a top surface of the lower word line layer 120a. Some of the plurality of upper word line layers 120b may extend in the first horizontal direction (X direction) and may be spaced apart from each other with the extension insulating portion 124F therebetween. For example, some of the plurality of upper word line layers 120b may be separated into two portions by the extension insulating portion 124F and may be spaced apart from each other in the first horizontal direction (X direction). At least some of the plurality of direct contact conductive patterns 134 may be spaced apart from each other without contacting the plurality of word lines 120, due to the extension insulating portion 124F filling the electrode recess 120RS.

Referring to FIGS. 16A to 16D, and FIG. 17C, each of the plurality of word lines 120 may have a stacked structure including the lower word line layer 120a and the upper word line layer 120b. At least some of the plurality of word lines 120 may include the electrode recess 120RS. At least some of the plurality of upper word line layers 120b may be separated into two portions by the electrode recess 120RS and may be spaced apart from each other in the first horizontal direction (X direction). The plurality of buried insulating films 124 may be located on the plurality of word lines 120 and may cover the plurality of word lines 120. At least some of the plurality of lower word line layers 120a may include a concave portion PTRS at a portion corresponding to the electrode recess 120RS. The concave portion PTRS may be referred to as a lower electrode recess. The lower word line layer 120a may have a top surface that is concave toward the inside of the lower word line layer 120a more than top surfaces of other portions of the lower word line layer 120a. For example, in a process of removing the defect PTa included in the plurality of lower word line layers 120a described with reference to FIGS. 8A to 8D and 9A to 9D, the defect PTa and a portion of the lower word line layer 120a other than the defect PTa may be removed together to form the concave portion PTRS.

At least some of the plurality of buried insulating films 124 may include the extension insulating portion 124F filling the electrode recess 120RS included in at least some of the plurality of word lines 120 and extending into the word line 120. The extension insulating portion 124F may contact the lower word line layer 120a. The extension insulating portion 124F may fill the concave portion PTRS included in the lower word line layer 120a. Some of the plurality of upper word line layers120b may extend in the first horizontal direction (X direction) and may be spaced apart from each other with the extension insulating portion 124F therebetween. For example, some of the plurality of upper word line layers 120b may be separated into two portions by the extension insulating portion 124F and may be spaced apart from each other in the first horizontal direction (X direction). At least some of the plurality of direct contact conductive patterns 134 and the plurality of word lines 120 may be spaced apart from each other without contacting each other, due to the extension insulating portion 124F filling the electrode recess 120RS. At portions corresponding to the concave portion PTRS, along the first horizontal direction (X direction), the plurality of insulating films 124 may extend between the plurality of lower word line layers 120a.

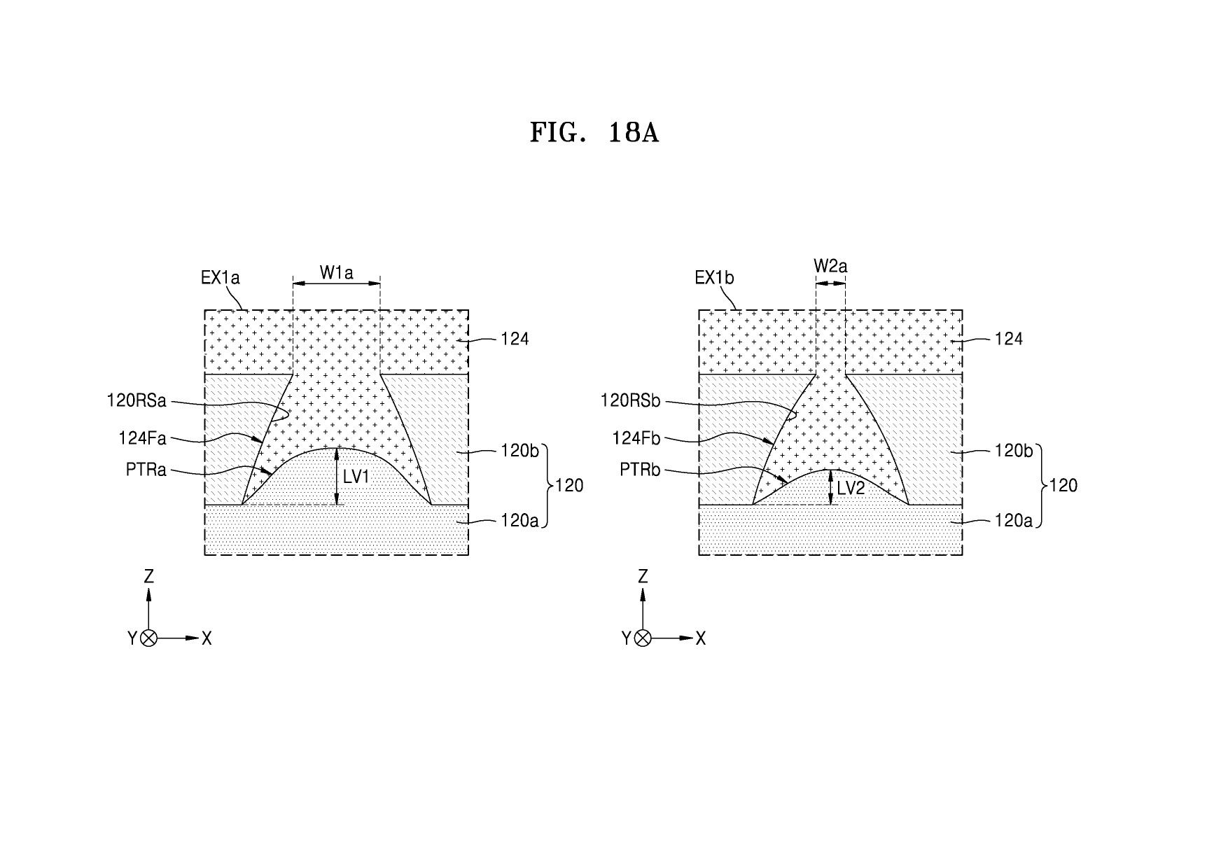

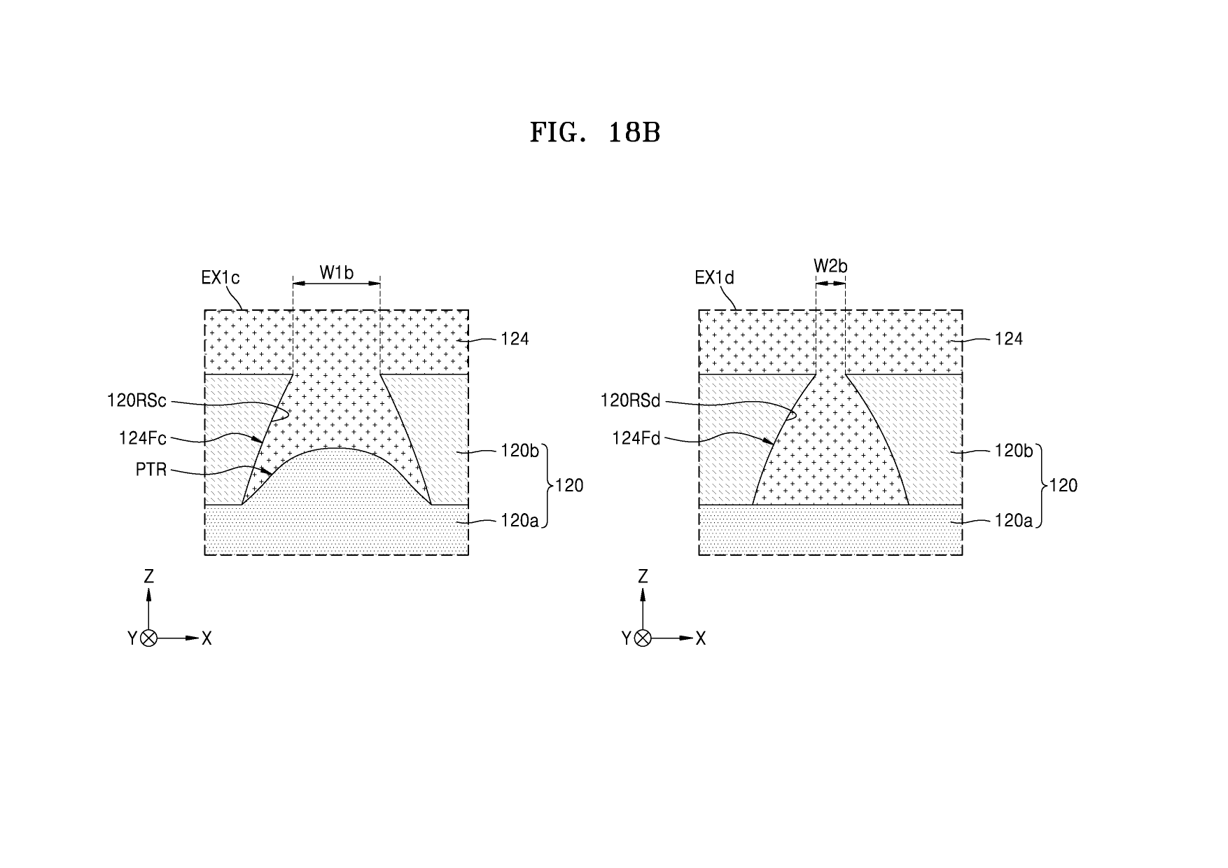

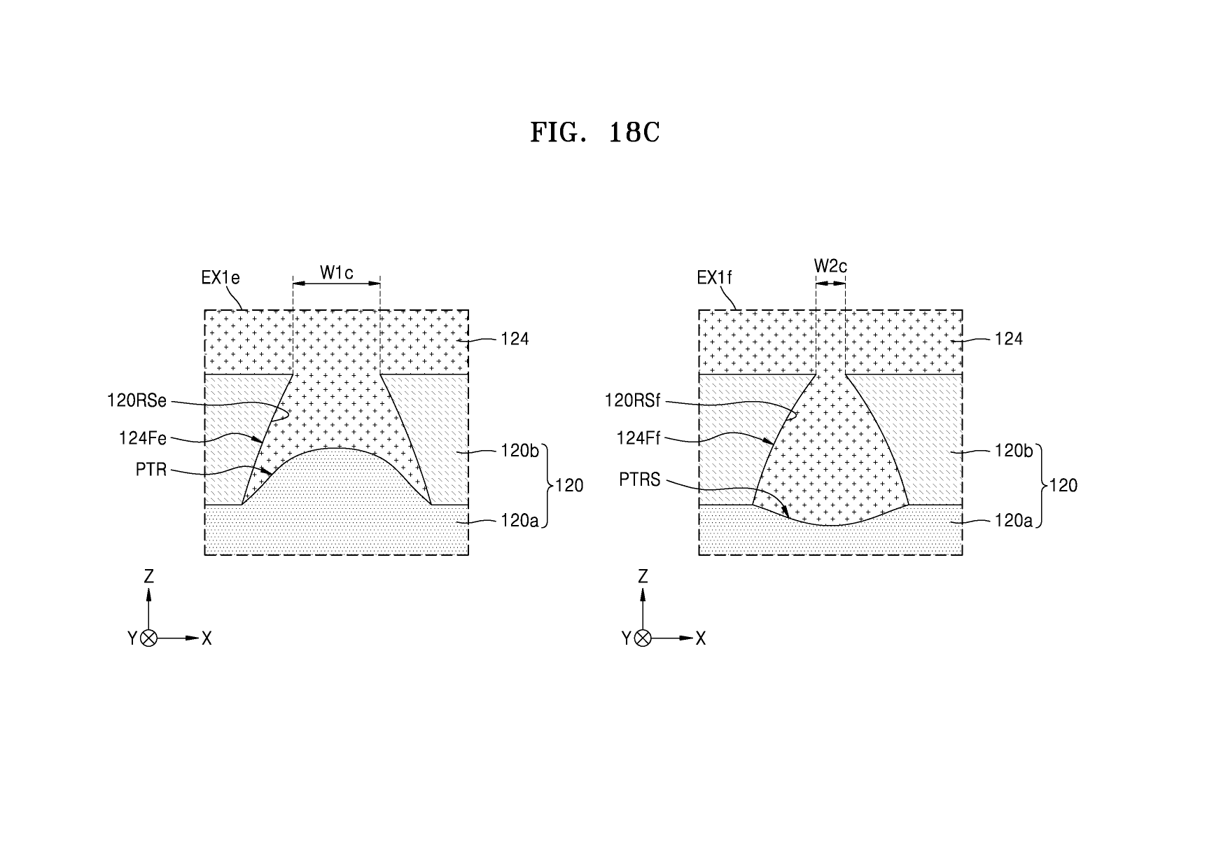

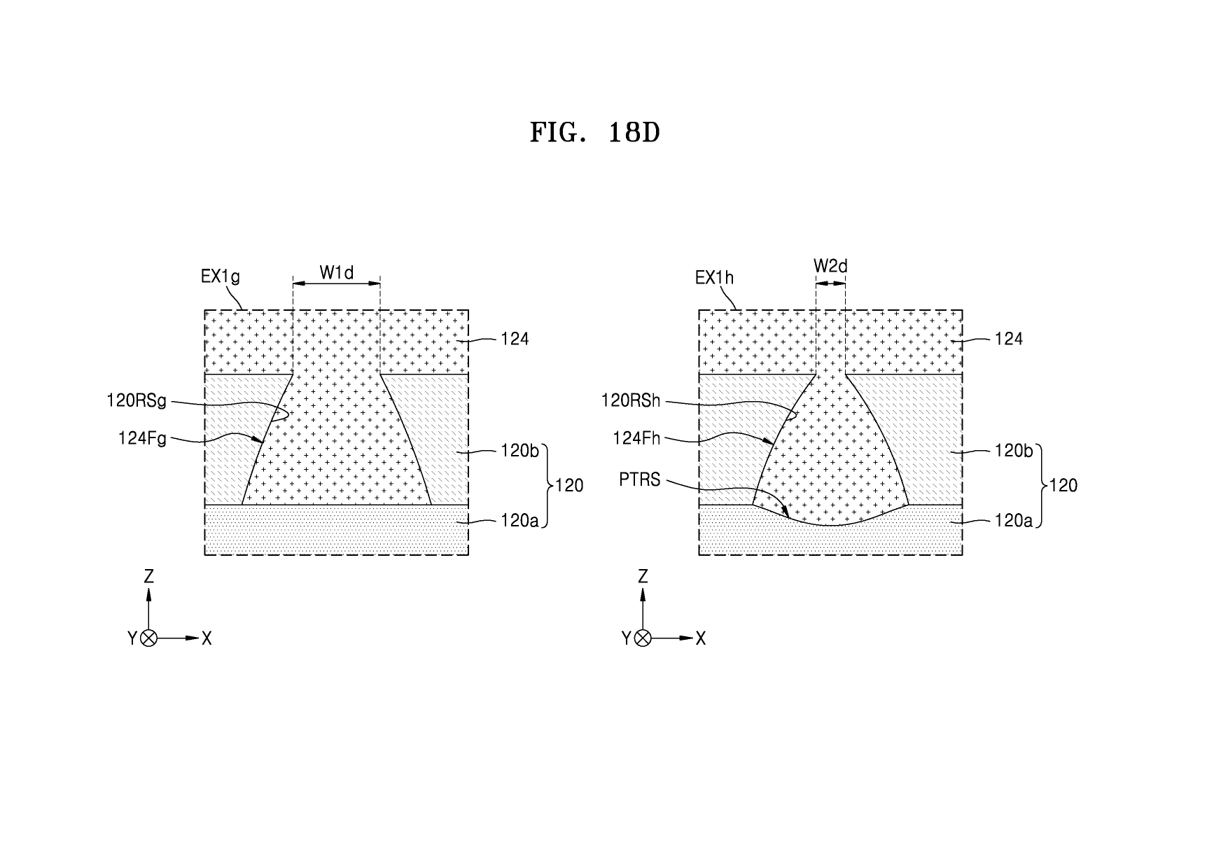

FIGS. 18A to 18D are partially enlarged views illustrating a semiconductor memory device, according to embodiments. In detail, portions EX1a and EX1b of FIG. 18A are other portions corresponding to EX1 of FIG. 16B, portions EX1c and EX1d of FIG. 18B are other portions corresponding to EX1 of FIG. 16B, portions EX1e and EX1f of FIG. 18C are other portions corresponding to EX1 of FIG. 16B, and portions EX1g and EX1h of FIG. 18D are other portions corresponding to EX1 of FIG. 16B.

Referring to FIGS. 16A to 16D and FIG. 18A, each of the plurality of word lines 120 may have a stacked structure including the lower word line layer 120a and the upper word line layer 120b. At least some of the plurality of word lines 120 may include a first electrode recess 120RSa, and at least some of the plurality of word lines 120 may include a second electrode recess 120RSb. In the first horizontal direction (X direction), a first horizontal width W1a, which is a horizontal width of an uppermost end of the first electrode recess 120RSa, may be greater than a second horizontal width W2a, which is a horizontal width of an uppermost end of the second electrode recess 120RSb. At least some of the plurality of lower word line layers 120a may include a first protrusion PTRa at a portion corresponding to the first electrode recess 120RSa, and at least some of the plurality of lower word line layers120a may include a second protrusion PTRb at a portion corresponding to the second electrode recess 120RSb. The first protrusion PTRa may protrude by a first height LV1 toward the first electrode recess 120RSa in the vertical direction (Z direction) more than other portions of the lower word line layer 120a. The second protrusion PTRb may protrude by a second height LV2 lower than the first height LV1 toward the second electrode recess 120RSb in the vertical direction (Z direction) more than other portions of the lower word line layer 120a. At least some of the plurality of buried insulating films 124 may include a first extension insulating portion 124Fa filling the first electrode recess 120RSa included in at least some of the plurality of word lines 120 and extending into the word line 120. The first extension insulating portion 124Fa may contact the first protrusion PTRa. At least some of the plurality of buried insulating films 124 may include a second extension insulating portion 124Fb filling the second electrode recess 120RSb included in at least some of the plurality of word lines 120 and extending into the word line 120. The second extension insulating portion 124Fb may contact the second protrusion PTRb. At the same vertical level, horizontal widths of the first electrode recess 120RSa and the first extension insulating portion 124Fa in the first horizontal direction (X direction) may be greater than horizontal widths of the second electrode recess 120RSb and the second extension insulating portion 124Fb, respectively.

For example, when the defect PT shown in FIGS. 5A to 5D is relatively large, for example, when a height of the defect PT is relatively high, the first electrode recess 120RSa, the first protrusion PTRa, and the first extension insulating portion 124Fa may be formed; and when the defect PT shown in FIGS. 5A to 5D is relatively small, for example, when a height of the defect PT is relatively low, the second electrode recess 120RSb, the second protrusion PTRb, and the second extension insulating portion 124Fb may be formed.

Referring to FIGS. 16A to 16D and FIG. 18B, each of the plurality of word lines 120 may have a stacked structure including the lower word line layer 120a and the upper word line layer 120b. At least some of the plurality of word lines 120 may include a first electrode recess 120RSc, and at least some of the plurality of word lines 120 may include a second electrode recess 120RSd. In the first horizontal direction (X direction), a first horizontal width W1b, which is a horizontal width of an uppermost end of the first electrode recess 120RSc, may be greater than a second horizontal width W2b, which is a horizontal width of an uppermost end of the second electrode recess 120RSd. At least some of the plurality of lower word line layers 120a may include the protrusion PTR at a portion corresponding to the first electrode recess 120RSc, and at least some of the plurality of lower word line layers 120a may be formed so that a top surface of a portion corresponding to the second electrode recess 120RSd is at substantially the same vertical level as top surfaces of other portions of the lower word line layer 120a.

At least some of the plurality of buried insulating films 124 may include a first extension insulating portion 124Fc filling the first electrode recess 120RSc included in at least some of the plurality of word lines 120 and extending into the word line 120. The first extension insulating portion 124Fc may contact the protrusion PTR. At least some of the plurality of buried insulating films 124 may include a second extension insulating portion 124Fd filling the second electrode recess 120RSd included in at least some of the plurality of word lines 120 and extending into the word line 120. The second extension insulating portion 124Fd may contact a top surface of the lower word line layer 120a. At the same vertical level, horizontal widths of the first electrode recess 120RSc and the first extension insulating portion 124Fc in the first horizontal direction (X direction) may be greater than horizontal widths of the second electrode recess 120RSd and the second extension insulating portion 124Fd, respectively.

For example, when the defect PT shown in FIGS. 5A to 5D is relatively large, for example, when a height of the defect PT is relatively high, the first electrode recess 120RSc, the protrusion PTR, and the first extension insulating portion 124Fc may be formed; and when the defect PT shown in FIGS. 5A to 5D is relatively small, for example, when a height of the defect PT is relatively low, the second electrode recess 120RSd and the second extension insulating portion 124Fd may be formed.

Referring to FIGS. 16A to 16D and FIG. 18C, each of the plurality of word lines 120 may have a stacked structure including the lower word line layer 120a and the upper word line layer 120b. At least some of the plurality of word lines 120 may include a first electrode recess 120RSe, and at least some of the plurality of word lines 120 may include a second electrode recess 120RSf. In the first horizontal direction (X direction), a first horizontal width W1c, which is a horizontal width of an uppermost end of the first electrode recess 120RSe, may be greater than a second horizontal width W2c, which is a horizontal width of an uppermost end of the second electrode recess 120RSf. At least some of the plurality of lower word line layers 120a may include the protrusion PTR at a portion corresponding to the first electrode recess 120RSe, and at least some of the plurality of lower word line layers 120a may include the concave portion PTRS at a portion corresponding to the second electrode recess 120RSf. At least some of the plurality of buried insulating films 124 may include a first extension insulating portion 124Fe filling the first electrode recess 120RSe included in at least some of the plurality of word lines 120 and extending into the word line 120. The first extension insulating portion 124Fe may contact the protrusion PTR. At least some of the plurality of buried insulating films 124 may include a second extension insulating portion 124Ff filling the second electrode recess 120RSf included in at least some of the plurality of word lines 120 and extending into the word line 120. The second extension insulating portion 124Ff may fill the concave portion PTRS. At the same vertical level, horizontal widths of the first electrode recess 120RSe and the first extension insulating portion 124Fe may be greater than horizontal widths of the second electrode recess 120RSf and the second extension insulating portion 124Ff, respectively.

For example, when the defect PT shown in FIGS. 5A to 5D is relatively large, for example, when a height of the defect PT is relatively high, the first electrode recess 120RSe, the protrusion PTR, and the first extension insulating portion 124Fe may be formed; and when the defect shown in FIGS. 5A to 5D is relatively small, for example, when a height of the defect PT is relatively low, the second electrode recess 120RSf, the concave portion PTRS, and the second extension insulating portion 124Ff may be formed.

Referring to FIGS. 16A to 16D and FIG. 18D, each of the plurality of word lines 120 may have a stacked structure including the lower word line layer 120a and the upper word line layer 120b. At least some of the plurality of word lines 120 may include a first electrode recess 120RSg, and at least some of the plurality of word lines 120 may include a second electrode recess 120RSh. In the first horizontal direction (X direction), a first horizontal width W1d, which is a horizontal width of an uppermost end of the first electrode recess 120RSg, may be greater than a second horizontal width W2d, which is a horizontal width of an uppermost end of the second electrode recess 120RSh. At least some of the plurality of lower word line layers 120a may be formed so that a top surface of a portion corresponding to the first electrode recess 120RSg is located at substantially the same vertical level as top surfaces of other portions of the lower word line layer 120a, and at least some of the plurality of lower word line layers 120 may include the concave portion PTRS at a portion corresponding to the second electrode recess 120RSh. At least some of the plurality of buried insulating films 124 may include a first extension insulating portion 124Fg filling the first electrode recess 120RSg included in at least some of the plurality of word lines 120 and extending into the word line 120. The first extension insulating portion 124Fg may contact a top surface of the lower word line layer 120a. At least some of the plurality of buried insulating films 124 may include a second extension insulating portion 124Fh filling the second electrode recess 120RSh included in at least some of the plurality of word lines 120 and extending into the word line 120. The second extension insulating portion 124Fh may fill the concave portion PTRS. In the first horizontal direction (X direction), horizontal widths of the first electrode recess 120RSg and the first extension insulating portion 124Fg may be greater than horizontal widths of the second electrode recess 120RSh and the second extension insulating portion 124Fh, respectively.

For example, when the defect PT shown in FIGS. 5A to 5D is relatively large, for example, when a height of the defect PT is relatively high, the first electrode recess 120RSg and the first extension insulating portion 124Fg may be formed; and when the defect PT shown in FIGS. 5A to 5D is relatively small, for example, when a height of the defect PT is relatively low, the second electrode recess 120RSh, the concave portion PTRS, and the second extension insulating portion 124Fh may be formed.

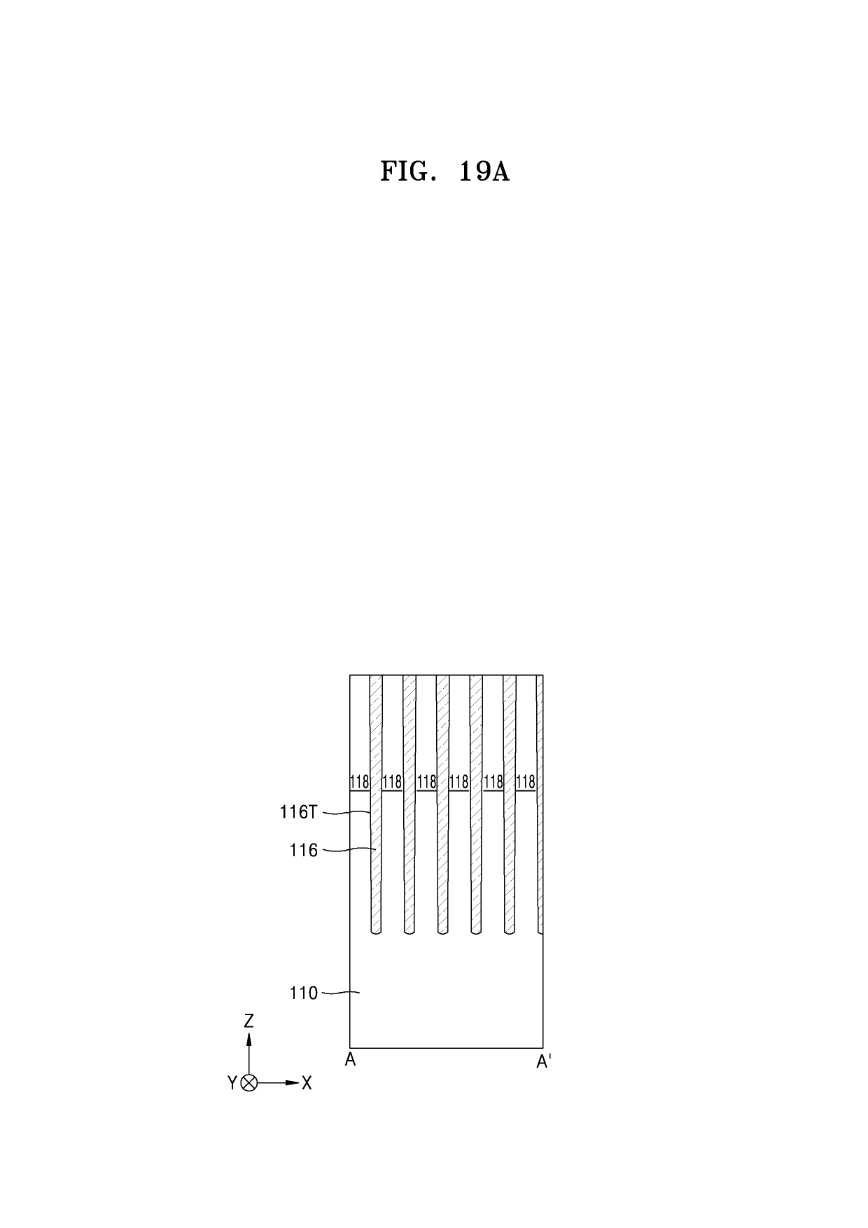

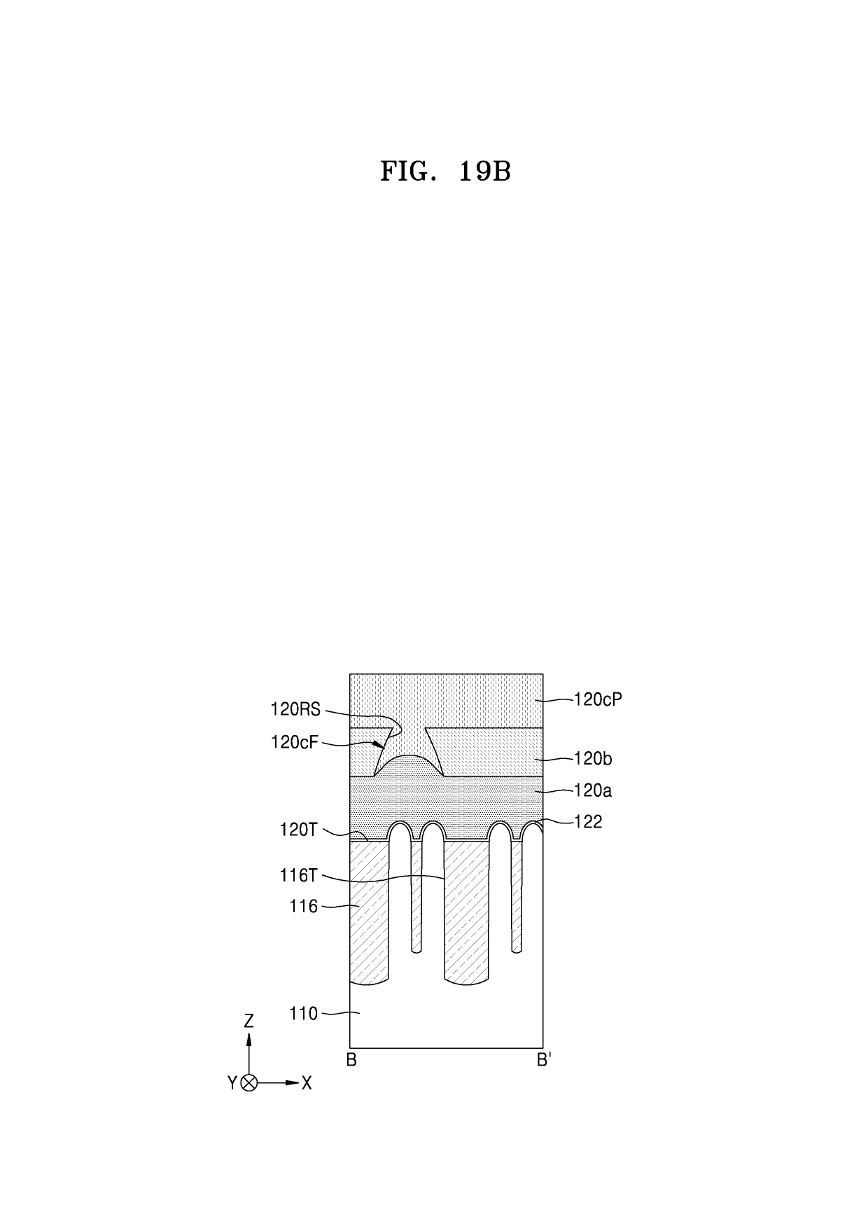

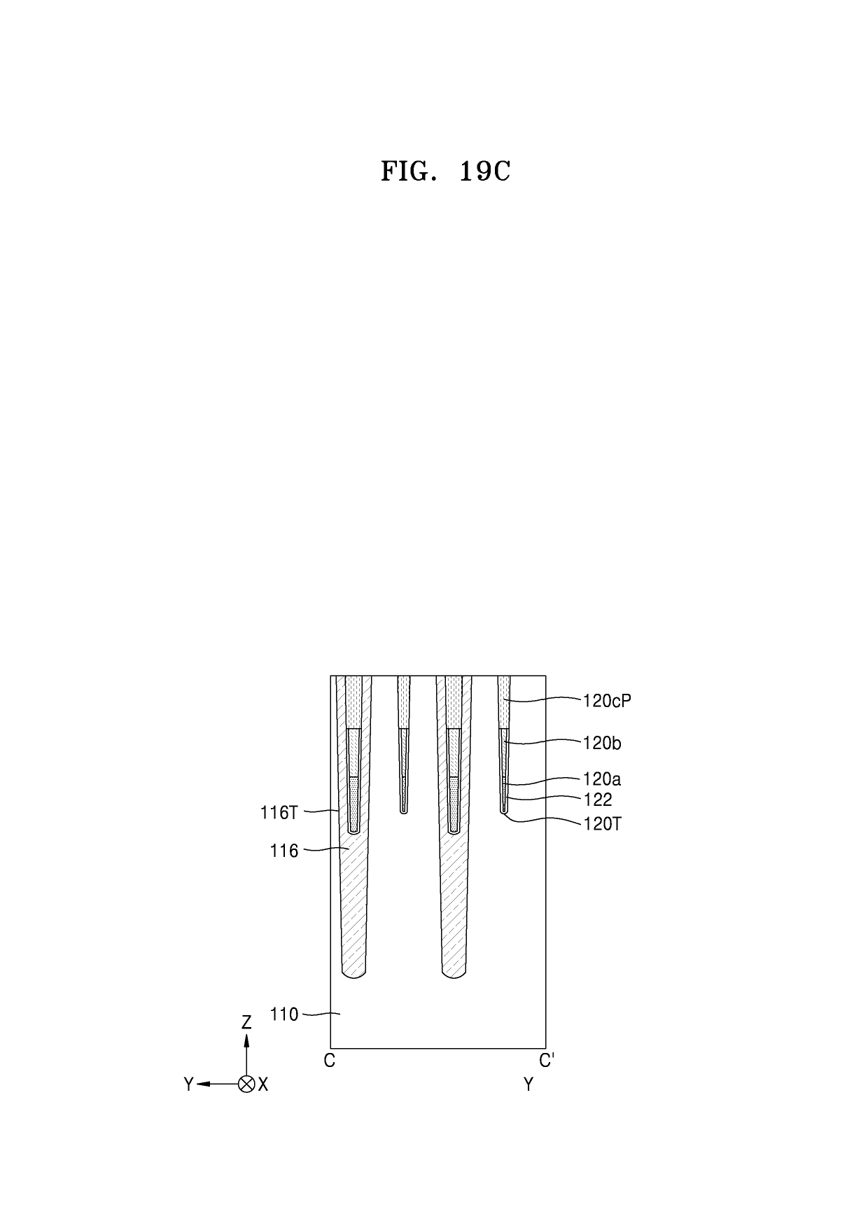

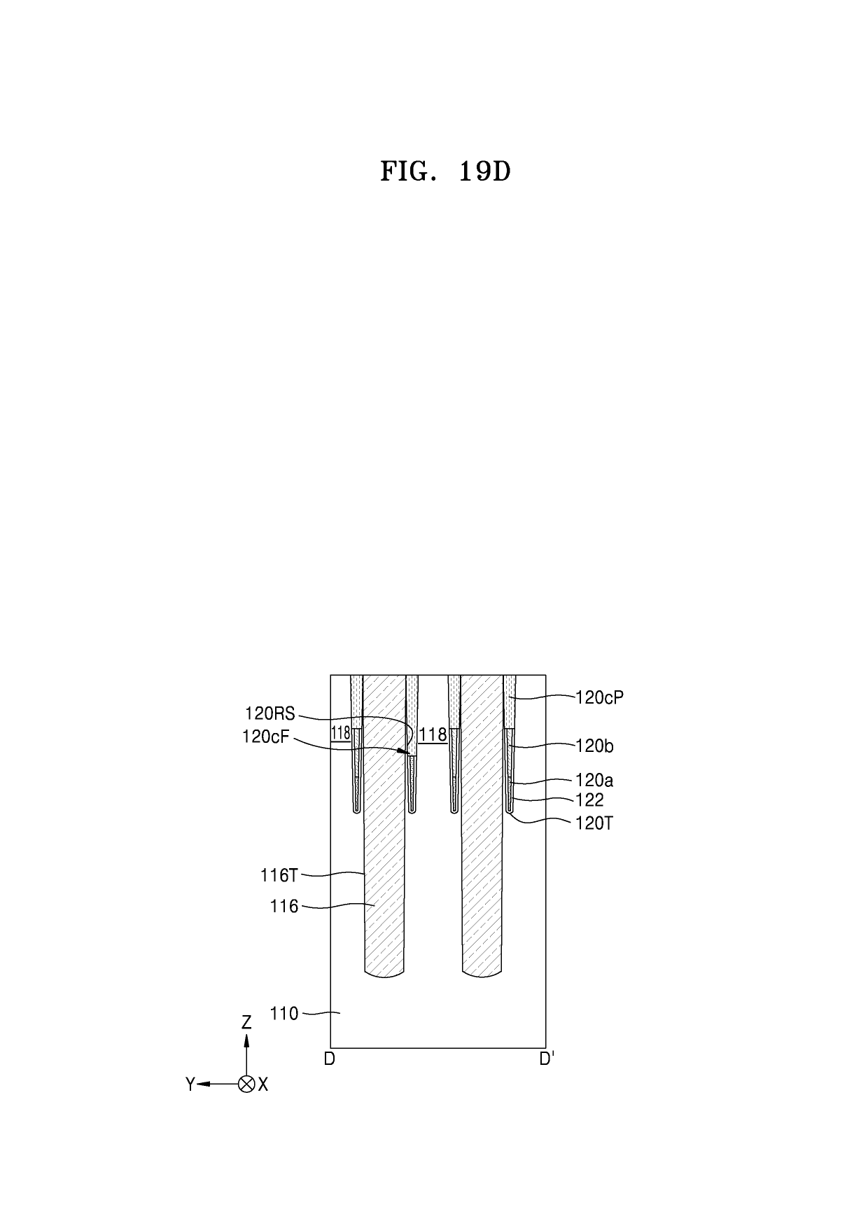

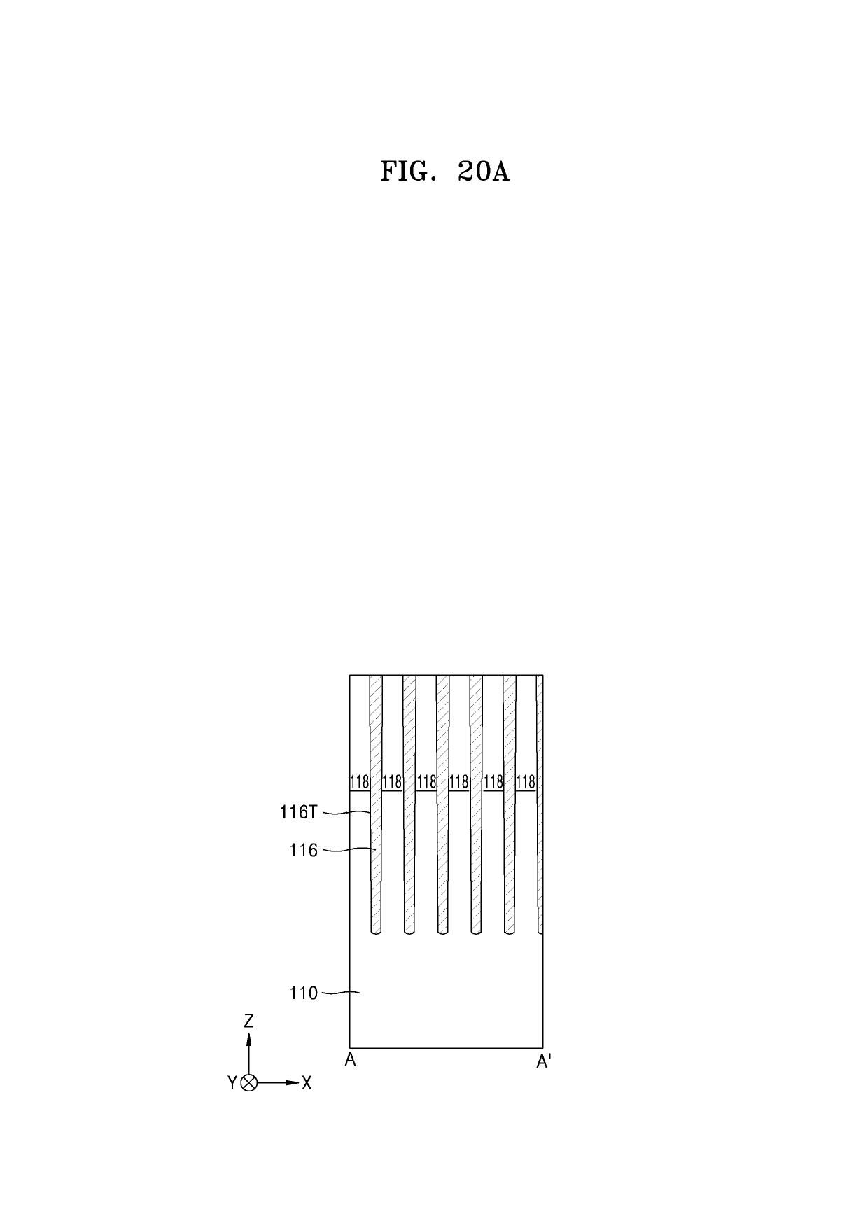

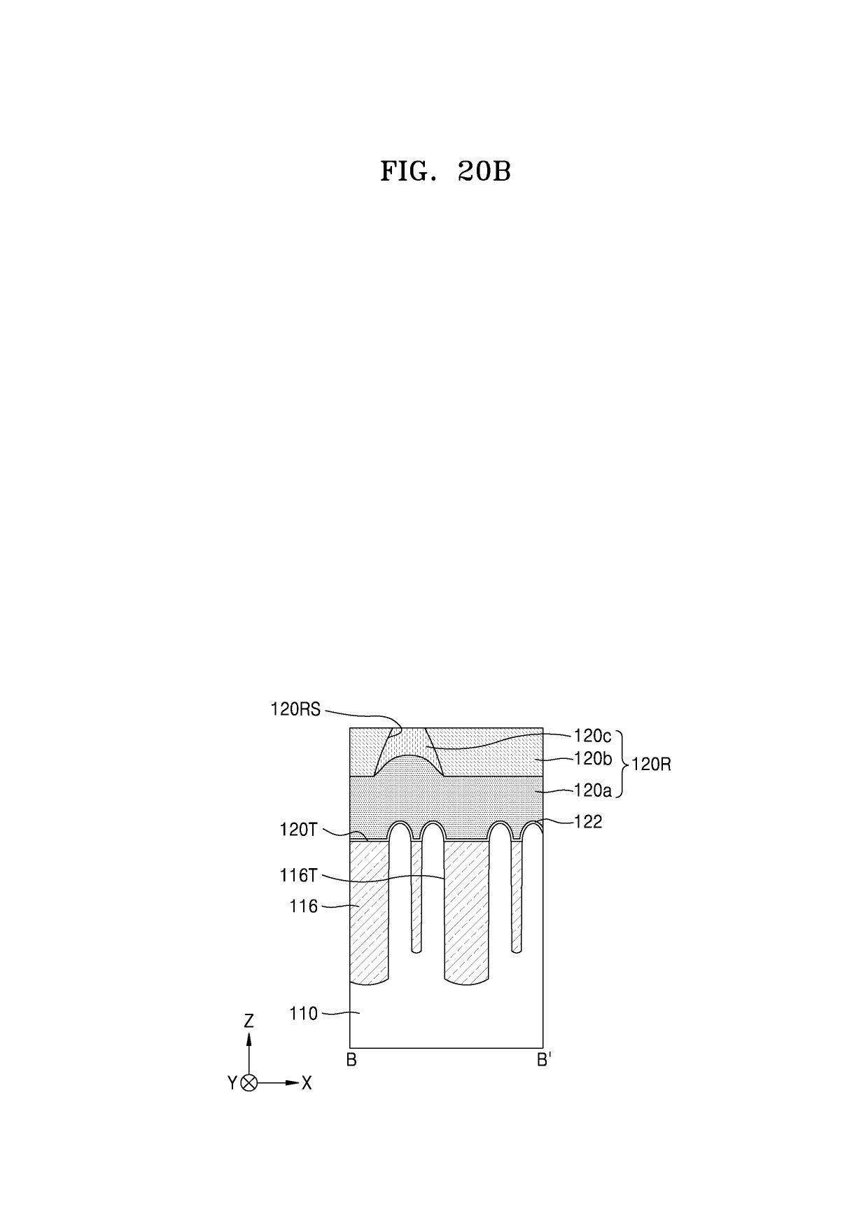

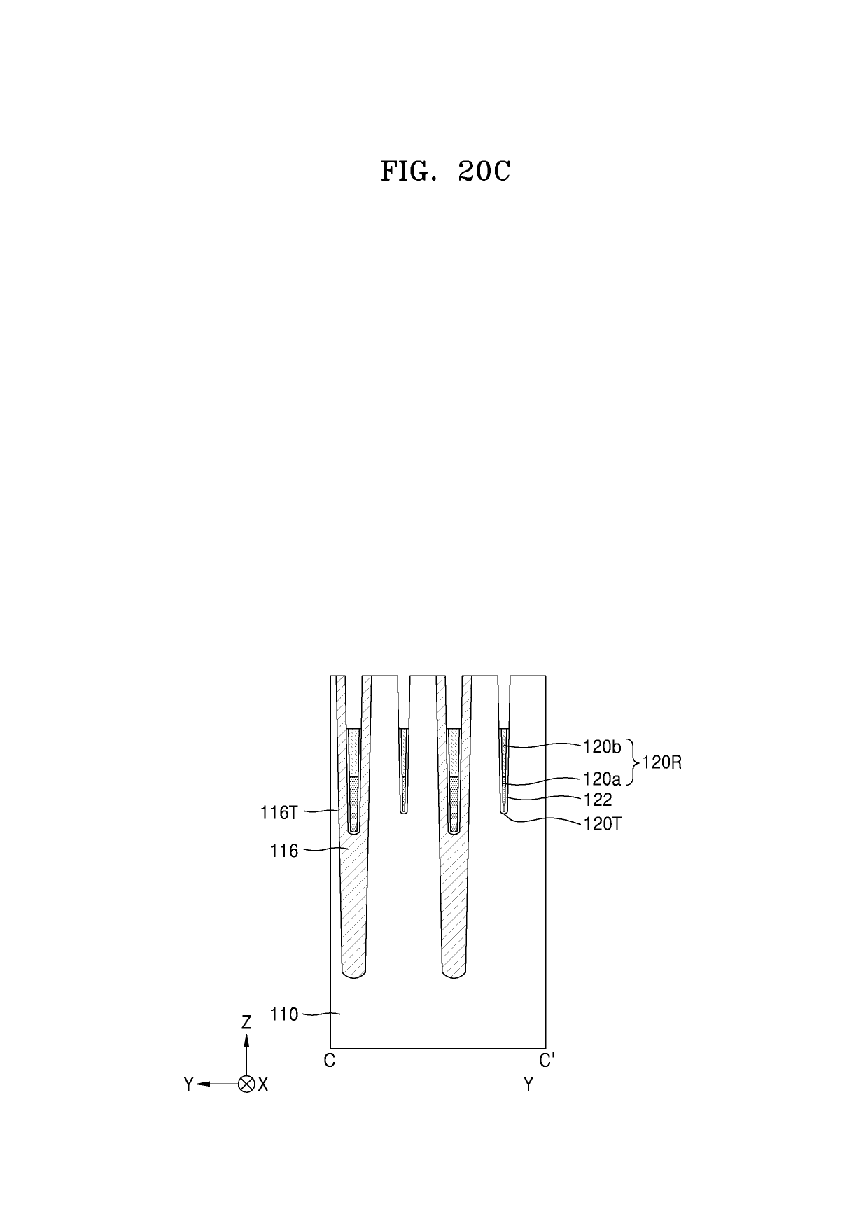

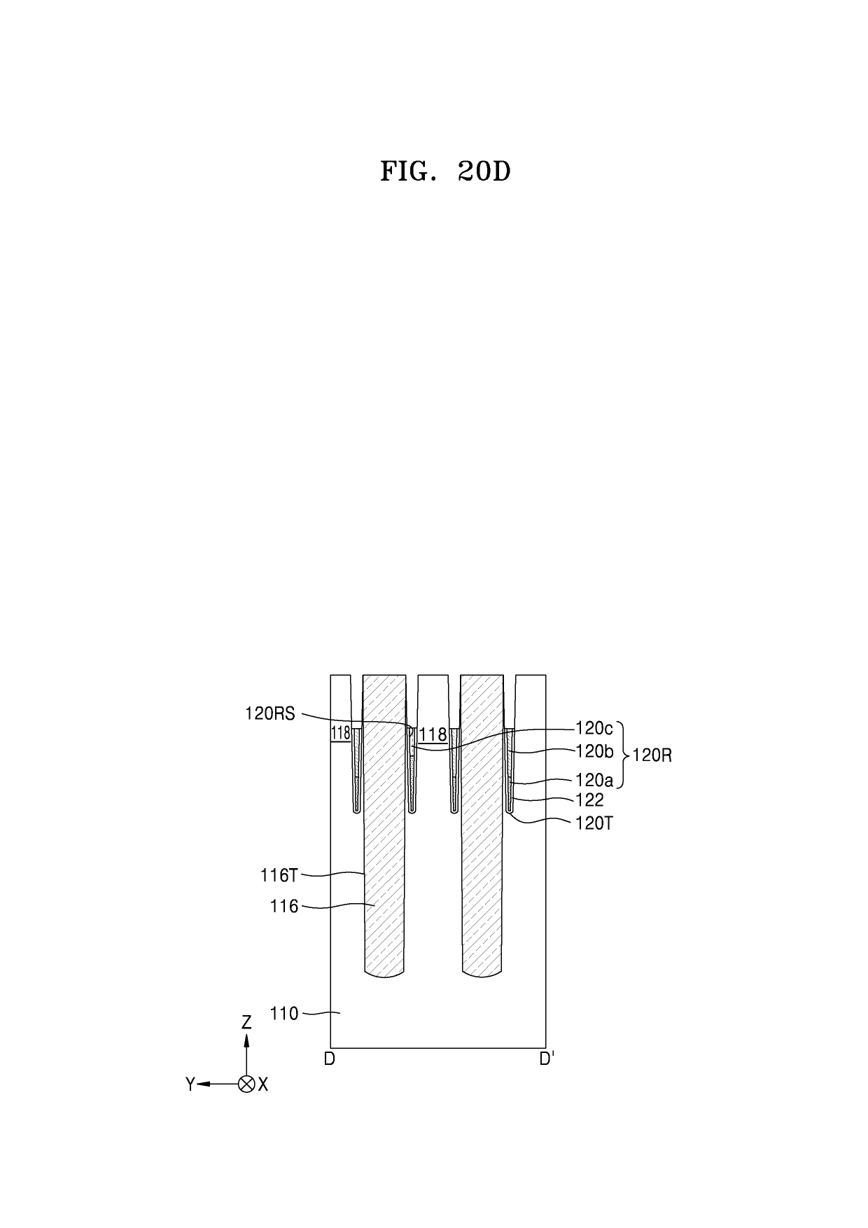

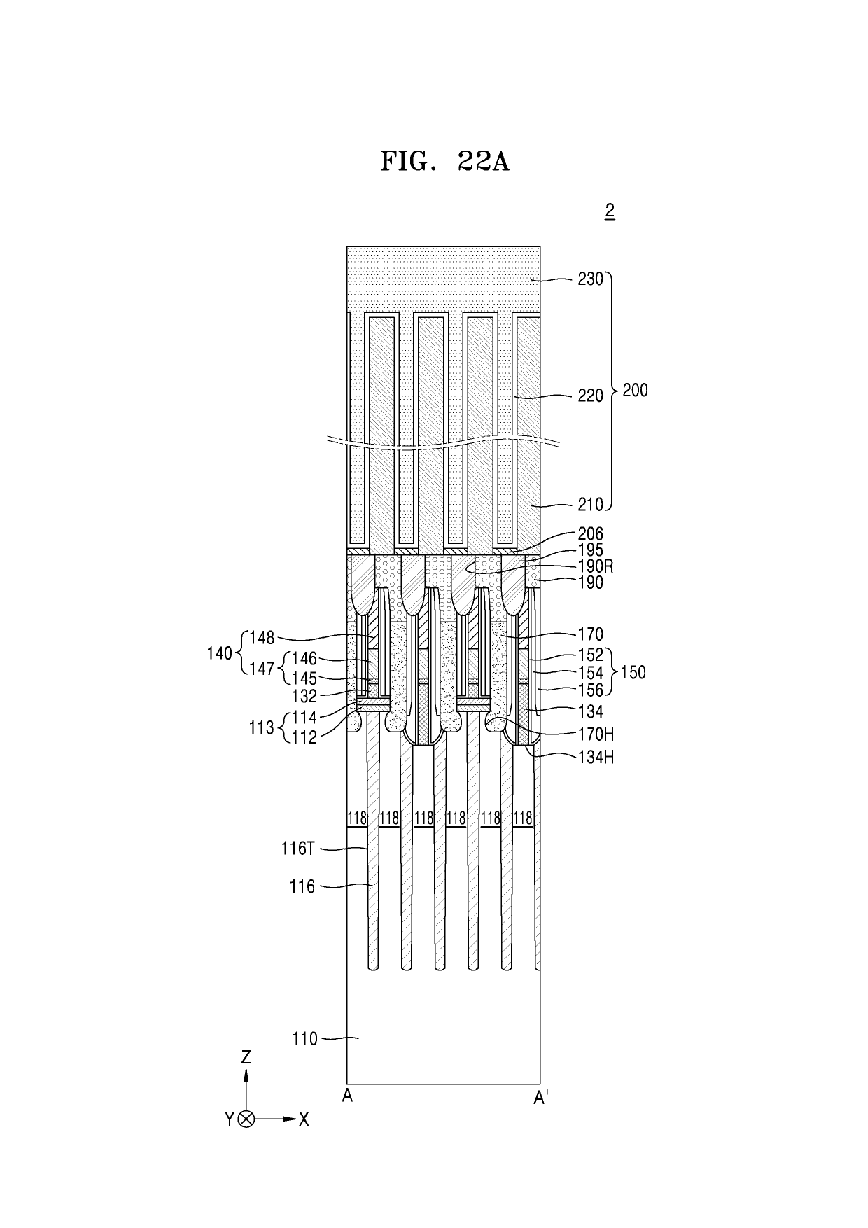

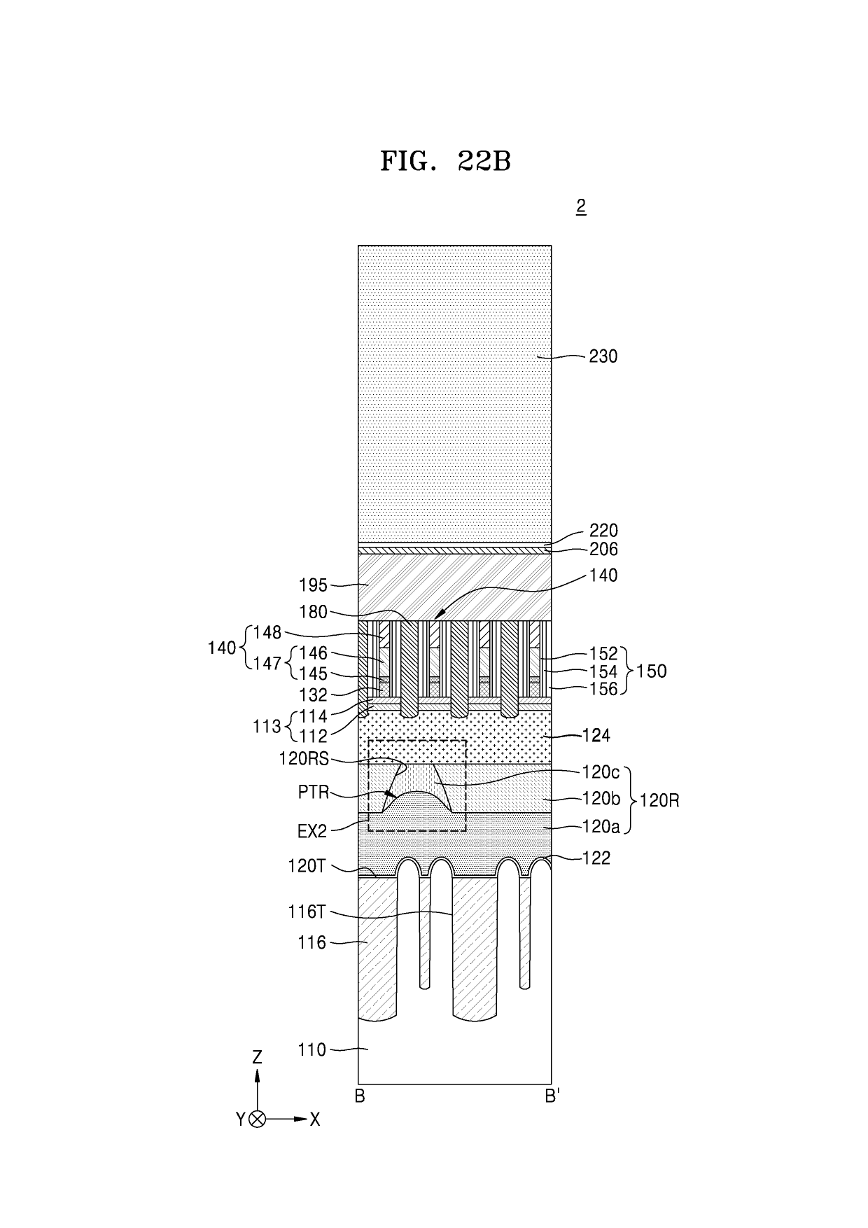

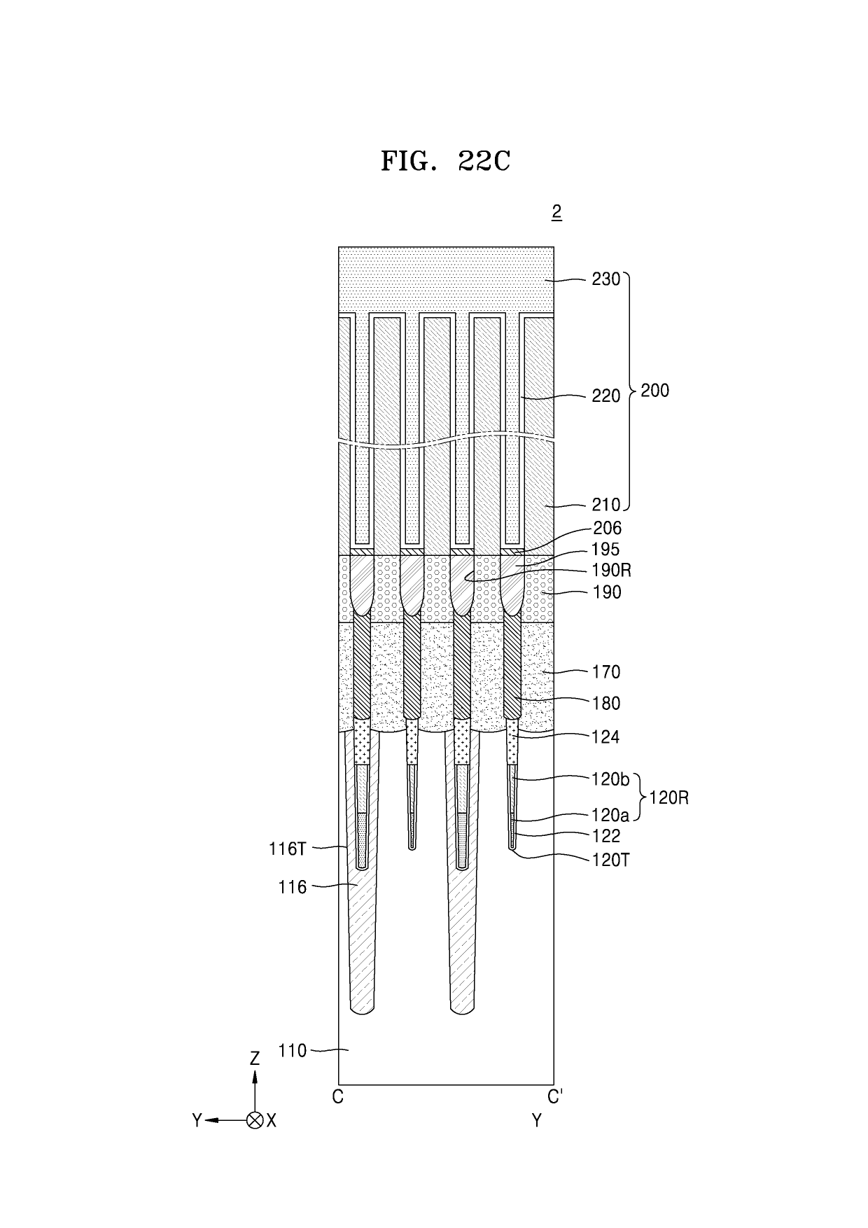

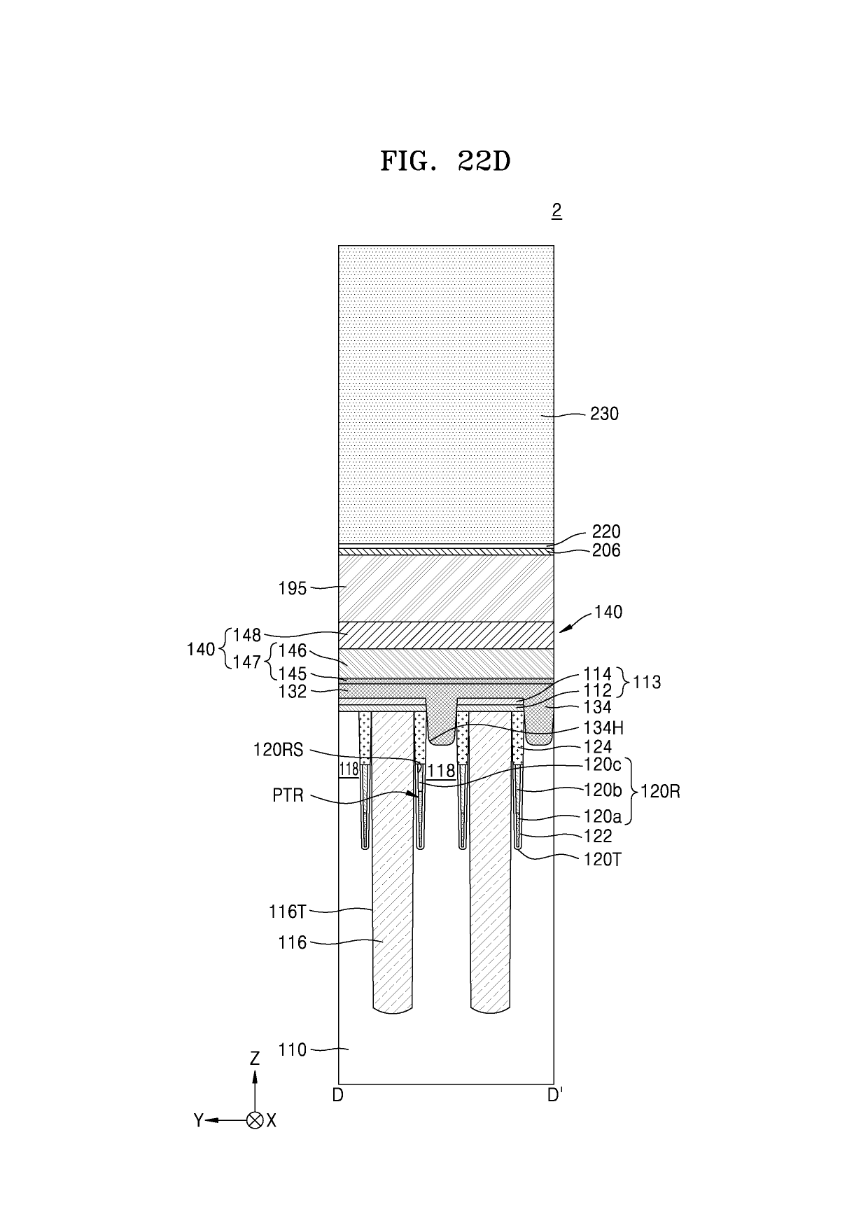

FIGS. 19A to 19D, 20A to 20D, and 21A to 21D are cross-sectional views for describing a method of manufacturing a semiconductor memory device, according to embodiments. FIGS. 22A to 22D are cross-sectional views illustrating a semiconductor memory device, according to embodiments. In detail, FIGS. 19A, 20A,and 21A, are cross-sectional views taken along line A-A’ of FIG. 2, FIGS. 19B, 20B, and 21B, are cross-sectional views taken along line B-B’ of FIG. 2, FIGS. 19C, 20C, amd 21C, are cross-sectional views taken along line C-C’ of FIG. 2, and FIGS. 19D, 20D, and 21D, are cross-sectional views taken along line D-D’ of FIG. 2, which are cross-sectional views for describing a method of manufacturing a semiconductor memory device after FIGS. 9A to 9D.

Referring to FIGS. 19A to 19D, a third preliminary conductive layer 120cP covering the plurality of lower word line layers 120a and the plurality of upper word line layers 120b and filling the plurality of word line trenches 120T is formed. The third preliminary conductive layer 120cP may include a semiconductor material. In some embodiments, the third preliminary conductive layer 120cP may include the same material as the plurality of upper word line layers 120b. For example, the third preliminary conductive layer 120cP may be formed of doped polysilicon. The third preliminary conductive layer 120cP may include an extension conductive portion 120cF filling the electrode recess 120RS.

Referring to FIGS. 19A to 19D and 20A to 20D, a filling conductive layer 120c filling the electrode recess 120RS is formed by removing an upper portion of the third preliminary conductive layer 120cP. The plurality of lower word line layers 120a, the plurality of upper word line layers 120b, and the filling conductive layer 120c may constitute a plurality of word lines 120R. The plurality of word lines 120R may constitute the plurality of word lines WL of FIG. 2.

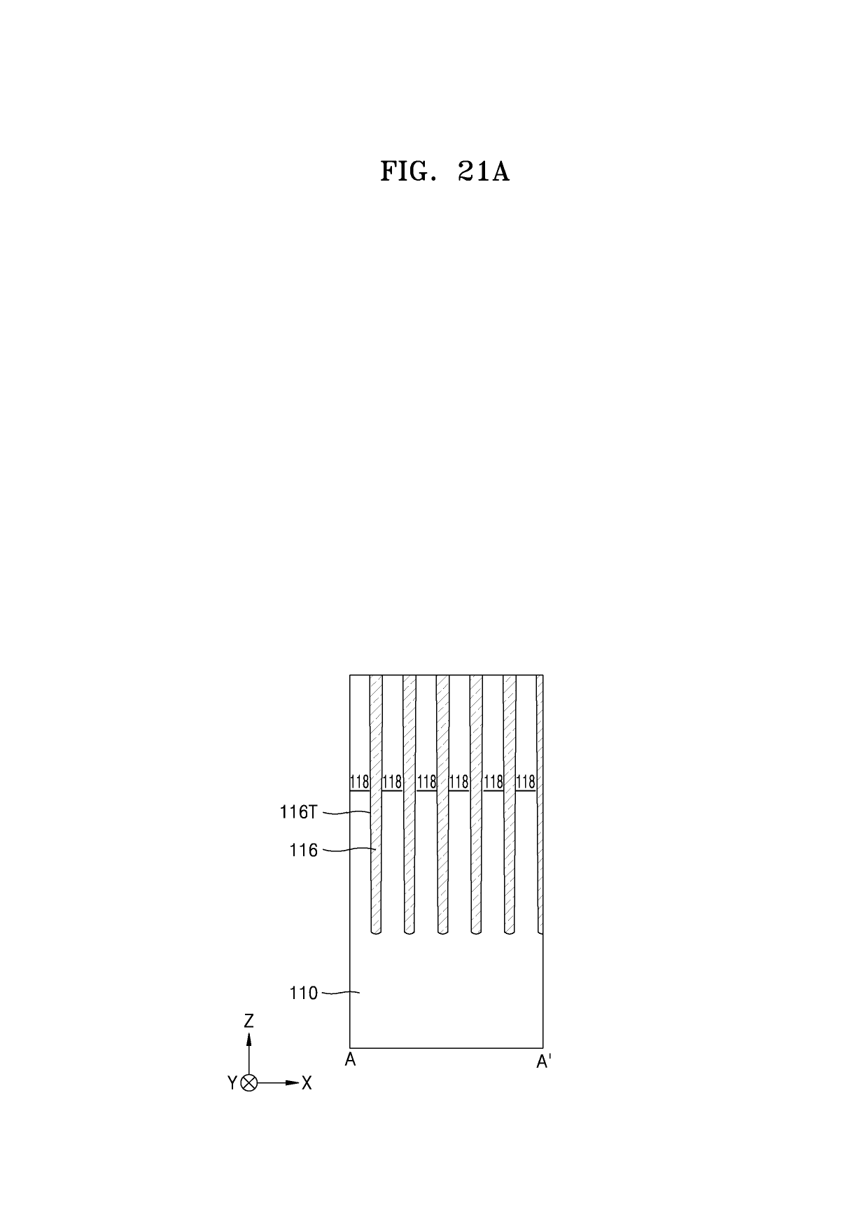

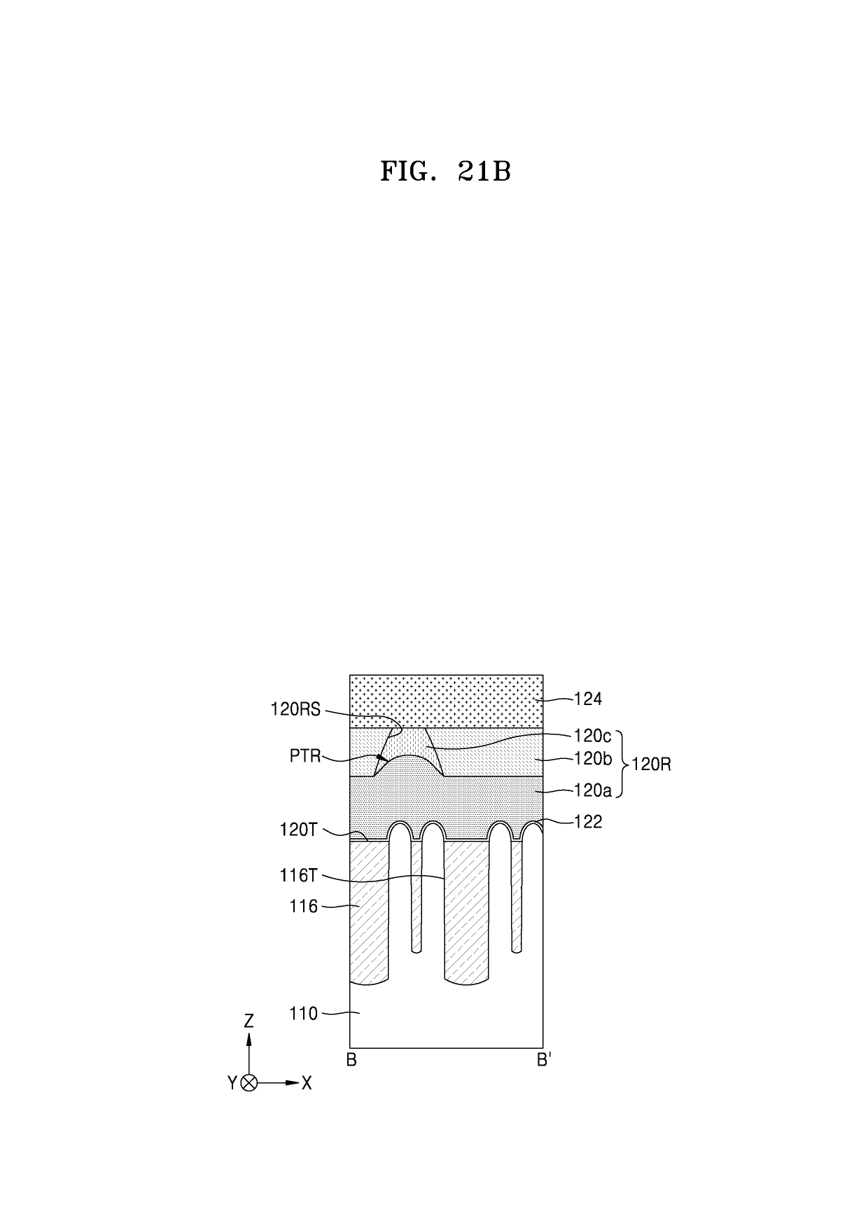

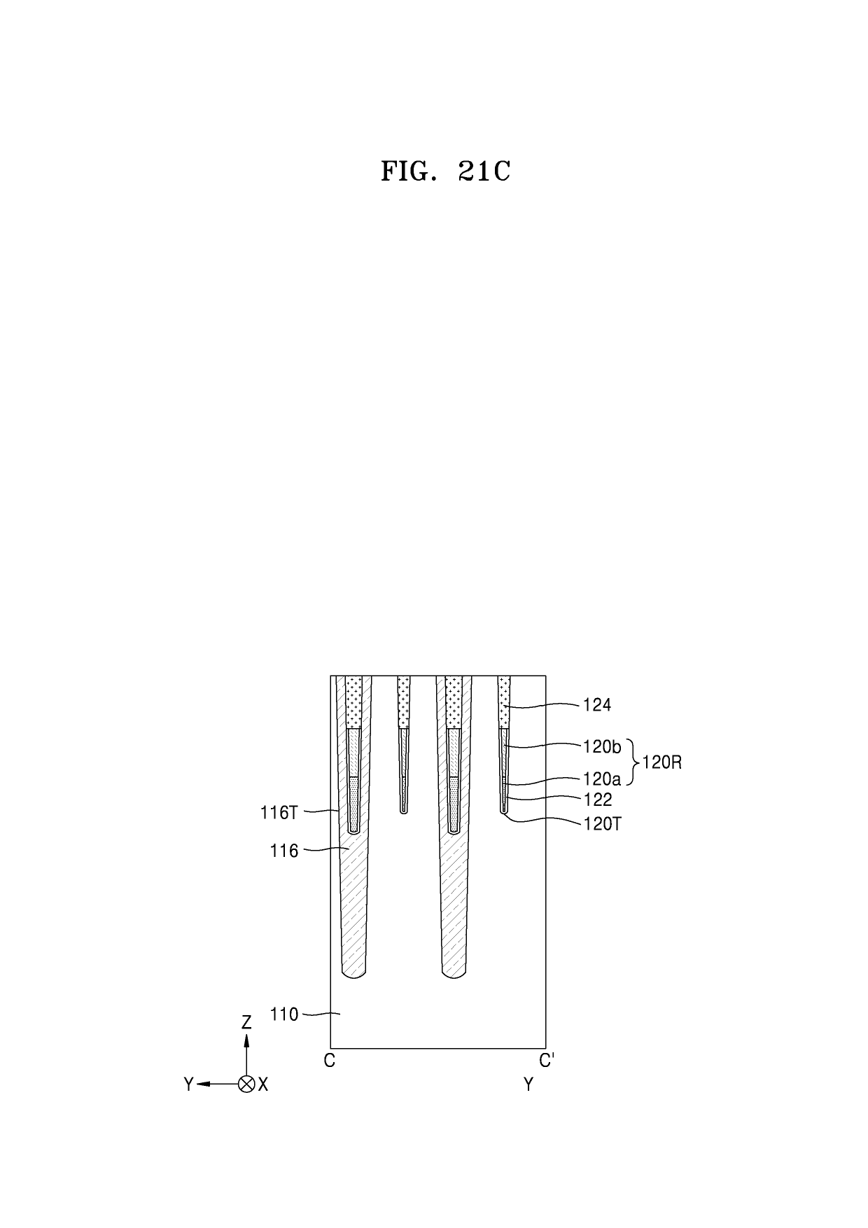

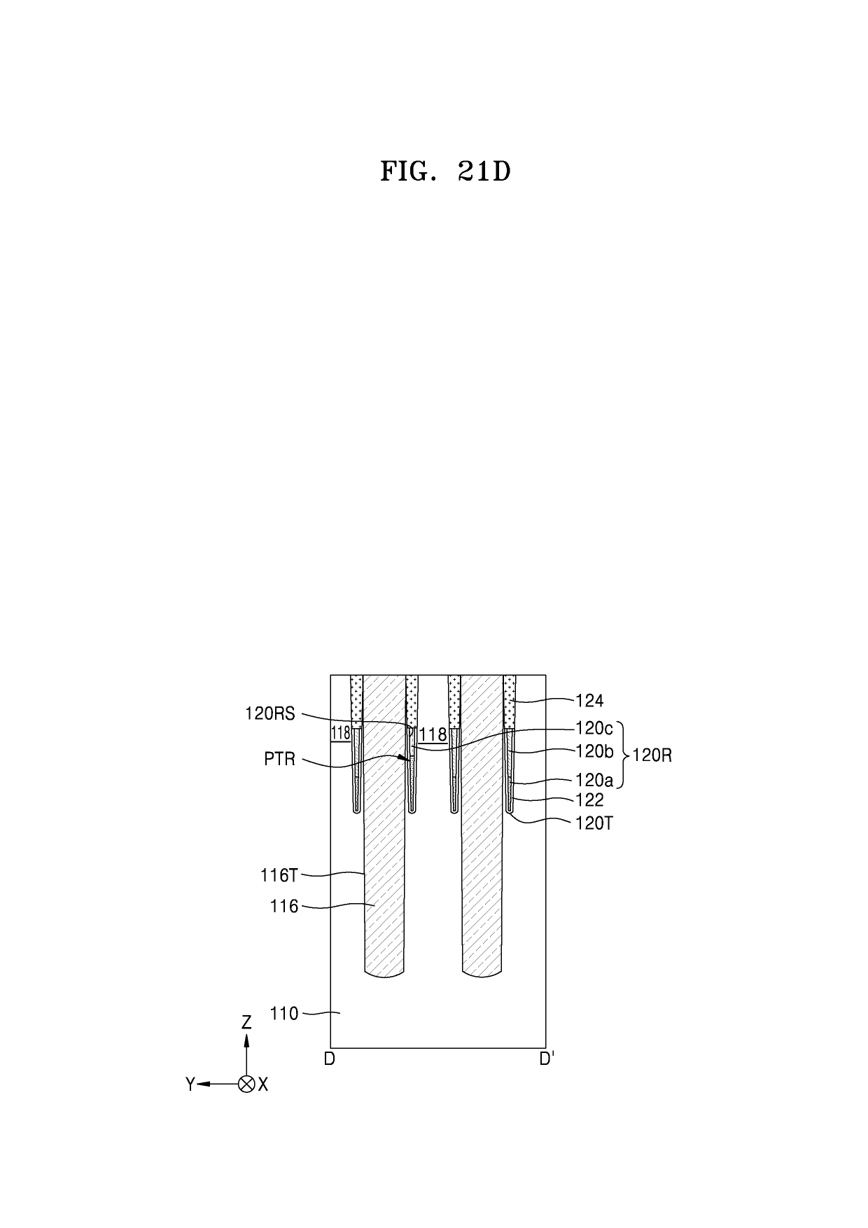

Referring to FIGS. 21A to 21D, the plurality of buried insulating films 124 covering the plurality of word lines 120R and filling the plurality of word line trenches 120T are formed. The plurality of gate dielectric films 122, the plurality of word lines 120R, and the plurality of buried insulating films 124 may fill all of the plurality of word line trenches 120T. The plurality of buried insulating films 124 may cover the plurality of upper word line layers 120b. At least some of the plurality of buried insulating films 124 may contact the filling conductive layer 120c.

Referring to FIGS. 22A to 22D, a semiconductor memory device 2 is formed by performing the manufacturing method described with reference to FIGS. 11A to 11D, 12D to 12D, 13A to 13D, 14A to 14D, 15A to 15D, FIGS. and 16A to 16D on a resultant structure shown in FIGS. 21A to 21D. The semiconductor memory device 2 includes the substrate 110 including the plurality of active areas 118, the plurality of gate dielectric films 122, the plurality of word lines 120R, and the plurality of buried insulating films 124 sequentially formed inside the plurality of word line trenches 120T crossing the plurality of active areas 118 in the substrate 110, the insulating structure 113 covering the device isolation film 116, the plurality of active areas 118, and the plurality of buried insulating films 124, the plurality of bit line structures 140 on the insulating structure 113, the plurality of insulating spacer structures 150 covering both side walls of the plurality of bit line structures 140, the plurality of buried contacts 170 filling a lower portion of a space defined by the plurality of insulating fences 180 and the plurality of insulating spacer structures 150 and connected to the plurality of active areas 118, the plurality of landing pads 190 filling an upper portion of the space defined by the plurality of insulating fences 180 and the plurality of insulating spacer structures 150 and extending to an upper portion of the bit line structure 140, the etching stop layer 206 disposed on the plurality of landing pads 190, and the plurality of capacitor structures 200 including the plurality of lower electrodes 210 passing through the etching stop layer 206 and connected to the plurality of landing pads 190, the capacitor dielectric layer 220, and the upper electrode 230 .

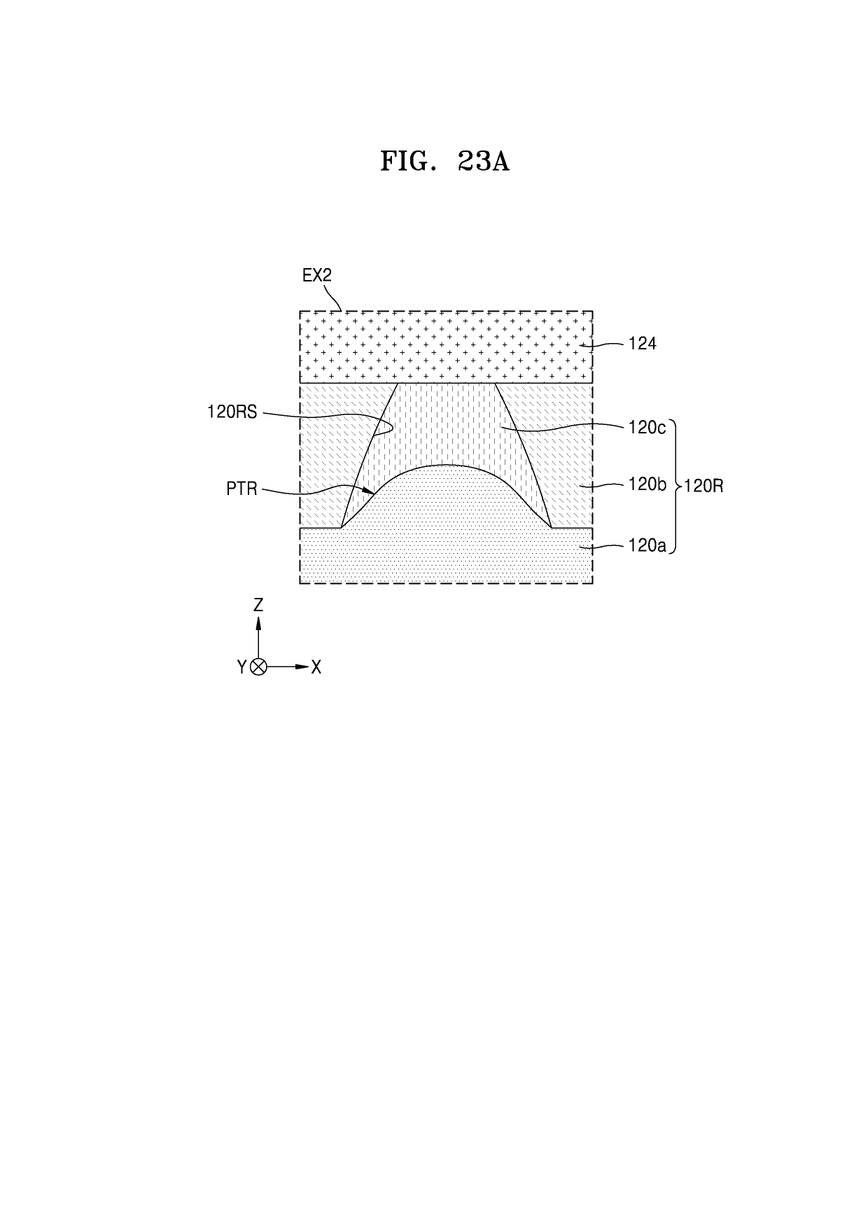

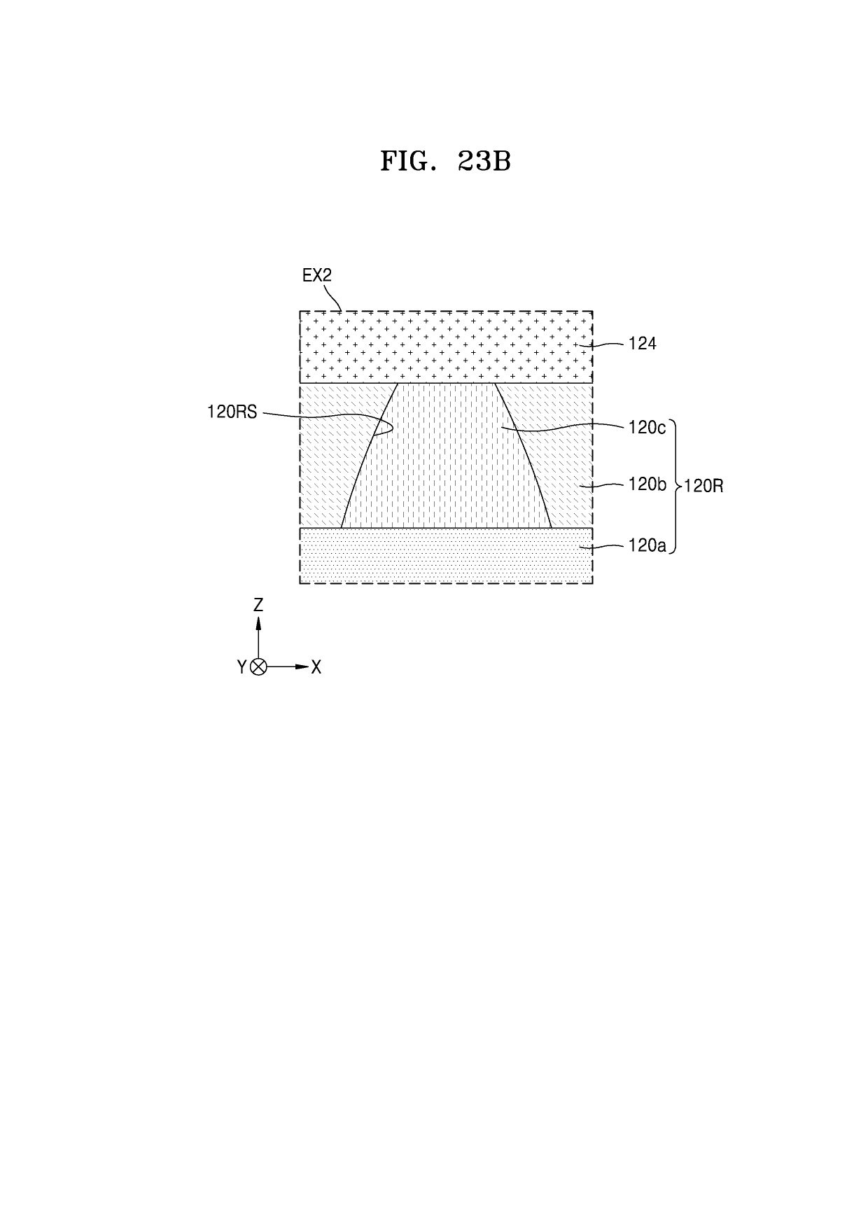

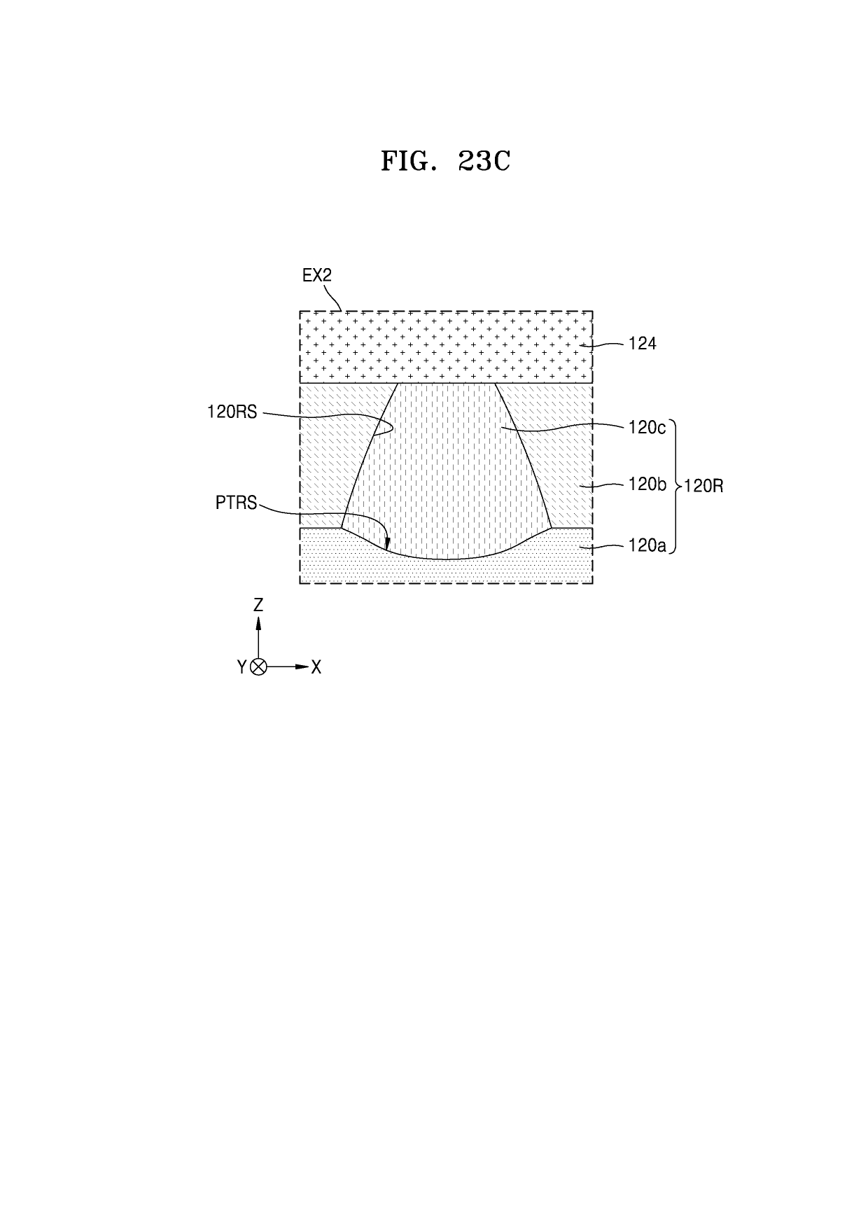

FIGS. 23A to 23C are partially enlarged views illustrating a semiconductor memory device, according to embodiments. In detail, FIGS. 23A to 23C are enlarged cross-sectional views illustrating a portion EX2 of FIG. 21B.

Referring to FIGS. 22A to 22D and FIG. 23A, the plurality of word lines 120R may include the plurality of lower word line layers 120a, the plurality of upper word line layers 120b, and the filling conductive layer 120c. At least some of the plurality of word lines 120R may include the electrode recess 120RS. The filling conductive layer 120c may fill the electrode recess 120RS. At least some of the plurality of upper word line layers 120b may be separated into two portions by the electrode recess 120RS and may be spaced apart from each other in the first horizontal direction (X direction). The plurality of buried insulating films 124 may be located on the plurality of word lines 120R and may cover the plurality of word lines 120R. At least some of the plurality of lower word line layers 120a may include the protrusion PTR at a portion corresponding to the electrode recess 120RS. The protrusion PTR may protrude toward the electrode recess 120RS in the vertical direction (Z direction) more than other portions of the lower word line layer 120a. The filling conductive layer 120c may contact the upper word line layer 120b and the lower word line layer 120a. In some embodiments, the filling conductive layer 120c may contact the protrusion PTR included in the lower word line layer 120a. Some of the plurality of upper word line layers 120b may extend in the first horizontal direction (X direction) and may be spaced apart from each other with the filling conductive layer 120c therebetween. For example, some of the plurality of upper word line layers 120b may be separated into two portions by the filling conductive layer 120c and may be spaced apart from each other in the first horizontal direction (X direction).

Accordingly, in the semiconductor memory device 2 and the method of manufacturing the semiconductor memory device 2 according to embodiments, even when the defect PT is formed as shown in FIGS. 5A to 5D, because the plurality of word lines 120R include the filling conductive layer 120c filling the electrode recess 120RS, electrical characteristics of the plurality of word lines 120R may not be degraded, and a short circuit in which the plurality of direct contact conductive patterns 134 and the plurality of word lines 120R are electrically connected to each other may be prevented. Accordingly, the method of manufacturing the semiconductor memory device 2 according to embodiments may form the semiconductor memory device 2 having a high degree of integration and operational reliability.

Referring to FIGS. 22A to 22D and FIG. 23B, the plurality of word lines 120R may include the plurality of lower word line layers 120a, the plurality of upper word line layers 120b, and the filling conductive layer 120c. At least some of the plurality of word lines 120R may include the electrode recess 120RS. The filling conductive layer 120c may fill the electrode recess 120RS. At least some of the plurality of upper word line layers 120b may be separated into two portions by the electrode recess 120RS and may be spaced apart from each other in the first horizontal direction (X direction). The plurality of buried insulating films 124 may be located on the plurality of word lines 120R and may cover the plurality of word lines 120R. A top surface of a portion of the lower word line layer 120a corresponding to the electrode recess 120RS may be at substantially the same vertical level as top surfaces of other portions of the lower word line layer 120a. That is, top surfaces of the plurality of lower word line layers 120 may be at substantially the same vertical level. For example, in a process of removing the defect PTa included in the plurality of lower word line layers 120a described with reference to FIGS. 8A to 8D and 9A to 9D, a portion of the defect PTa may not remain.

The plurality of buried insulating films 124 may be located on the plurality of word lines 120R and may cover the plurality of word lines 120R. The filling conductive layer 120c may contact the upper word line layer 120b and the lower word line layer 120a. In some embodiments, the filling conductive layer 120c may contact a top surface of the lower word line layer 120a. Some of the plurality of upper word line layers 120b may extend in the first horizontal direction (X direction) and may be spaced apart from each other with the filling conductive layer 120c therebetween. For example, some of the plurality of upper word line layers 120b may be separated into two portions by the filling conductive layer 120c and may be spaced apart from each other in the first horizontal direction (X direction).

Referring to FIGS. 22A to 22D and FIG. 23C, the plurality of word lines 120R may include the plurality of lower word line layers 120a, the plurality of upper word line layers 120b, and the filling conductive layer 120c. At least some of the plurality of word lines 120R may include the electrode recess 120RS. The filling conductive layer 120c may fill the electrode recess 120RS. At least some of the plurality of upper word line layers 120b may be separated into two portions by the electrode recess 120RS and may be spaced apart from each other in the first horizontal direction (X direction). The plurality of buried insulating films 124 may be located on the plurality of word lines 120 and may cover the plurality of word lines 120. At least some of the plurality of lower word line layers 120a may include the concave portion PTRS. The lower word line layer 120a may have a top surface that is concave toward the inside of the lower word line layer 120a more than top surfaces of other portions of the lower word line layer 120a. For example, in a process of removing the defect PTa included in the plurality of lower word line layers 120a described with reference to FIGS. 8A to 8D and 9A to 9D, the defect PTa and a portion of the lower word line layer 120a other than the defect PTa may be removed together to form the concave portion PTRS.

The filling conductive layer 120c may contact the upper word line layer 120b and the lower word line layer 120a. In some embodiments, the filling conductive layer 120c may fill the concave portion PTRS included in the lower word line layer 120a. Some of the plurality of upper word line layers 120b may extend in the first horizontal direction (X direction) and may be spaced apart from each other with the filling conductive layer 120c therebetween. For example, some of the plurality of upper word line layers 120b may be separated into two portions by the filling conductive layer 120c and may be spaced apart from each other in the first horizontal direction (X direction).

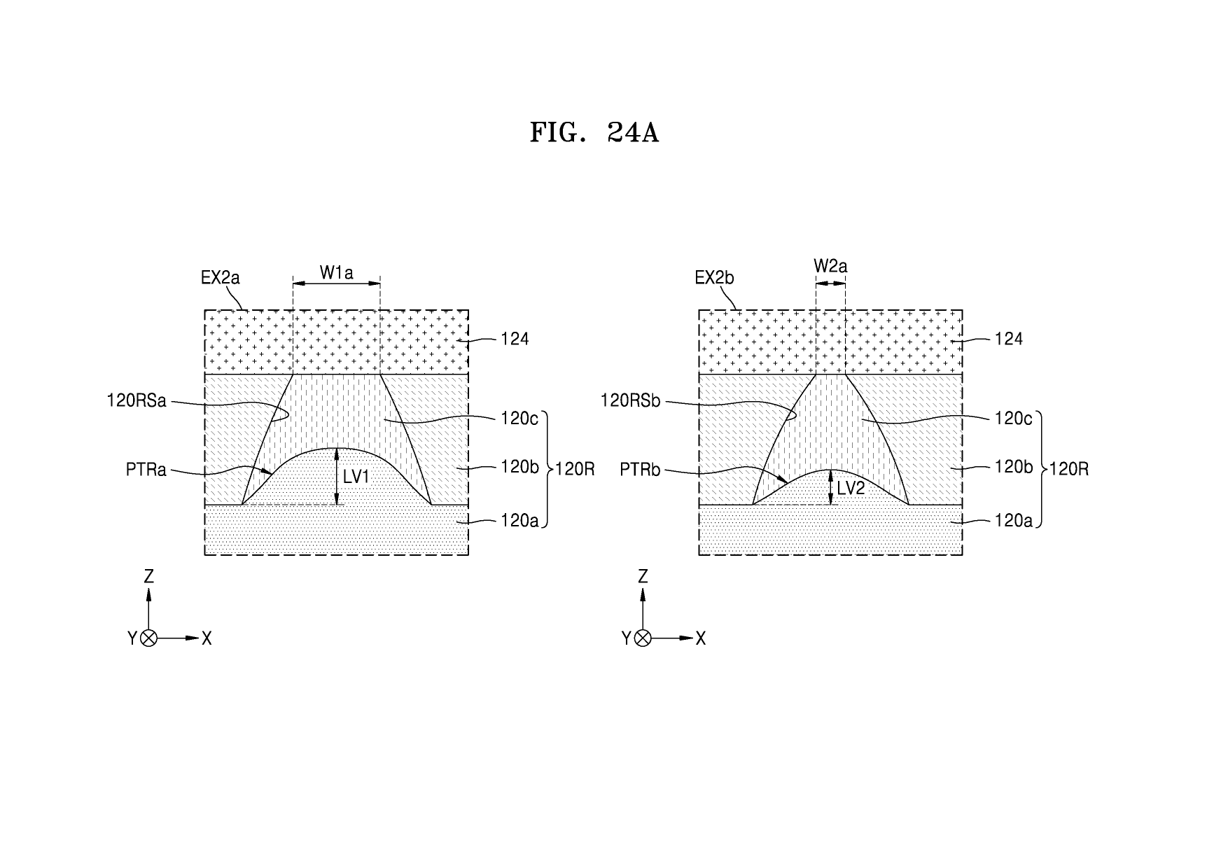

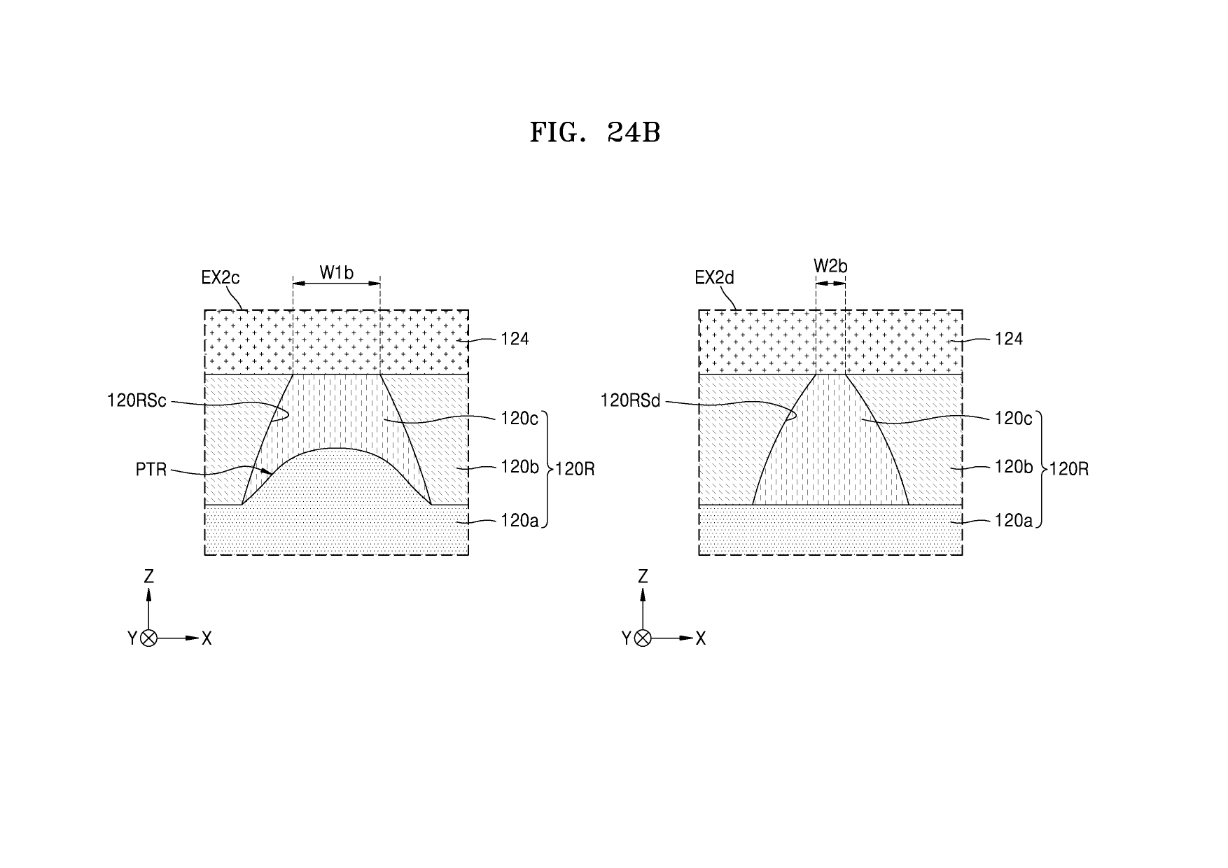

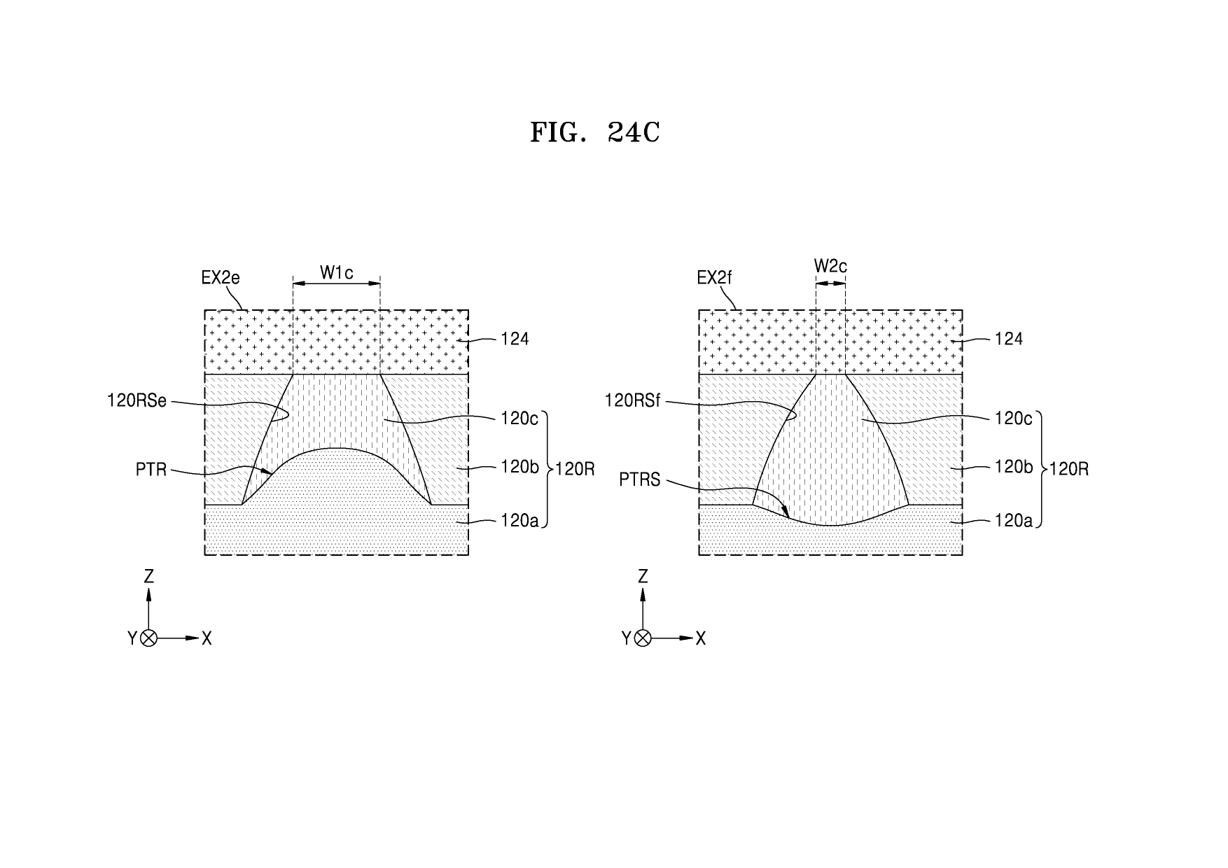

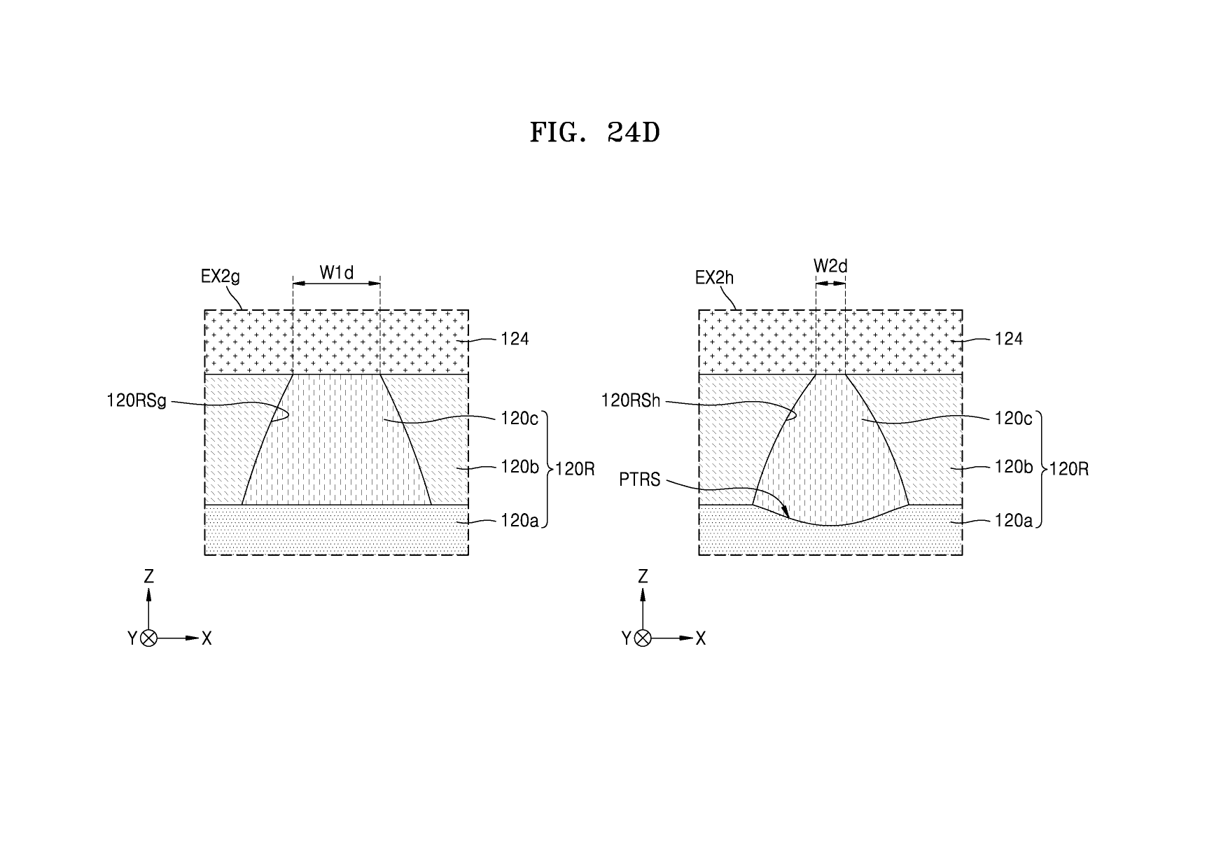

FIGS. 24A to 24D are partially enlarged views illustrating a semiconductor memory device, according to embodiments. In detail, portions EX2a and EX2b of FIG. 24A are other portions corresponding to EX2 of FIG. 21B, portions EX2c and EX2d of FIG. 24B are other portions corresponding to EX2 of FIG. 21B, portions EX2e and EX2f of FIG. 24C are other portions corresponding to EX2 of FIG. 21B, and portions EX2g and EX2h of FIG. 24D are other portions corresponding to EX2 of FIG. 21B.

Referring to FIGS. 22A to 22D and FIG. 24A, the plurality of word lines 120R may include the plurality of lower word line layers 120a, the plurality of upper word line layers 120b, and the filling conductive layer 120c. At least some of the plurality of word lines 120R may include the first electrode recess 120RSa, and at least some of the plurality of word lines 120R may include the second electrode recess 120RSb. The filling conductive layer 120c may fill each of the first electrode recess 120RSa and the second electrode recess 120RSb. In the first horizontal direction (X direction), the first horizontal width W1a, which is a horizontal width of an uppermost end of the first electrode recess 120RSa, may be greater than the second horizontal width W2a, which is a horizontal width of an uppermost end of the second electrode recess 120RSb. At least some of the plurality of lower word line layers 120a may include the first protrusion PTRa at a portion corresponding to the first electrode recess 120RSa, and at least some of the plurality of lower word line layers 120a may include the second protrusion PTRb at a portion corresponding to the second electrode recess 120RSb. The first protrusion PTRa may protrude by the first height LV1 toward the first electrode recess 120RSa in the vertical direction (Z direction) more than other portions of the lower word line layer 120a. The second protrusion PTRb may protrude by the second height LV2 lower than the first height LV1 toward the second electrode recess 120RSb in the vertical direction (Z direction) more than other portions of the lower word line layer 120a. The filling conductive layer 120c may contact each of the first protrusion PTRa and the second protrusion PTRb. At the same vertical level, horizontal widths of the first electrode recess 120RSa and the filling conductive layer 120c filling the first electrode recess 120RSa may be greater than horizontal widths of the second electrode recess 120RSb and the filling conductive layer 120c filling the second electrode recess 120RSb, respectively. The filling conductive layer 120c filling the first electrode recess 120RSa may be referred to as a first filling conductive layer, and the filling conductive layer 120c filling the second electrode recess 120RSb may be referred to as a second filling conductive layer.

Referring to FIGS. 22A to 22D and FIG. 24B, the plurality of word lines 120R may include the plurality of lower word line layers 120a, the plurality of upper word line layers 120b, and the filling conductive layer 120c. At least some of the plurality of word lines 120R may include the first electrode recess 120RSc, and at least some of the plurality of word lines 120R may include the second electrode recess 120RSd. The filling conductive layer 120c may fill each of the first electrode recess 120RSc and the second electrode recess 120RSd. In the first horizontal direction (X direction), the first horizontal width W1b, which is a horizontal width of an uppermost end of the first electrode recess 120RSc, may be greater than the second horizontal width W2b, which is a horizontal width of an uppermost end of the second electrode recess 120RSd. At least some of the plurality of lower word line layers 120a may include the protrusion PTR at a portion corresponding to the first electrode recess 120RSc, and at least some of the plurality of lower word line layers 120a may be formed so that a top surface of a portion corresponding to the second electrode recess 120RSd is located at substantially the same vertical level as top surfaces of other portions of the lower word line layer 120a. The filling conductive layer 120c filling the first electrode recess 120RSc may contact the protrusion PTR. The filling conductive layer 120c filling the second electrode recess 120RSd may contact a top surface of the lower word line layer 120a. At the same vertical level, horizontal widths of the first electrode recess 120RSc and the filling conductive layer 120c filling the first electrode recess 120RSc in the first horizontal direction (X direction) may be greater than horizontal widths of the second electrode recess 120RSd and the filling conductive layer 120c filling the second electrode recess 120RSd, respectively. The filling conductive layer 120c filling the first electrode recess 120RSc may be referred to as a first filling conductive layer, and the filling conductive layer 120c filling the second electrode recess 120RSd may be referred to as a second filling conductive layer.

Referring to FIGS. 22A to 22D and FIG. 24C, the plurality of word lines 120R may include the plurality of lower word line layers 120a, the plurality of upper word line layers 120b, and the filling conductive layer 120c. At least some of the plurality of word lines 120R may include the first electrode recess 120RSe, and at least some of the plurality of word lines 120R may include the second electrode recess 120RSf. The filling conductive layer 120c may fill each of the first electrode recess 120RSe and the second electrode recess 120RSf. In the first horizontal direction (X direction), the first horizontal width W1c, which is a horizontal width of an uppermost end of the first electrode recess 120RSe, may be greater than the second horizontal width W2c, which is a horizontal width of an uppermost end of the second electrode recess 120RSf. At least some of the plurality of lower word line layers 120a may include the protrusion PTR at a portion corresponding to the first electrode recess 120RSe, and at least some of the plurality of lower word line layers 120a may include the concave portion PTRS at a portion corresponding to the second electrode recess 120RSf. The filling conductive layer 120c filling the first electrode recess 120RSe may contact the protrusion PTR, and the filling conductive layer 120c filling the second electrode recess 120RSf may fill the concave portion PTRS. At the same vertical level, in the first horizontal direction (X direction), horizontal widths of the first electrode recess 120RSe and the filling conductive layer 120c filling the first electrode recess 120RSe may be greater than horizontal widths of the second electrode recess 120RSf and the filling conductive layer 120c filling the second electrode recess 120RSf, respectively. The filling conductive layer 120c filling the first electrode recess 120RSe may be referred to as a first filling conductive layer, and the filling conductive layer 120c filling the second electrode recess 120RSf may be referred to as a second filling conductive layer.

Referring to FIGS. 22A to 22D and FIG. 24D, the plurality of word lines 120R may include the plurality of lower word line layers 120a, the plurality of upper word line layers 120b, and the filling conductive layer 120c. At least some of the plurality of word lines 120R may include the first electrode recess 120RSg, and at least some of the plurality of word lines 120R may include the second electrode recess 120RSh. The filling conductive layer 120c may fill each of the first electrode recess 120RSg and the second electrode recess 120RSh. In the first horizontal direction (X direction), the first horizontal width W1d, which is a horizontal width of an uppermost end of the first electrode recess 120RSg, may be greater than the second horizontal width W2d, which is a horizontal width of an uppermost end of the second electrode recess 120RSh. At least some of the plurality of lower word line layers 120a may be formed so that a top surface of a portion corresponding to the first electrode recess 120RSg is located at substantially the same vertical level as top surfaces of other portions of the lower word line layer 120a, and at least some of the plurality of lower word line layers 120a may include the concave portion PTRS at a portion corresponding to the second electrode recess 120RSh. The filling conductive layer 120c filling the first electrode recess 120RSg may contact a top surface of the lower word line layer 120a, and the filling conductive layer 120c filling the second electrode recess 120RSh may fill the concave portion PTRS. At the same vertical level, horizontal widths of the first electrode recess 120RSg and the filling conductive layer 120c filling the first electrode recess 120RSg in the first horizontal direction (X direction) may be greater than horizontal widths of the second electrode recess 120RSh and the filling conductive layer 120c filling the second electrode recess 120RSh, respectively. The filling conductive layer 120c filling the first electrode recess 120RSg may be referred to as a first filling conductive layer, and the filling conductive layer 120c filling the second electrode recess 120RSh may be referred to as a second filling conductive layer.

While aspects of embodiments have been particularly shown and described, it will be understood that various changes in form and details may be made therein without departing from the spirit and scope of the following claims.

What is claimed is:

1. A method of manufacturing a semiconductor memory device, the method comprising:
providing a substrate in which a plurality of active areas are defined by a device isolation film;
forming a word line trench extending along a first horizontal direction across the plurality of active areas and the device isolation film;
forming a first preliminary conductive layer filling at least a portion of the word line trench;
performing a first etching process to remove an upper portion of the first preliminary conductive layer and form a lower word line layer that fills a lower portion of the word line trench;
forming a second preliminary conductive layer covering the lower word line layer and filling the word line trench;
performing a second etching process to remove an upper portion of the second preliminary conductive layer and form an upper word line layer that fills a portion of the word line trench;
performing a third etching process having a high etch selectivity of the lower word line layer with respect to the upper word line layer; and
forming a buried insulating film covering the lower word line layer and the upper word line layer and filling the word line trench.

2. The method of claim 1, wherein each of the first etching process and the second etching process is an anisotropic dry etching process, and
wherein the third etching process is an isotropic wet etching process.

3. The method of claim 1, wherein the first preliminary conductive layer comprises a material containing metal atoms, and
wherein the second preliminary conductive layer comprises a semiconductor material.

4. The method of claim 1, wherein the lower word line layer comprises a defect protruding upward more than other portions of the lower word line layer, and
wherein the forming of the upper word line layer comprises removing an upper portion of the second preliminary conductive layer so that the defect in the lower word line layer protrudes upward beyond a top surface of the upper word line layer.

5. The method of claim 4, wherein the performing of the third etching process comprises removing at least a portion of the defect in the lower word line layer to form an electrode recess, which is a space where the portion of the defect in the lower word line layer is removed.

6. The method of claim 5, wherein the forming of the buried insulating film comprises forming the buried insulating film so that the buried insulating film comprises an extension insulating portion filling the electrode recess.

7. The method of claim 6, wherein the extension insulating portion contacts the lower word line layer.

8. The method of claim 5, further comprising forming a filling conductive layer filling the electrode recess, before the forming of the buried insulating film.

9. The method of claim 5, wherein, after the performing of the third etching process, the lower word line layer comprises a protrusion protruding toward the electrode recess more than other portions of the lower word line layer.

10. The method of claim 5, wherein, after the performing of the third etching process, the lower word line layer comprises a concave portion having a concave top surface at a portion corresponding to the electrode recess.

11. A method of manufacturing a semiconductor memory device, the method comprising:
providing a substrate in which a plurality of active areas are defined by a device isolation film;
forming a plurality of word line trenches extending parallel to each other along a first horizontal direction across the plurality of active areas and the device isolation film;
forming a first preliminary conductive layer filling at least a portion of each of the plurality of word line trenches;
performing a first etching process to remove an upper portion of the first preliminary conductive layer and form a plurality of lower word line layers that fill lower portions of the plurality of word line trenches, wherein the first etching process is an anisotropic etching process;
forming a second preliminary conductive layer covering the plurality of lower word line layers and filling the plurality of word line trenches;
performing a second etching process to remove an upper portion of the second preliminary conductive layer and form a plurality of upper word line layers filling portions of the plurality of word line trenches, wherein the second etching process is an anisotropic etching process;
performing a third etching process that is an isotropic etching process and has a high etch selectivity of the plurality of lower word line layers with respect to the plurality of upper word line layers; and
forming a plurality of buried insulating films covering the plurality of lower word line layers and the plurality of upper word line layers and filling the plurality of word line trenches.

12. The method of claim 11, wherein at least one of the plurality of lower word line layers comprise a defect protruding upward more than other portions of the plurality of lower word line layers, and
wherein the forming of the plurality of upper word line layers comprises removing an upper portion of the second preliminary conductive layer so that the defect in the at least one of the plurality of lower word line layers protrudes upward beyond top surfaces of the plurality of upper word line layers.

13. The method of claim 12, wherein the performing of the third etching process comprises forming an electrode recess by removing at least a portion of the defect in the at least one of the plurality of lower word line layers, and
wherein the forming of the plurality of buried insulating films comprises forming the plurality of buried insulating films so that at least one of the plurality of buried insulating films comprises an extension insulating portion filling the electrode recess and contacting at least one of the plurality of lower word line layers.

14. The method of claim 13, wherein, after the performing of the third etching process, at least one of the plurality of lower word line layers comprises a first protrusion protruding toward a first electrode recess, and at least one of the plurality of lower word line layers comprises a second protrusion protruding toward a second electrode recess,
wherein a horizontal width of an uppermost end of the first electrode recess is greater than a horizontal width of an uppermost end of the second electrode recess, and
wherein a protrusion height of the second protrusion is lower than a protrusion height of the first protrusion.

15. The method of claim 13, wherein, after the performing of the third etching process, at least one of the plurality of lower word line layers comprise a concave portion having a concave top surface at a portion corresponding to the electrode recess, and
wherein the extension insulating portion fills the concave portion.

16. The method of claim 12, wherein the first preliminary conductive layer comprises a material containing metal atoms, and
wherein the second preliminary conductive layer comprises a semiconductor material.

17. The method of claim 16, wherein the performing of the third etching process comprises forming an electrode recess by removing at least a portion of the defect in the at least one of the plurality of lower word line layers, and
wherein the method further comprises forming a filling conductive layer comprising a semiconductor material and filling the electrode recess, before the forming of the plurality of buried insulating films.

18. A method of manufacturing a semiconductor memory device, the method comprising:
providing a substrate in which a plurality of active areas are defined by a device isolation film;
forming a plurality of word line trenches extending parallel to each other along a first horizontal direction across the plurality of active areas and the device isolation film;
forming a first preliminary conductive layer filling at least a portion of each of the plurality of word line trenches;
performing a first etching process to remove an upper portion of the first preliminary conductive layer and form a plurality of lower word line layers filling lower portions of the plurality of word line trenches, wherein the first etching process is an anisotropic etching process, and wherein at least one of the plurality of lower word line layers comprises a defect protruding upward more than other portions of the plurality of lower word line layers;
forming a second preliminary conductive layer covering the plurality of lower word line layers and filling the plurality of word line trenches;
performing a second etching process to remove an upper portion of the second preliminary conductive layer and form a plurality of upper word line layers filling portions of the plurality of word line trenches, wherein the second etching process is an anisotropic etching process, wherein the defect in the at least one of the plurality of lower word line layers protrudes upward beyond a top surface of the plurality of upper word line layers, and wherein the plurality of lower word line layers and the plurality of upper word line layers constitute a plurality of word lines;
performing a third etching process that is an isotropic etching process and has a high etch selectivity of the plurality of lower word line layers with respect to the plurality of upper word line layers, to form an electrode recess by removing at least a portion of the defect in the at least one of the plurality of lower word line layers;
forming a plurality of buried insulating films covering the plurality of lower word line layers and the plurality of upper word line layers, and filling the plurality of word line trenches and the electrode recess;
forming a plurality of bit lines extending along a second horizontal direction, perpendicular to the first horizontal direction, and a plurality of direct contact conductive patterns connecting the plurality of bit lines to the plurality of active areas, on the plurality of word lines;
forming a plurality of buried contacts filling a lower portion of a space between the plurality of bit lines and connected to the plurality of active areas;
forming a plurality of landing pads connected to the plurality of buried contacts; and
forming a plurality of capacitor structures connected to the plurality of landing pads.

19. The method of claim 18, wherein the first preliminary conductive layer is formed of a metal, conductive metal nitride, or a combination thereof, and
wherein the second preliminary conductive layer is formed of doped polysilicon.

20. The method of claim 18, wherein, after the forming of the electrode recess, at least one of the plurality of lower word line layers comprise a protrusion protruding toward the electrode recess.
